(19) United States
(12) Patent Application Publication
(10) Pub. No.: US 2015/0207012 A1
(43) Pub. Date: Jul. 23, 2015

(54) PRINTING-BASED ASSEMBLY OF MULTI-JUNCTION, MULTI-TERMINAL PHOTOVOLTAIC DEVICES AND RELATED METHODS

(71) Applicants: THE BOARD OF TRUSTEES OF THE UNIVERSITY OF ILLINOIS, Urbana, IL (US); SEMPRIUS, INC., Durham, NC (US)

(72) Inventors: John A. ROGERS, Champaign, IL (US); Xing SHENG, Urbana, IL (US); Christopher A. BOWER, Durham, NC (US); Matthew MEITL, Durham, NC (US); Scott BURROUGHS, Durham, NC (US)

(21) Appl. No.: 14/599,290

(22) Filed: Jan. 16, 2015

Related U.S. Application Data
(60) Provisional application No. 61/928,364, filed on Jan. 16, 2014.

(51) Int. Cl. H01L 31/0725; H01L 31/0216; H01L 31/0232; H01L 31/0735; H01L 31/18

(52) U.S. Cl. CPC H01L 31/0725; H01L 31/0735; H01L 31/184; H01L 31/1844; H01L 31/02327; H01L 31/02168

(57) ABSTRACT

Multi-junction photovoltaic devices and methods for making multi-junction photovoltaic devices are disclosed. The multi-junction photovoltaic devices comprise a first photovoltaic p-n junction structure having a first interface surface, a second photovoltaic p-n junction structure having a second interface surface, and an optional interface layer provided between the first interface surface and the second interface surface, where the photovoltaic p-n junction structures and optional layers are provided in a stacked multilayer geometry. In an embodiment, the optional interface layer comprises a chalcogenide dielectric layer.

### CROSS-REFERENCE TO RELATED APPLICATIONS

This application claims benefit to U.S. Provisional Patent Application No. 61/928,364 filed Jan. 16, 2014, which is incorporated by reference to the extent not inconsistent herewith.

### STATEMENT REGARDING FEDERALLY SPONSORED RESEARCH OR DEVELOPMENT

Not applicable.

### BACKGROUND OF INVENTION

Significant research activity has sought to realize the efficiency limits of known photovoltaic (PV) cells, and to expand upon materials and geometries for semiconductor p-n junctions in order to increase cell efficiency.

Single junction (SJ) cells have a theoretical efficiency limit of ˜33.4% under one sun illumination, primarily due to the ineffective use of the entire solar spectrum. To optimize the efficiency of SJ cells, multiple, separated SJ cells can be implemented with spectral-splitting optical elements to utilize more of the solar spectrum, but complexity in manufacturing, alignment and light management hinders use of such systems in practice.

Devices that incorporate multiple junctions (i.e. sub-cells) in monolithic stacks, known as multijunction (MJ) cells, spectrally split sunlight into sub-cells with different bandgaps along a path normal to a receiving surface of the cell. Current MJ cells provide absolute efficiencies of about 44%, but further improvements will require solutions to challenges in achieving lattice-matched or metamorphic epitaxial growth in complex stacks and in maintaining current-matched outputs from each of the serially connected sub-cells because the overall current is determined by the smallest current among the sub-cells.

Mechanical stacking of separately grown SJ or MJ materials represents a well-explored route to MJ devices. This process involves physical wafer bonding, followed by eliminating the top and/or bottom wafers, for example, by etching or polishing. One option for bonding uses direct, high-temperature wafer fusion techniques. The electrically conducting interface that results, however, retains the requirement of current-matching. This requirement becomes challenging to maintain as the number of sub-cells in the MJ device increases due to variations in the terrestrial solar spectrum.

An alternative bonding approach uses thick, insulating organic adhesives, with double-sided, multilayer antireflective coatings and multi-terminal connections. Here, the current-matching requirement is eliminated by the presence of an insulator but the resulting MJ cells suffer from interface reflections, poor heat flow characteristics and often unfavorable thermo-mechanical interface stresses at high irradiance concentrations. Thus, neither of these bonding strategies currently offers a realistic means for manufacturing cells or for viable multiple stacking operations.

A number of patents and publications disclose multijunction photovoltaic devices including: U.S. Patent Application Publication Nos. 2014/0261628 and 2012/0115262 and Lumb et al., “Development of InGaAs solar cells for >44% efficient transfer-printed multi-junctions”, Photovoltaic Specialist Conference, (2014).

### SUMMARY OF THE INVENTION

The invention provides devices having multiple p-n junctions and corresponding terminals, including multi-junction, multi-terminal photovoltaic devices for the conversion of solar energy into electricity. In some embodiments, a multi-junction, multi-terminal device is combined with a single junction (1J) device or another multi-junction device in a stacked configuration via printing, such as dry contact transfer printing, to facilitate absorption of a wide range of wavelengths from the electromagnetic spectrum, thereby improving overall device efficiency. In some embodiments, a non-organic insulating material, such as air or an inorganic insulator, is disposed between sub-cells to eliminate the need for current-matching between the cells. When the non-organic insulating material is a good thermal conductor, thermo-mechanical interface stresses can be reduced, thereby improving mechanical stability of the MJ cells relative to cells bound by organic adhesives.

In an aspect, a multi-junction photovoltaic device comprises a first photovoltaic p-n junction structure characterized by a thickness and lateral dimensions, the first photovoltaic p-n junction structure having a first interface surface; a second photovoltaic p-n junction structure characterized by a thickness and lateral dimensions, the second photovoltaic p-n junction structure having a second interface surface; and an interface layer provided between the first interface surface and the second interface surface, the interface layer comprising a chalcogenide dielectric layer; wherein the first photovoltaic p-n junction structure, the interface layer and the second photovoltaic p-n junction structure are provided in a stacked multilayer geometry. In an embodiment, the multi-junction photovoltaic device is characterized by a conversion efficiency for incident solar radiation greater than or equal to 43%, or greater than or equal to 45%, or greater than or equal to 47%, or greater than or equal to 49%

In an embodiment, the lateral dimensions of the first photovoltaic p-n junction structure and/or the second photovoltaic p-n junction structure are each independently less than or equal to 3000 microns, or less than or equal to 1500 microns, or less than or equal to 800 microns. For example, the lateral dimensions of the first photovoltaic p-n junction structure, the second photovoltaic p-n junction structure or both may be independently selected from the range of 800 microns to 3000 microns, or 800 microns to 1500 microns, or 800 microns to 1000 microns.

The interface layer between the first interface surface and the second interface surface enables important physical, optical, thermal and/or electrical properties. For example, the interface layer may comprise an electrically insulating layer characterized by an electrical resistance greater than or equal to 100,000 Ωcm², a refractive index-matched layer characterized by a refractive index within 30% of the refractive indices at the first interface surface and the second interface surface, a thermally conductive layer characterized by a thermal conductivity greater than or equal to 0.5 W/m/K, an optically transparent layer characterized by a transmittance equal to or greater than 90% for light having wavelengths selected over the range of 800 nm to 1800 nm and/or an electrostatically stable layer characterized by an electrical breakdown threshold voltage equal to or greater than 15 V.

The interface layer between the first interface surface and the second interface surface, which may be provided using a sol-gel process, a spin-on process, a spray process or a combination thereof, generally has a thickness selected from the range of 50 nm to 5 microns, or 100 nm to 2 microns, 200 nm to 1 micron, 400 nm to 1 micron or 500 nm to 1 micron. In an embodiment, the interface layer comprises a selenide, a sulfide or a telluride composition. In an embodiment, an interface layer is a selenide, such as a selenide glass. In a particular embodiment, the interface layer comprises As₂Se₃.

In an embodiment, the first photovoltaic p-n junction structure, the second photovoltaic p-n junction structure or both independently comprise epitaxially grown multilayer structures. However, the first photovoltaic p-n junction structure is not epitaxially grown on top of the second photovoltaic p-n junction structure and the second photovoltaic p-n junction structure is not epitaxially grown on top of the first photovoltaic p-n junction structure.

The first photovoltaic p-n junction structure and the second photovoltaic p-n junction structure may each have a thickness selected from the range of 1 micron to 250 microns, or 2 microns to 200 microns, or 3 microns to 150 microns, or 4 microns to 100 microns, or 5 microns to 75 microns, or 10 microns to 50 microns.

In an embodiment, the first photovoltaic p-n junction structure comprises 1-4 p-n junctions and the second photovoltaic p-n junction structure comprises 1-3 p-n junctions, such that the first and second photovoltaic p-n junction structures may or may not comprise the same number of p-n junctions. In an embodiment, the first photovoltaic p-n junction structure comprises 2 or more p-n junctions, optionally 3 or more p-n junctions, and the second photovoltaic p-n junction structure comprises 2 or more p-n junctions, optionally 3 or more p-n junctions.

The first photovoltaic p-n junction structure and the second photovoltaic p-n junction structure may comprise different multi-junction structures having different quantities of p-n junctions, different compositions, different stacking structures, different physical, optical, thermal or electrical properties, different thicknesses and/or different lateral dimensions. For example, the first photovoltaic p-n junction structure may have a different composition than the second photovoltaic p-n junction structure. For example, the first photovoltaic p-n junction structure may have a composition selected from the group consisting of: InGaP/GaAs/InGaAsNSb; AlGaAs; InGaAlP and combinations of these, and the second photovoltaic p-n junction structure may have a composition selected from the group consisting of: a diffusion-junction Ge cell; InGaAs; InGaAsP; AlGaInAs and combinations of these. In another example, the first photovoltaic p-n junction structure and the second photovoltaic p-n junction structure absorb electromagnetic radiation of different wavelengths. In an embodiment, the first photovoltaic p-n junction structure absorbs electromagnetic radiation having a wavelength selected from the range of 300 nm to 1250 nm and the second photovoltaic p-n junction structure absorbs electromagnetic radiation having a wavelength selected from the range of 850 nm to 1800 nm.

In an embodiment, a multi-junction photovoltaic device further comprises one or more additional electronic components in electrical contact with the first photovoltaic p-n junction structure or the second photovoltaic p-n junction structure. The one or more additional electronic components may be selected from the group consisting of an electrode, a dielectric layer or any combinations of these.

In an embodiment, a multi-junction photovoltaic device further comprises one or more electrical contacts provided in a recessed region of the first interface surface or the second interface surface.

In an embodiment, a multi-junction photovoltaic device further comprises one or more additional optical components in optical communication with the first photovoltaic p-n junction structure or the second photovoltaic p-n junction structure. The one or more additional optical components may be selected from the group consisting of an antireflection coating, a concentrator, an optical filter, a window or any combinations of these.

In an embodiment, a multi-junction photovoltaic device further comprises one or more antireflection coatings on the first interface surface or the second interface surface.

In an aspect, a method for making a multi-junction photovoltaic device comprises the steps of: providing a first photovoltaic p-n junction structure characterized by a thickness and lateral dimensions, the first photovoltaic p-n junction structure having a first interface surface; providing a second photovoltaic p-n junction structure characterized by a thickness and lateral dimensions, the second photovoltaic p-n junction structure having a second interface surface; providing an interface layer between the first interface surface and the second interface surface, the interface layer comprising a chalcogenide dielectric layer; and contacting the first interface surface of the first photovoltaic p-n junction structure or the interface layer provided thereon with the second interface surface of the second photovoltaic p-n junction structure or the interface layer provided thereon, thereby making the multi-junction photovoltaic device having a stacked multilayer geometry. In an embodiment, the interface layer is on the first interface surface of the first photovoltaic p-n junction structure or the second interface surface of the second photovoltaic p-n junction structure.

In an embodiment, the step of providing a first photovoltaic p-n junction structure comprises: fabricating the first photovoltaic p-n junction structure via epitaxial growth on a mother substrate, wherein the first photovoltaic p-n junction structure is connected to the mother substrate via a sacrificial layer; and at least partially removing the sacrificial layer.

The contacting step may be carried out via an assembly technique selected from the group consisting of dry transfer printing, solution printing, pick and place assembly, and electrostatic transfer. In an embodiment, the contacting step further comprises: contacting a transfer surface of the first photovoltaic p-n junction structure with a contact surface of a conformal transfer device, wherein the first photovoltaic p-n junction structure is adhered to the contact surface; and contacting the first photovoltaic p-n junction structure adhered to the contact surface with the second photovoltaic p-n junction structure.

In an embodiment, a method for making a multi-junction photovoltaic device further comprises separating the first photovoltaic p-n junction structure and the conformal transfer device, thereby transferring the first photovoltaic p-n junction structure onto the second photovoltaic p-n junction structure.

In an embodiment, a method for making a multi-junction photovoltaic device further comprises moving the conformal transfer device having the first photovoltaic p-n junction structure adhered to the contact surface, thereby releasing the first photovoltaic p-n junction structure from a mother substrate; wherein the release involves fracture or disengagement of one or more alignment maintaining elements connecting the first photovoltaic p-n junction structure to the mother wafer. The first photovoltaic p-n junction structure may be provided in a selected orientation which is maintained by the one or more alignment maintaining elements during contact with the contact surface of the conformal transfer device.

In an embodiment, a method for making a multi-junction photovoltaic device further comprises contacting transfer surfaces of a first set of additional photovoltaic p-n junction structures with the contact surface of a conformal transfer device, wherein the first set of additional photovoltaic p-n junction structures is adhered to the contact surface; and contacting the additional photovoltaic p-n junction structures adhered to the contact surface with a second set of photovoltaic p-n junction structures; wherein contacting of the first set of additional photovoltaic p-n junction structures is carried out in parallel.

In an embodiment, the conformal transfer device comprises an elastomeric stamp. For example, the conformal transfer device may have a Young's modulus selected from the range of 0.2 MPa to 50 MPa and/or a flexural rigidity selected from the range of 1×10−7 Nm to 1×10−5 Nm.

In an aspect, a multi-junction photovoltaic device comprises a first photovoltaic p-n junction structure characterized by a thickness and lateral dimensions, the first photovoltaic p-n junction structure having a first interface surface; a second photovoltaic p-n junction structure characterized by a thickness and lateral dimensions, the second photovoltaic p-n junction structure having a second interface surface; an intermediate layer connecting at least a portion of the first photovoltaic p-n junction structure and at least a portion of the second photovoltaic p-n junction structure; wherein an air gap exists between at least a portion of the first interface surface of the first photovoltaic p-n junction structure and at least a portion of the second interface surface of the second photovoltaic p-n junction structure, thereby providing a stacked multilayer device geometry.

In an aspect, a method for making a multi-junction photovoltaic device comprises the steps of: providing a first photovoltaic p-n junction structure characterized by a thickness and lateral dimensions, the first photovoltaic p-n junction structure having a first interface surface; providing a second photovoltaic p-n junction structure characterized by a thickness and lateral dimensions, the second p-n junction having a second interface surface; providing an intermediate layer to connect at least a portion of the first photovoltaic p-n junction structure and at least a portion of the second photovoltaic p-n junction structure; wherein an air gap exists between at least a portion of the first interface surface of the first photovoltaic p-n junction structure and at least a portion of the second interface surface of the second photovoltaic p-n junction structure, thereby making the multi-junction photovoltaic device having a stacked multilayer geometry.

In an embodiment, at least one of the first photovoltaic p-n junction structure and the second photovoltaic p-n junction structure independently comprises a multi-junction structure, the multi-junction structure having 2, 3, 4, 5, or 6 photovoltaic p-n junctions.

In an aspect, a method for making a multi-junction photovoltaic device comprises the steps of: providing a first photovoltaic p-n junction structure characterized by a thickness and lateral dimensions, the first photovoltaic p-n junction structure having a first interface surface; providing a second photovoltaic p-n junction structure characterized by a thickness and lateral dimensions, the second photovoltaic p-n junction structure having a second interface surface; wherein at least one of the first photovoltaic p-n junction structure and the second photovoltaic p-n junction structure independently comprises a multi-junction structure; and wherein the lateral dimensions of the first photovoltaic p-n junction structure, the second photovoltaic p-n junction structure or both are independently selected from the range of 800 microns to 3000 microns; contacting a transfer surface of the first photovoltaic p-n junction structure with a contact surface of a conformal transfer device, wherein the first photovoltaic p-n junction structure is adhered to the contact surface; and contacting the first interface surface of the first photovoltaic p-n junction structure adhered to the contact surface, or an intermediate structure provided on the first photovoltaic p-n junction structure, with the second interface surface of the second photovoltaic p-n junction structure, or an intermediate structure provided on the second photovoltaic p-n junction structure, thereby making the multi-junction photovoltaic device having a stacked multilayer geometry.

In an embodiment, the step of contacting comprises aligning a first centerline of a first grid finger of the first photovoltaic p-n junction structure with a second centerline of a second grid finger of the second photovoltaic p-n junction structure with the first and second centerlines being within 2 μm of each other at all points. Alignment of the grid fingers between top and bottom subcells reduces shading of the subcell furthest from the sun and increases device efficiency.

Methods of making and using multi-junction photovoltaic devices disclosed herein may be implemented to produce or utilize all embodiments of the multi-junction photovoltaic devices disclosed herein.

Without wishing to be bound by any particular theory, there may be discussion herein of beliefs or understandings of underlying principles relating to the devices and methods disclosed herein. It is recognized that regardless of the ultimate correctness of any mechanistic explanation or hypothesis, an embodiment of the invention can nonetheless be operative and useful.

### BRIEF DESCRIPTION OF THE DRAWINGS

FIG. 1A. Schematic illustration of a multi-junction photovoltaic device, according to an exemplary embodiment.

FIG. 1B, FIG. 1C and FIG. 1D. Flowcharts of methods for making multi-junction photovoltaic devices, according to exemplary embodiments.

FIG. 2. Schematic illustrations and images of quadruple junction, four-terminal microscale solar cells assembled using a printing-based method and an As₂Se₃ interface material. (a) Schematic illustration of a cell from a 3J thin film stack of InGaP/GaAs/InGaAsNSb derived from epitaxial growth and liftoff and a separate 1J Ge cell, before (left) and after (right) assembly by transfer printing. The As₂Se₃ layer (blue) and the recessed metal contact lines on the top of the Ge cell ensure excellent optical, electrical and thermal properties at the interface. (b) and (c) SEM images (top and magnified tilted views) of a Ge cell before and after printing a 3J cell on top. (d) Optical micrograph of an array of 3J/Ge microscale solar cells. The bottom part of this image shows alignment features for the printing process, and several bare Ge cells. (d) SEM image (cross-sectional view) of a 3J/Ge cell, showing the aligned metal contact lines and the As₂Se₃ layer. Inset, high magnification image of the interface region.

FIG. 3. Image of a packaged quadruple junction microscale solar cell with separate terminal connections to the top 3J cell and the bottom Ge cell, and key performance parameters. (a) SEM image (top view) of an encapsulated and metallized 3J/Ge cell. (b) Current density (J)-voltage (V) curves for the top 3J cell under 1 sun and 1000 suns illumination. (c) J-V curves for the bottom Ge cell under the same conditions. (d) Cell efficiency (η), open-circuit voltage (V_{oc}) and fill factor (FF) as a function of concentration for the top 3J cell. (e) η, V_{oc} and FF as a function of concentration for the bottom Ge cell. The measured current density (J_{sc}) is assumed to be linearly proportional to the irradiance. The presented J_{sc} values are normalized to an irradiance of 1000 W/m². (f) Total, summed efficiency as a function of concentration. (g) Schematic illustrations of the EQE and measurements of the reflectance spectra of a 3J/Ge cell.

FIG. 4. Schematic illustrations of microscale quadruple junction structures assembled by printing with different interfaces, and comparisons of their electrical, optical and thermal properties. (a) Schematic illustrations of stacked 3J/Ge cells with different interfaces (300 nm As₂Se₃, 10 μm organic adhesive (NOA), and direct bond). (b) Leakage currents measured between the bottom contact of the top 3J cell and the top contact of the bottom Ge cell, as a function of applied voltage. (c) EQE spectra measured from the Ge cells. (d) Measured and (e) Simulated infrared reflectance spectra. (f) Measured and (g) Simulated temperature distributions associated with irradiation of the structures with a laser beam (center wavelength 488 nm, 0.15 W). Map size: 650 μm×650 μm.

FIG. 5. Images and performance of completed quadruple junction microscale solar cells with concentration optics. (a) Optical images of a diced stacked cell (left) and a cell with a secondary ball lens (right). (b) Side view (left) and top view (right) of a cell in a module with a secondary ball lens and a primary lens. (c) Ray-tracing analysis of a fully integrated module. (d) Calculated irradiance distribution under the incidence of the AM1.5D spectrum (power 1000 W/m²). (e) Current (I)-voltage (V) curves of the module measured on sun. Air Mass condition is 1.8. (f) Theoretically predicted I-V curve of a voltage-matched array with 10 interconnected cells. (g) Theoretically predicted I-V curve of a current-matched array with 3 interconnected cells. Insets show circuit diagrams.

FIG. 6. Process flow for fabricating 3J cells on a GaAs substrate with a releasable AlInP sacrificial layer.

FIG. 7. Process flow for fabricating Ge cells.

FIG. 8. Process flow for fabricating 3J/Ge cells by transfer printing.

FIG. 9. Schematic illustration for encapsulating assembled 3J/Ge cells in epoxy and metal deposition for contact pads.

FIG. 10. Schematic illustrations and SEM images of (a) a bare Ge cell, (b) an assembled 3J/Ge cell, and (c) an encapsulated 3J/Ge cell with metal contact pads.

FIG. 11. (a) Process flow for fabricating PDMS stamps. (b) Optical image of a PDMS stamp with a 10×10 post array. (c) SEM image of the PDMS stamp, including post and backing layer.

FIG. 12. (a) Process flow for fabricating assembled 3J/Ge cells using transfer printing. (b) SEM images (side view) of PDMS stamps with 3J cells, bare Ge cells and printed 3J/Ge cells. Images for 3J cells are colorized. Insets show magnified views of the cell structures. Reference for printing method: Carlson, A. et al. Shearenhanced adhesiveless transfer printing for use in deterministic materials assembly. Appl. Phys. Lett. 98, 264104 (2011).

FIG. 13. A photograph of the printing machine used to assemble the 3J/Ge solar cells. Reference on parallel, wafer-scale transfer printing process: Justice, J. et al. Wafer-scale integration of group III-V lasers on silicon using transfer printing of epitaxial layers. Nature Photonics 6, 610-614 (2012).

FIG. 14. Colorized infrared optical images of two assembled 3J/Ge cells with As₂Se₃ interface. Different colors indicate the difference in emissivity. (a) A cell with a perfectly bonded interface; (b) A cell exhibiting air voids due to unwanted particles at the interface during the printing process.

FIG. 15. Colorized infrared optical images of an assembled 3J/Ge cell with As₂Se₃ interface, (a) before and (b) after thermal cycling. Different colors indicate the difference in emissivity. The thermal cycling is performed by rapid heating (at 110° C. for 1 min on a hot plate) and cooling (at 20° C. for 1 min on a cold plate) for 10 cycles. No interface and performance degradations are observed.

FIG. 16. Optical image of a bottle with As₂Se₃ dissolved into ethylenediamine solution (0.2 g/mL).

FIG. 17. (a) AFM image of the back surface of a 3J cell. Measured RMS roughness 0.12 nm. (b) AFM image of a 300 nm As₂Se₃ film coated on a Ge cell. Measured RMS roughness 1.0 nm.

FIG. 18. Measured transmission spectrum of a 807 nm thick As₂Se₃ film coated on 1 mm thick glass. The measured refractive index for As₂Se₃ from 900 nm to 2000 nm is 2.67. Calculation is based on the method in: Swanepoel, R. Determination of the thickness and optical constants of amorphous silicon. J. Phys. E: Sci. Instrum. 16, 1214-1222 (1983).

FIG. 19. Differential scanning calorimetric (DSC) curve of As₂Se₃ films, showing glass transition temperature T_{g}=150° C., crystallization temperature T_{c}=250° C., and melting temperature Tₘ=370° C.

FIG. 20. Current-voltage curve of a 300 nm As₂Se₃ film with gold contacts on both sides, measured from −100 V to +100 V. Measured resistivity is 10¹³˜10¹⁴ Ω*cm.

FIG. 21. Properties of thin-film As₂Se₃ reported in literature.

FIG. 22. Transmission spectrum of a 10 μm thick InterVia 8023-10 film coated on 1 mm thick glass. The material is transparent above 500 nm, and has a refractive index of 1.56.

FIG. 23. Transmission spectrum of NOA 61 by Norland Products Inc. Further information can be found at www.norlandprod.com/adhesives/noa%2061.html.

FIG. 24. (a) Simulated reflection spectrum of a tri-layer ARC coated on GaAs. (b) Layer structure used in the simulation.

FIG. 25. (a) Measured and simulated reflection spectra for assembled 3J/Ge cells with different interfaces (also shown in FIGS. 4d and 4f). (b) Layer structure used in the simulation. A 10 μm thick GaAs layer is used in the simulation model to replace the actual 3J cell structure. Note that the 10 μm thick NOA layer is assumed to generate incoherent interference, due to the thickness non-uniformity. Transfer matrix method is used. Reference: Troparevsky, M. C. Transfer-matrix formalism for the calculation of optical response in multilayer systems: from coherent to incoherent interference. Opt. Express 18, 24715-24721 (2010). Details on the optical properties of different materials can be found in: Palik, E. Handbook of optical constants of solids (Academic Press, 1998).

FIG. 26. (a) Simulated reflection spectra for the 3J/Ge cell (using 300 nm As₂Se₃ as interface) with and without 10 nm adhesive layer (InterVia 8023-10), showing similar reflection responses. (b) Layer structure used in the simulation.

FIG. 27. (a) Simulated reflectance (averaged between 1300 nm and 1700 nm) for the stacked 3J/Ge cell as a function of the As₂Se₃ thickness at the interface. The results show that the interface reflection is slightly dependent on the As₂Se₃ thickness. (b) Layer structure used in the simulation.

FIG. 28. (a) Simulated reflection spectra for 3J/Ge cells with different interfaces, assuming a perfect ARC is applied between air and the cells. (b) Layer structure used in the simulation.

FIG. 29A. Measured current-voltage curves for a 3J cell under concentrations (˜1000 suns) when the Ge cell is at I_{sc}, V_{oc} or maximum power.

FIG. 29B. Measured current-voltage curves for a Ge cell under concentrations (˜1000 suns) when the 3J cell is at I_{sc}, V_{oc} or maximum power. The results in FIGS. 29A and 29B show that the 3J cell and the Ge cell in the stack work independently without optical and electronic coupling.

FIG. 30. Measured current-voltage curves between the bottom p-contact for the 3J cell and the top n-contact for the Ge cell, for cells with different interfaces (also shown in FIG. 4b). The resistivities for As₂Se₃ and NOA are measured to be ˜1010 Ω*cm and ˜1011 Ω*cm, respectively.

FIG. 31. (a) Experimental setup for temperature measurements under laser heating. (b) Layer structure and material properties used in thermal simulations by Finite Element Analysis (FEA). Experiment and simulation results are shown in FIGS. 4f and 4g, respectively. An interfacial thermal conductivity of 85000 W/K/m² (very good thermal contact) is prescribed to simulate the contact interface between the Ge substrates and the stainless steel based optical stage.

FIG. 32. Simulated FEA results for Tresca stresses at the interface between 3J cells and its adjacent interface layers under laser heating, for the cases of (a) 300 nm As₂Se₃; (b) 10 μm NOA; (c) direct bonding. The unit shown in scale bars is Pa.

FIG. 33. (a) I-V curves for an assembled 3J/Ge cell module with concentration optics (FIGS. 5a and 5b). A pair of curves, one for the 3J cell and the other for the Ge cell, were collected under a range of air mass conditions corresponding to different times of the day. (b) Total efficiency (3J+Ge) versus air mass as measured on sun by comparison to simultaneously measured direct normal irradiance (DNI): efficiency=Pₘₐₓ/(DNI*Aperture area).

FIG. 34. On-sun module light-IVdata and adjustment to account for cell heating in-module. (a) method for determining module performance with cell temperature at 25° C. (b) raw light-IVdata from on-sun module measurements and adjusted curves obtained through the method of (a). (c) tabulated V_{oc} data from raw on-sun module measurements and indoor measurements. Air Mass at the time of measurement was 1.8, DNI was 914 W/m², and air temperature was 14° C. For indoor measurements, 4 lasers were selected to excite each sub-cell. Lasers were tuned to match currents in each of the 3 upper sub-cells and to produce roughly half of the current in the Ge cell. dV_{oc}/dT values for the 3J cell were determined using the same laser set-up, varying the temperature of the chuck underneath the cells. dV_{oc}/dT for the Ge cell was estimated at one third of the value of dV_{oc}/dT for the 3J.

FIG. 35. Statistical variations in I_{sc}, V_{oc}, FF and power measured for 10 bare Ge cells (no stack, no ARC) under standard AM1.5D one-sun illumination.

FIG. 36. Statistical variations in I_{sc}, V_{oc}, FF and power measured for about 4000 3J cells released on a ceramic substrate, under concentrated illumination (with a power equivalent to ˜400 suns).

FIG. 37. Designed voltage matching interconnected scheme and equivalent circuit diagram for a module array with 10 3J/Ge cells.

FIG. 38. Designed current matching interconnected scheme and equivalent circuit diagram for a module array with 3 3J/Ge cells.

FIG. 39. Theoretically predicted module performance including the measured cell variation results (FIGS. 35 and 36), assuming both measured current and voltage have a standard deviation of about 1%. (a) Voltage-matching design. (b) Current-matching design.

FIG. 40. Schematic illustrations of the different photon dynamics in MJ solar cells with a) a high-index interface and b) a low-index interface.

FIG. 41. a) Schematic illustrations of GaAs DH layers on substrates with different interface materials. b) Measured PL intensity decays. c) Plot of the relationship between PL decay, lifetime rand interface refractive index n. In agreement with theory, 1/τ is linearly proportional to n_{sub}²+1.

FIG. 42. a) Schematic illustrations of GaAs microscale solar cells on substrates with different interface materials. b) Optical microscope image (top view) of a GaAs cell (0.7 mm×0.7 mm) with ohmic contacts. c) Cross sectional device layout of the GaAs cell. d) SEM image (tilted view) of a GaAs cell printed on patterned SU-8, with a 25 μm air gap in between. e) Measured current-voltage characteristic for a GaAs cell under AM1.5g illumination.

FIG. 43. a) Calculated behavior of V_{oc} for ideal GaAs cells on substrates with different refractive indices, at different internal luminescent efficiency ηᵢₙₜ. b) Measured V_{oc} for micro GaAs cells on different substrates (air, SU-8 and GaAs). c) Measured I_{sc} for micro GaAs cells on different substrates (air, SU-8 and GaAs).

FIG. 44. a) Simulated and measured maximum temperatures reached on the front surfaces for cells on different substrates, as a function of absorbed laser power. b) Measured and simulated temperature distributions on cell surfaces with an absorbed laser power of 0.13 W. Map size: 0.7 mm×0.7 mm. c) Simulated optical reflectance at the cell/air gap interface and maximum temperature for a cell with the air gap interface with an absorbed laser power of 0.13 W, as a function of the air gap thickness. Inset: measured temperature distributions on a GaAs cell printed on Si with a 500 nm thick air gap.

FIG. 45. a) Schematic illustration of a MJ cell structure with an air gap interface and ARCs at all the semiconductor/air interfaces. b) SEM image (tilted view) of a Si thin film (size 0.7 mm×0.7 mm, 10 μm thick) printed on a Ge substrate with an air gap interface formed by patterned SU-8 posts, as a proof of concept demonstration. c) Measured and d) Simulated reflectance spectra for the Si/air gap/Ge stacked structures with and without ARCs made by 150 nm ALD HfO₂.

### DETAILED DESCRIPTION OF THE INVENTION

In general, the terms and phrases used herein have their art-recognized meaning, which can be found by reference to standard texts, journal references and contexts known to those skilled in the art. The following definitions are provided to clarify their specific use in the context of the invention.

“P-N junction” refers to a direct boundary or direct interface between a p-doped material and an n-doped material. A p-n junction may be formed by doped regions within a single crystalline material or by epitaxially growing doped materials in contact with one another. A p-n junction comprises at least one p-doped region/material and at least one n-doped region/material. In some embodiments, a p-n junction comprises a plurality of p-doped regions/materials, a plurality of n-doped regions/materials, or a plurality of both p-doped and n-doped regions/materials.

“Tunnel junction” refers to an insulating layer between consecutive p-n junctions.

“Photovoltaic p-n junction structure” refers to a structure comprising one or more p-n junctions and configured for conversion of electromagnetic energy into electricity. In an embodiment, a photovoltaic p-n junction structure is a multi-junction structure comprising a plurality of p-n junctions, e.g., 2, 3, 4 or more p-n junctions. In an embodiment, a photovoltaic p-n junction structure that is configured for conversion of electromagnetic energy into electricity absorbs energy in the ultraviolet and/or visible portion of the electromagnetic spectrum.

“Module” refers to a device comprising at least one p-n junction in physical, thermal, optical and/or electrical communication with at least one additional device that also comprises at least one p-n junction. For example, a plurality of photovoltaic devices or PV cells, each comprising one or more p-n junctions, may be configured in a solar module or panel.

“Array” refers to a plurality of modules in physical, thermal, optical and/or electrical communication with one another. For example, a plurality of solar modules or panels may be configured as a solar array.

“Chalcogenide” refers to a chemical compound comprising at least one element selected from the group consisting of oxygen, sulfur, selenium and tellurium. “Non-oxide chalcogenide” or “chalcogenide glass” refers to a chemical compound comprising at least one element selected from the group consisting of sulfur, selenium and tellurium. “Non-sulfide chalcogenide” refers to a chemical compound comprising at least one element selected from the group consisting of oxygen, selenium and tellurium. “Non-selenium chalcogenide” refers to a chemical compound comprising at least one element selected from the group consisting of oxygen, sulfur and tellurium. “Non-tellurium chalcogenide” refers to a chemical compound comprising at least one element selected from the group consisting of oxygen, sulfur and selenium. Any one of these compounds may be a binary, ternary or quaternary compound.

In an embodiment, a chalcogenide compound has the formula X_{N}Y_{Z} (FX1), where X is a metal, Y is an element selected from the group consisting of sulfur, selenium and tellurium, N is an integer selected from a range of 1 to 3, and Z is an integer selected from a range of 1 to 4. In an embodiment, a chalcogenide compound has the formula X_{N}Y_{Z} (FX1), where X is arsenic, Y is an element selected from the group consisting of sulfur, selenium and tellurium, N is an integer selected from a range of 1 to 3, and Z is an integer selected from a range of 1 to 4. In an embodiment, a chalcogenide compound has the formula X_{N}Y_{Z} (FX1), where X is a metal, Y is selenium, N is an integer selected from a range of 1 to 3, and Z is an integer selected from a range of 1 to 4. In an embodiment, a chalcogenide compound has the formula X_{N}Y_{Z} (FX1), where X is arsenic, Y is selenium, N is an integer selected from a range of 1 to 3, and Z is an integer selected from a range of 1 to 4.

“Transferable” or “printable” are used interchangeably and relate to materials, structures and/or device components that are capable of transfer, assembly, patterning, organizing and/or integrating onto or into substrates. In an embodiment, transferring or printing refers to the direct transfer of a structure or element from one substrate to another substrate. Alternatively, transferable refers to a structure or element that is printed via an intermediate substrate, such as a stamp that lifts-off the structure or element and then subsequently transfers the structure or element to a device substrate or a component that is on a device substrate. In an embodiment, the printing occurs without exposure of the substrate to high temperatures (i.e. at temperatures less than or equal to about 400 degrees Celsius). In one embodiment, printable or transferable materials, elements, device components and devices are capable of transfer, assembly, patterning, organizing and/or integrating onto or into substrates via solution printing or dry transfer contact printing. Similarly, “printing” is used broadly to refer to the transfer, assembly, patterning, organizing and/or integrating onto or into substrates, such as a substrate that functions as a stamp or a substrate that is itself a target (e.g., device) substrate. Such a direct transfer printing provides low-cost and relatively simple repeated transfer of a functional top-layer of a multilayer structure to a device substrate. This achieves blanket transfer from, for example, a growth substrate to a target substrate without the need for a separate stamp substrate.

“Substrate” refers to a material having a surface that is capable of supporting a component, including a device, component or an interconnect. “Host substrate” and “handle substrate” interchangeably refer to a substrate on which a device is assembled, processed or otherwise manipulated. In certain embodiments, a handle substrate is a substrate useful as a transitory substrate, for example for holding structures for subsequent transfer to another substrate, such as by transfer printing. In some embodiments, a handle substrate is useful as a processing substrate, where structures present on the handle substrate undergo additional processing steps. “Growth substrate” refers to a substrate useful for growing material, for example via epitaxial growth. In embodiments, a growth substrate comprises the same material as is being grown. In embodiments, a growth substrate comprises material different from that being grown. Useful growth substrates include substrates which are lattice matched, or effectively lattice matched, to the material being grown. In some embodiments, a growth substrate is a host substrate. “Device substrate” refers to a substrate useful for assembling device components. In some embodiments, a device substrate comprises functional device components. In some embodiments, a device substrate is a flexible substrate, a large area substrate, a pre-metalized substrate, a substrate pre-patterned with one or more device components, or any combination of these. In some embodiments, a device substrate is a host substrate.

The term “surface” as used herein is intended to be consistent with its plain meaning which refers to an outer boundary of an object. In embodiments, surfaces may be given specific names, such as “receiving surface”, “contact surface”, “external surface”. In some embodiments, named surfaces can refer to their target use and/or identify subregions of a surface. In some embodiments, named surfaces can refer to their orientation, for example relative to other nearby or adjacent components.

“Release layer” (sometimes referred to as “sacrificial layer”) refers to a layer that at least partially separates one or more functional layers. A release layer is capable of being removed or providing other means for facilitating separation of the functional layer from other layers of a multi-layer structure, such as by a release layer that physically separates in response to a physical, thermal, chemical and/or electromagnetic stimulation, for example. Accordingly, the actual release layer composition is selected to best match the means by which separation will be provided. Means for separating is by any one or more separating means known in the art, such as by interface failure or by release layer sacrifice. A release layer may itself remain connected to a functional layer, such as a functional layer that remains attached to the remaining portion of the multilayer structure, or a functional layer that is separated from the remaining portion of the multilayer structure. The release layer is optionally subsequently separated and/or removed from the functional layer.

“Release” and “releasing” refer to at least partially separating two layers, devices or device components from one another, for example by mechanical or physical separation, or by removal of at least a portion of one layer, device or device component. In some embodiments, removal of a sacrificial layer results in the release of a layer, device or device component. In some embodiments, layers, devices or device components are released by etching away a portion of the layer, device or device component. In certain embodiments, released components remain attached to the object they are released from by one or more anchors. In some embodiments, released components are subsequently attached to the object they are released from by one or more anchors.

“Etch” and “etching” refer to a process by which a portion of a layer, device or device component is reacted away, dissolved or otherwise removed. In embodiments, an anisotropic etch or a directional etch refers to an etching process which preferentially removes material along a specific direction. In embodiments, a wet etch refers to removal of material by exposure to a solution. In embodiments, a selective etch refers to removal of a specific material or class of materials. In embodiments, a reactive ion etch or an inductively coupled plasma reactive ion etch refers to an etching method which utilizes a plasma to etch away material, for example by reaction with ions in the plasma. The term “etchant” is used in the present description to broadly refer to a substance which is useful for removal of material by etching. The term “electrochemical etching” refers to an etching process which utilizes an applied electric potential, electric field or electric current. The term “photoelectrochemical etching” refers to an etching process which utilizes an applied electric potential, electric field or electric current and exposure to electromagnetic radiation.

An “etch mask” refers to material useful for preventing underlying material from being etched. In some embodiments, a thick etch mask refers to an etch mask of a sufficient thickness that the majority of the mask remains after an etching process. In embodiments a thick etch mask has a thickness selected over the range of 100 nm to 5 μm. In some embodiments a metal etch mask refers to an etch block layer.

The term “mask” refers to a material which covers or otherwise blocks portions of an underlying material. Use of the term “mask” is intended to be consistent with use of the term in the art of microfabrication. In embodiments, the term “mask” refers to an etch mask, an optical mask, a deposition mask or any combination of these.

The terms “masked region” and “exposed region” respectively refer to portions of an underlying material which are blocked and unblocked by a mask.

“Epitaxial regrowth” and “epitaxial growth” refer to a method of growing a crystalline layer by deposition of material, for example gas or liquid phase deposition. The term “epilayer” refers to a layer grown via epitaxial growth.

The term “patterning” is used herein as in the art of microfabrication to broadly refer to a process by which portions of a layer, device or device component are selectively removed or deposited to create a specified structure.

“Supported by a substrate” refers to a structure that is present at least partially on a substrate surface or present at least partially on one or more intermediate structures positioned between the structure and the substrate surface. The term “supported by a substrate” may also refer to structures partially or fully embedded in a substrate.

“Contact printing” refers broadly to a dry transfer contact printing method such as with a stamp that facilitates transfer of features from a stamp surface to a substrate surface. In an embodiment, the stamp is an elastomeric stamp. Alternatively, the transfer can be directly to a target (e.g., device) substrate or host substrate. The following references relate to self assembly techniques which may be used in methods of the present invention to transfer, assemble and interconnect transferable elements via contact printing and/or solution printing techniques and are incorporated by reference in their entireties herein: (1) “Guided molecular self-assembly: a review of recent efforts”, Jiyun C Huie Smart Mater. Struct. (2003) 12, 264-271; (2) “Large-Scale Hierarchical Organization of Nanowire Arrays for Integrated Nanosystems”, Whang, D.; Jin, S.; Wu, Y.; Lieber, C. M. Nano Lett. (2003) 3(9), 1255-1259; (3) “Directed Assembly of One-Dimensional Nanostructures into Functional Networks”, Yu Huang, Xiangfeng Duan, Qingqiao Wei, and Charles M. Lieber, Science (2001) 291, 630-633; and (4) “Electric-field assisted assembly and alignment of metallic nanowires”, Peter A. Smith et al., Appl. Phys. Lett. (2000) 77(9), 1399-1401.

Useful contact printing methods for assembling, organizing and/or integrating transferable elements include dry transfer contact printing, microcontact or nanocontact printing, microtransfer or nanotransfer printing and self assembly assisted printing. Use of contact printing is beneficial because it allows assembly and integration of a plurality of transferable elements in selected orientations and positions relative to each other. Contact printing also enables effective transfer, assembly and integration of diverse classes of materials and structures, including semiconductors (e.g., inorganic semiconductors, single crystalline semiconductors, organic semiconductors, carbon nanomaterials etc.), dielectrics, and conductors. Contact printing methods optionally provide high precision registered transfer and assembly of transferable elements in preselected positions and spatial orientations relative to one or more device components prepatterned on a device substrate. Contact printing is also compatible with a wide range of substrate types, including conventional rigid or semi-rigid substrates such as glasses, ceramics and metals, and substrates having physical and mechanical properties attractive for specific applications, such as flexible substrates, bendable substrates, shapeable substrates, conformable substrates and/or stretchable substrates. Contact printing assembly of transferable structures is compatible, for example, with low temperature processing (e.g., less than or equal to 298K). This attribute allows the present optical systems to be implemented using a range of substrate materials including those that decompose or degrade at high temperatures, such as polymer and plastic substrates. Contact printing transfer, assembly and integration of device elements is also beneficial because it can be implemented via low cost and high-throughput printing techniques and systems, such as roll-to-roll printing and flexographic printing methods and systems.

“Functional layer” refers to a device-containing layer that imparts some functionality to the device. For example, the functional layer may be a thin film such as a semiconductor layer. Alternatively, the functional layer may comprise multiple layers, such as multiple semiconductor layers separated by support layers. The functional layer may comprise a plurality of patterned elements, such as interconnects running between device-receiving pads or islands.

“Multilayer” refers to a plurality of functional layers in a stacked configuration.

“Semiconductor” refers to any material that is an insulator at very low temperatures, but which has an appreciable electrical conductivity at a temperature of about 300 Kelvin. In the present description, use of the term semiconductor is intended to be consistent with use of this term in the art of microelectronics and electrical devices. Useful semiconductors include elemental semiconductors, such as silicon, germanium and diamond, and compound semiconductors, such as group IV compound semiconductors such as SiC and SiGe, group III-V semiconductors such as AlSb, AlAs, AIn, AlP, BN, GaSb, GaAs, GaN, GaP, InSb, InAs, InN, and InP, group III-V ternary semiconductors alloys such as AlxGa1-xAs, group II-VI semiconductors such as CsSe, CdS, CdTe, ZnO, ZnSe, ZnS; and ZnTe, group I-VII semiconductors CuCl, group IV-VI semiconductors such as PbS, PbTe and SnS, layer semiconductors such as PbI₂, MoS₂ and GaSe, oxide semiconductors such as CuO and Cu₂O. The term semiconductor includes intrinsic semiconductors and extrinsic semiconductors that are doped with one or more selected materials, including semiconductors having p-type doping materials (also known as P-type or p-doped semiconductors) and n-type doping materials (also known as N-type or n-doped semiconductors), to provide beneficial electrical properties useful for a given application or device. The term semiconductor includes composite materials comprising a mixture of semiconductors and/or dopants. Useful specific semiconductor materials include, but are not limited to, Si, Ge, SiC, AlP, AlAs, AlSb, GaN, GaP, GaAs, GaSb, InP, InAs, GaSb, InSb, ZnO, ZnSe, ZnTe, CdS, CdSe, ZnSe, ZnTe, CdTe, HgS, PbS, PbSe, PbTe, AlGaAs, AlInAs, AlInP, GaAsP, GaInAs, GaInP, AlGaAsSb, AlGaInP, and GaInAsP. Impurities of semiconductor materials are atoms, elements, ions and/or molecules other than the semiconductor material(s) themselves or any dopants provided to the semiconductor material. Impurities are undesirable materials present in semiconductor materials which may negatively impact the electrical properties of semiconductor materials, and include but are not limited to oxygen, carbon, and metals including heavy metals. Heavy metal impurities include, but are not limited to, the group of elements between copper and lead on the periodic table, calcium, sodium, and all ions, compounds and/or complexes thereof.

A “semiconductor component” broadly refers to any semiconductor material, composition or structure, and expressly includes high quality single crystalline and polycrystalline semiconductors, semiconductor materials fabricated via high temperature processing, doped semiconductor materials, inorganic semiconductors, and composite semiconductor materials.

“Plastic” refers to any synthetic or naturally occurring material or combination of materials that can be molded or shaped, generally when heated, and hardened into a desired shape. Useful plastics include, but are not limited to, polymers, resins and cellulose derivatives. In the present description, the term plastic is intended to include composite plastic materials comprising one or more plastics with one or more additives, such as structural enhancers, fillers, fibers, plasticizers, stabilizers or additives which may provide desired chemical or physical properties.

“Prepolymer” refers to a material which is a polymer precursor and/or a material which, when cured, is a polymer. A “liquid prepolymer” refers to a prepolymer which exhibits one or more properties of a liquid, for example flow properties. Specific prepolymers include, but are not limited to, photocurable polymers, thermally curable polymers and photocurable polyurethanes.

“Curing” refers to a process by which a material is transformed such that the transformed material exhibits one or more properties different from the original, non-transformed material. In some embodiments, a curing process allows a material to become solid or rigid. In an embodiment, curing transforms a prepolymer material into a polymer material. Useful curing processes include, but are not limited to, exposure to electromagnetic radiation (photocuring processes), for example exposure to electromagnetic radiation of a specific wavelength or wavelength range (e.g., ultraviolet or infrared electromagnetic radiation); thermal curing processes, for example heating to a specific temperature or within a specific temperature range (e.g., 150° C. or between 125 and 175° C.); temporal curing processes, for example waiting for a specified time or time duration (e.g., 5 minutes or between 10 and 20 hours); drying processes, for example removal of all or a percentage of water or other solvent molecules; and any combination of these. For example, one embodiment for curing a silver epoxy comprises heating the silver epoxy to 150° C. for a duration of 5 minutes.

“Polymer” refers to a molecule comprising a plurality of repeating chemical groups, typically referred to as monomers. Polymers are often characterized by high molecular masses. Useful polymers include organic polymers and inorganic polymers, both of which may be in amorphous, semi-amorphous, crystalline or partially crystalline states. Polymers may comprise monomers having the same chemical composition or may comprise a plurality of monomers having different chemical compositions, such as a copolymer. Cross linked polymers having linked monomer chains are also useful for some embodiments. Useful polymers include, but are not limited to, plastics, elastomers, thermoplastic elastomers, elastoplastics, thermostats, thermoplastics and acrylates. Exemplary polymers include, but are not limited to, acetal polymers, biodegradable polymers, cellulosic polymers, fluoropolymers, nylons, polyacrylonitrile polymers, polyamide-imide polymers, polyimides, polyarylates, polybenzimidazole, polybutylene, polycarbonate, polyesters, polyetherimide, polyethylene, polyethylene copolymers and modified polyethylenes, polyketones, polymethylmethacrylate, polymethylpentene, polyphenylene oxides and polyphenylene sulfides, polyphthalamide, polypropylene, polyurethanes, styrenic resins, sulfone based resins, vinyl-based resins or any combinations of these.

“Elastomeric stamp” and “elastomeric transfer device” are used interchangeably and refer to an elastomeric material having a surface that can receive as well as transfer a material. Exemplary conformal transfer devices useful in some methods of the invention include elastomeric transfer devices such as elastomeric stamps, molds and masks. The transfer device affects and/or facilitates material transfer from a donor material to a receiver material. In an embodiment, a method of the invention uses a conformal transfer device, such as an elastomeric transfer device (e.g. elastomeric stamp) in a microtransfer printing process, for example, to transfer one or more structures from a fabrication substrate to a device substrate.

“Elastomer” refers to a polymeric material which can be stretched or deformed and return to its original shape without substantial permanent deformation. Elastomers commonly undergo substantially elastic deformations. Useful elastomers may comprise polymers, copolymers, composite materials or mixtures of polymers and copolymers. An elastomeric layer refers to a layer comprising at least one elastomer. Elastomeric layers may also include dopants and other non-elastomeric materials. Useful elastomer embodiments include, but are not limited to, thermoplastic elastomers, styrenic materials, olefinic materials, polyolefin, polyurethane thermoplastic elastomers, polyamides, synthetic rubbers, PDMS, polybutadiene, polyisobutylene, poly(styrene-butadiene-styrene), polyurethanes, polychloroprene and silicones.

“Transfer device” or “transfer substrate” refers to a substrate, device or device component capable of and/or configured for receiving and/or relocating an element or array of elements, such as printable elements. Useful transfer devices include conformal transfer devices, such as devices having one or more contact surfaces capable of establishing conformal contact with elements undergoing transfer. An elastomeric stamp and/or transfer device is useful with a variety of the methods and devices described herein. Useful elastomeric transfer devices include, but are not limited to, elastomeric stamps, composite elastomeric stamps, an elastomeric layer, a plurality of elastomeric layers and an elastomeric layer coupled to a substrate such as a glass, ceramic, metal or polymer substrate.

“Target substrate” is used broadly to refer to the desired final substrate that will support the transferred structure. In an embodiment, the target substrate is a device substrate. In an embodiment, the target substrate is a device component or element that is itself supported by a substrate.

“Electrical contact” and “electrical communication” refer to the arrangement of one or more objects such that an electric current efficiently flows from one object to another. For example, in some embodiments, two objects having an electrical resistance between them less than 100Ω are considered to be in electrical communication with one another. An electrical contact can also refer to a component of a device or object used for establishing electrical communication with external devices or circuits, for example an electrical interconnection.

“Electrical resistivity” refers to a property of a material characteristic of the resistance to flow of electrons through the material. In certain embodiments, the resistivity of a material (ρ) is related to the resistance (R) of a length of material (L) having a specific cross sectional area (A), e.g., ρ=R×A/L.

“Electrical interconnection” and “electrical interconnect” refers to a component of an electrical device used for providing electrical communication between two or more device components. In some embodiments, an electrical interconnect is used to provide electrical communication between two device components spatially separated from one another, for example spatially separated by a distance greater than 50 nm, for some applications greater than 100 nm, for other applications greater than 1 μm, and for yet other applications greater than 50 μm. “Electrode contact” refers to a component of an electronic device or device component to which an electrical interconnect attaches or provides electrical communication.

“Embed” refers to a process by which one object or device is buried, conformally surrounded or otherwise placed or positioned within or below the surface of another object, layer or material.

“Encapsulate” refers to the orientation of one structure such that it is at least partially, and in some cases completely, surrounded by one or more other structures, such as a substrate, adhesive layer or encapsulating layer. “Partially encapsulated” refers to the orientation of one structure such that it is partially surrounded by one or more other structures, for example, wherein 30%, or optionally 50% or optionally 90%, of the external surfaces of the structure is surrounded by one or more structures. “Completely encapsulated” refers to the orientation of one structure such that it is completely surrounded by one or more other structures. Some embodiments contemplate devices having partially or completely encapsulated devices, device components and/or electrodes.

“Relief feature” refers to portions of an object or layer exhibiting differences in elevation and slope between the higher and lower parts of the surface of a given area or portion of the object or layer. “Raised features” refer to relief features which extend above the surface or average surface level of an object or layer or relief features which have elevations higher than other portions of the surface of an object or layer.

“Recessed feature” refer to relief features which extend below the surface or average surface level of an object or layer or relief features which have elevations lower than other portions of the surface of an object or layer.

“Conformable” refers to a device, material or substrate which has a bending stiffness that is sufficiently low to allow the device, material or substrate to adopt any desired contour profile, for example a contour profile allowing for conformal contact with a surface having a pattern of relief features.

“Conformal contact” refers to contact established between surfaces, coated surfaces, and/or surfaces having materials deposited thereon which may be useful for transferring, assembling, organizing and integrating structures (such as printable elements) on a substrate surface. In one aspect, conformal contact involves a macroscopic adaptation of one or more contact surfaces of a conformal transfer device to the overall shape of a substrate surface or the surface of an object such as a printable element. In another aspect, conformal contact involves a microscopic adaptation of one or more contact surfaces of a conformal transfer device to a substrate surface leading to an intimate contact without voids. The term conformal contact is intended to be consistent with use of this term in the art of soft lithography. Conformal contact may be established between one or more bare contact surfaces of a conformal transfer device and a substrate surface. Alternatively, conformal contact may be established between one or more coated contact surfaces, for example contact surfaces having a transfer material, printable element, device component, and/or device deposited thereon, of a conformal transfer device and a substrate surface. Alternatively, conformal contact may be established between one or more bare or coated contact surfaces of a conformal transfer device and a substrate surface coated with a material such as a transfer material, solid photoresist layer, prepolymer layer, liquid, thin film or fluid.

“Bind” and “bond” refer to the physical attachment of one object to another. Bind and bound can also refer the retention of one object on another. In one embodiment, an object can bind to another by establishing a force between the objects. In some embodiments, objects are bound to one another through use of an adhesion layer. In one embodiment, an adhesion layer refers to a layer used for establishing a bonding force between two objects.

“Placement accuracy” refers to the ability of a transfer method or device to transfer a printable element, to a selected position, either relative to the position of other device components, such as electrodes, or relative to a selected region of a receiving surface. “Good placement accuracy” refers to methods and devices capable of transferring a printable element to a selected position relative to another device or device component or relative to a selected region of a receiving surface with spatial deviations from the absolutely correct position less than or equal to 50 microns, more preferably less than or equal to 20 microns for some applications and even more preferably less than or equal to 5 microns for some applications. Methods and devices described herein include those comprising at least one printable element transferred with good placement accuracy.

“Fidelity” refers to a measure of how well a selected pattern of elements, such as a pattern of printable elements, is transferred to a receiving surface of a substrate. Good fidelity refers to transfer of a selected pattern of elements wherein the relative positions and orientations of individual elements are preserved during transfer, for example wherein spatial deviations of individual elements from their positions in the selected pattern are less than or equal to 500 nanometers, more preferably less than or equal to 100 nanometers.

“Undercut” refers to a structural configuration wherein the bottom surface(s) of an element, such as a printable element, are at least partially detached from or not fixed to another structure, such as a mother wafer or bulk material. Entirely undercut refers to a structural configuration wherein the bottom surface(s) of an element, such as printable element, is completely detached from another structure, such as a mother wafer or bulk material. Undercut structures may be partially or entirely free standing structures. Undercut structures may be partially or fully supported by another structure, such as a mother wafer or bulk material, that they are detached from. Undercut structures may be attached, affixed and/or connected to another structure, such as a wafer or other bulk material, at surfaces other than the bottom surface(s).

“Anchor” refers to a structure useful for connecting or tethering one device or device component to another. “Anchoring” refers to a process resulting in the connection or tethering of one device or device component to another.

“Dielectric” and “dielectric material” are used synonymously in the present description and refer to a substance that is highly resistant to flow of electric current. Useful dielectric materials include, but are not limited to, SiO₂, Ta₂O₅, TiO₂, ZrO₂, Y₂O₃, Si₃N₄, STO, BST, PLZT, PMN, and PZT.

“Conductive material” refers to a substance or compound possessing an electrical resistivity which is typical of or equivalent to that of a metal, for example copper, silver or aluminum. In embodiments, the electrical resistivity of a conductive material is selected over the range of 1×10⁻¹⁰ to 1×10⁻² Ω·cm. In the present description, use of the term conductive material is intended to be consistent with use of this term in the art of electronic devices and electric circuits. In embodiments, conductive materials are useful as electrical interconnections and/or for providing electrical communication between two devices.

The terms “directly and indirectly” describe the actions or physical positions of one component relative to another component. For example, a component that “directly” acts upon or touches another component does so without intervention from an intermediary. Contrarily, a component that “indirectly” acts upon or touches another component does so through an intermediary (e.g., a third component).

“Young's modulus” refers to a mechanical property of a material, device or layer which refers to the ratio of stress to strain for a given substance. Young's modulus may be provided by the expression;

$$E = \frac{( stress )}{( strain )} = ( \frac{{L}_{0}}{Δ L} \times \frac{F}{A} )$$

where E is Young's modulus, L₀ is the equilibrium length, ΔL is the length change under the applied stress, F is the force applied and A is the area over which the force is applied. Young's modulus may also be expressed in terms of Lame constants via the equation:

$$E = \frac{μ ( 3 λ + 2 μ )}{λ + μ}$$

where μ and λ are Lame constants. High Young's modulus (or “high modulus”) and low Young's modulus (or “low modulus”) are relative descriptors of the magnitude of Young's modulus in a given material, layer or device. In the present description, a high Young's modulus is larger than a low Young's modulus, about 10 times larger for some applications, more preferably about 100 times larger for other applications and even more preferably about 1000 times larger for yet other applications.

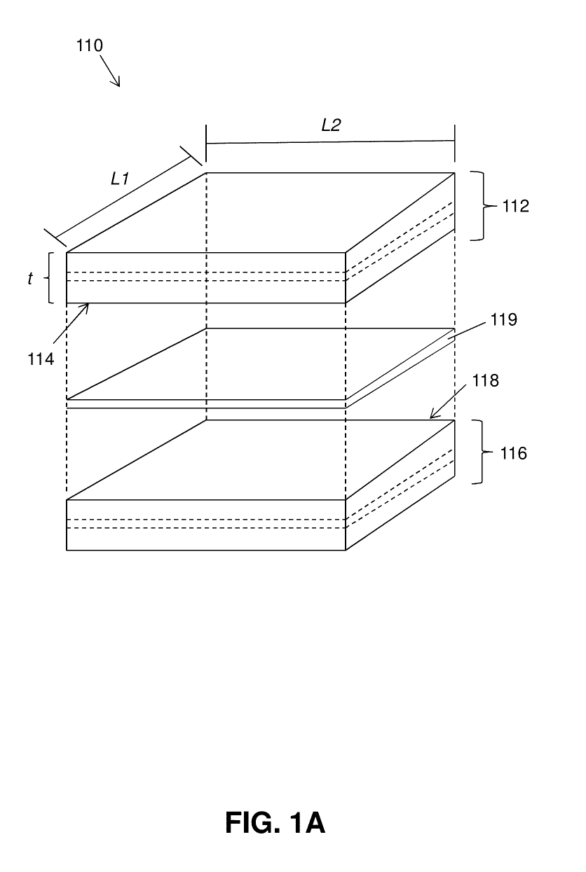

FIG. 1A shows a schematic of a multi-junction photovoltaic device 110 comprising a first photovoltaic p-n junction structure 112 and a second photovoltaic p-n junction structure 116, both characterized by a thickness, t, and lateral dimensions, L1 and L2. “Lateral dimensions” refer to measurement in the plane of a layer, e.g., a length or a width. Accordingly, a lateral dimension is perpendicular to a thickness of a layer. Dashed lines within photovoltaic p-n junction structures 112 and 116 show optional functional layers. First photovoltaic p-n junction structure 112 has a first interface surface114 and second photovoltaic p-n junction structure 116 has a second interface surface 118. In an embodiment, first interface surface 114 of first photovoltaic p-n junction structure 112 is provided in direct or indirect contact with second interface surface 118 of second photovoltaic p-n junction structure 116. As an example of indirect contact, an interface layer 119 may be provided between first interface surface 114 and second interface surface 118. For example, interface layer 119 may comprise a chalcogenide dielectric layer. Further, dashed lines in FIG. 1A show how first photovoltaic p-n junction structure 112, optional interface layer 119, and second photovoltaic p-n junction structure 116 may be combined in a stacked multilayer geometry. For example, the lateral dimensions of first photovoltaic p-n junction structure 112 or second photovoltaic p-n junction structure 116 may independently be less than or equal to 3000 microns.

FIG. 1B shows a flowchart 120 of a method for making a multi-junction photovoltaic device. The process begins with steps 122 and 124 of providing first and second photovoltaic p-n junction structures, such as structures 112 and 116 of FIG. 1A. In step 126, an interface layer, such as layer 119 of FIG. 1A, is provided on a first interface surface of the first photovoltaic p-n junction structure or a second interface surface of the second photovoltaic p-n junction structure. In an embodiment, the interface layer comprises a chalcogenide dielectric layer. In step 128, the first interface surface of the first photovoltaic p-n junction structure or the interface layer provided thereon is contacted with the second interface surface of the second photovoltaic p-n junction structure or the interface layer provided thereon, thereby making the multi-junction photovoltaic device having a stacked multilayer geometry.

FIG. 1C shows a flowchart 130 of a method for making a multi-junction photovoltaic device. The process begins with steps 132 and 134 of providing first and second photovoltaic p-n junction structures, such as structures 112 and 116 of FIG. 1A. In step 136, a first interface surface of the first photovoltaic p-n junction structure is directly or indirectly contacted with a second interface surface of the second photovoltaic p-n junction structure, thereby making the multi-junction photovoltaic device having a stacked multilayer geometry. In an embodiment, lateral dimensions of the first photovoltaic p-n junction structure or the second photovoltaic p-n junction structure are independently less than or equal to 3000 microns.

FIG. 1D shows a flowchart 140 of a method for making a multi-junction photovoltaic device. The process begins with steps 142 and 144 of providing first and second photovoltaic p-n junction structures, such as structures 112 and 116 of FIG. 1A. In step 146, a transfer surface of the first photovoltaic p-n junction structure is contacted with a contact surface of a conformal transfer device, such that the first photovoltaic p-n junction structure is adhered to the contact surface. Subsequently, a first interface surface of the first photovoltaic p-n junction structure adhered to the contact surface is contacted, in step 148, with a second interface surface of the second photovoltaic p-n junction structure, thereby making the multi-junction photovoltaic device having a stacked multilayer geometry.

### EXAMPLE 1

### Printing-Based Assembly of Quadruple Junction, Four-Terminal Microscale Solar Cells and Their use in High-Efficiency Modules

Expenses associated with shipping, installation, land, regulatory compliance and on-going maintenance/operations of utility-scale photovoltaics suggest that increases in solar-to-electrical conversion efficiencies will drive cost reductions¹. Advancements in light management are the primary determinants of higher PV efficiencies²⁻⁴. Single-junction cells have performance constraints defined by their Shockley-Queisser limits⁵. Multi-junction (MJ) cells⁶⁻¹² can achieve higher efficiencies, but advances are limited by requirements in epitaxial growth and current-matching. Mechanically stacked MJ cells¹³⁻¹⁹ circumvent these disadvantages, but existing approaches lack scalable manufacturing processes and suitable interfaces between the stacked cells. This example presents materials and strategies designed to bypass these limitations. The schemes involve (1) printing of microscale solar cells, (2) advanced optical/electrical/thermal interface materials and (3) packaging techniques, electrical matching networks, and compact ultrahigh concentration optics. This example demonstrates quadruple junction, four-terminal solar cells with measured efficiencies of 43.9% at concentrations exceeding 1000 suns, and modules with efficiencies of 36.5%.

PV module efficiency impacts almost every component of the aggregate system cost, from materials to manufacturing, to installation and operations¹. Single-junction (SJ) solar cells are already near theoretical efficiency limits defined by thermalization losses and sub-bandgap transparency²⁻⁵. Parallel use of multiple, separated SJ cells with spectral-splitting optical elements²⁰⁻²² can be attractive, but the complexity in manufacturing, alignment and light management hinder prospects for practical use. Devices that incorporate multiple junctions (i.e. sub-cells) in monolithic stacks, known as multijunction (MJ) cells⁶⁻¹⁹, provide an attractive route to ultrahigh efficiency. Over the last decade, increases in the absolute efficiency of MJ cells correspond to nearly 1% per year, reaching values that are presently ˜44%⁶⁻¹². Further improvements, however, will require solutions to daunting challenges in achieving lattice-matched^{7,8} or metamorphic⁸⁻¹² epitaxial growth in complex stacks and in maintaining current matched outputs from each of the sub-cells. Mechanical stacking of separately grown SJ or MJ materials represents a well-explored alternative route to MJ devices¹³⁻¹⁹ that recently demonstrated very high efficiencies¹⁵. This process involves physical wafer bonding, followed by eliminating the top and/or bottom wafers. One option for bonding uses direct, high-temperature wafer fusion techniques¹³⁻¹⁵. The electrically conducting interface that results, however, retains the requirement of current matching. This requirement becomes challenging to maintain as the number of sub-cells in the MJ device increases due to variations in the terrestrial solar spectrum. An alternative approach uses thick, insulating organic adhesives, with double-sided, multilayer antireflective coatings and multi-terminal connections¹⁶⁻¹⁹. Here, the resulting MJ cells suffer from interface reflections, poor heat flow characteristics and often unfavorable thermo-mechanical interface stresses at high irradiance concentration. Despite research and development of the last ˜25 years, neither of these bonding strategies currently offers a realistic means for manufacturing or for viable multiple stacking operations.

This example describes concepts to bypass many of the limitations of these and other previously explored technologies. Here, printing-based methods enable high-throughput physical assembly of arrays of stacked, microscale MJ solar cells using high performance, released thin film materials via epitaxial liftoff processes. An infrared transparent and refractive-index matched layer of a chalcogenide glass (arsenic triselenide, As₂Se₃) serves as a thermally conductive and electrically insulating interface layer in these stacks. Advanced packaging techniques, electrical matching networks and dual-stage imaging lenses yield modules with an efficiency of 36.5%.

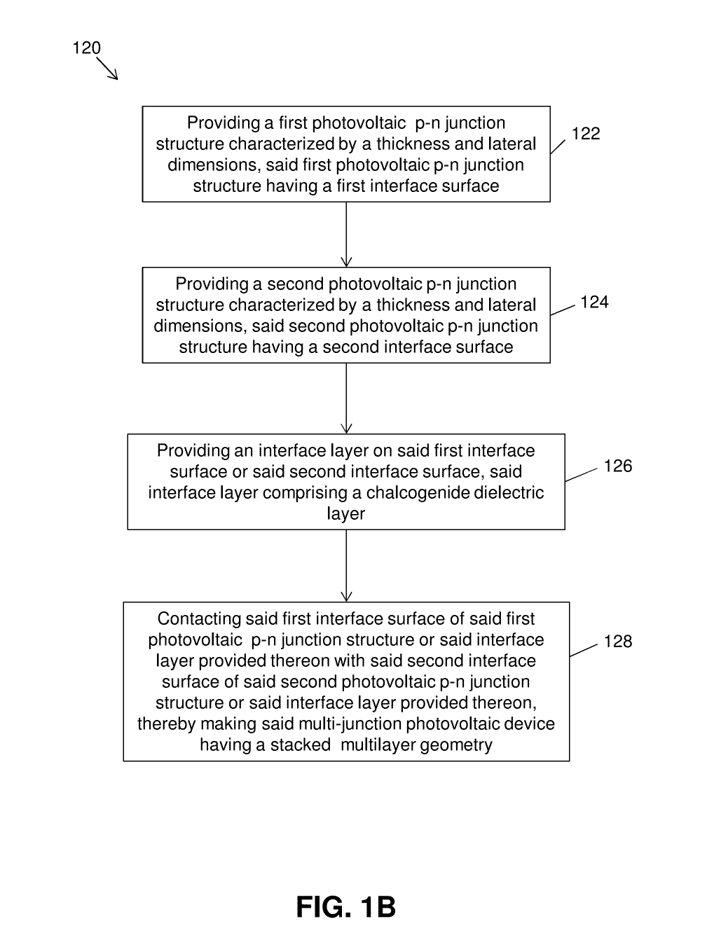

FIG. 2a schematically illustrates the structure and assembly process for a quadruple junction, four-terminal microscale solar cell, with an active area of 600×600 μm². The top cell uses a three-junction (3J) design based on InGaP/GaAs/InGaAsNSb (bandgaps of 1.9 eV/1.4 eV/1.0 eV)⁷, grown lattice matched on a GaAs substrate and released by eliminating a sacrificial layer of AlInP at the base of the stack^{23,24}. A tri-layer anti-reflective coating (ARC) ensures efficient transmission of light into this 3J cell. The bottom cell (lateral dimensions matched to the top cell) is a diffused-junction Ge solar cell²⁵ with recessing grid metallization below the top surface. FIGS. 2b and 2c provide scanning electron microscope (SEM) images of a typical Ge cell before and after delivery of a 3J cell onto its surface by transfer printing²⁶, respectively. This assembly process occurs in a high-throughput, parallel fashion, to allow simultaneous formation of arrays of stacked MJ cells, in a fully automated step-and-repeat mode with high yields (>95%) and accurate overlay registration (<2 μm), as illustrated by the optical microscope image in FIG. 2d. The Ge cells use recessed contacts to enable high quality contact and bonding at the interface. A layer of As₂Se₃ (˜300 nm thick) cast on top of the Ge cell using a sol-gel process²⁷ provides a low loss optical interface, with minimal thermal resistance and excellent electrical isolation, as described in detail subsequently. An ultrathin (˜10 nm), optically negligible layer of a transparent polymer can help to ensure intimate contact and high yields in printing. The cross-sectional SEM images in FIG. 2e illustrate the aligned and recessed metal contacts as well as the As₂Se₃ interface layer. In such a stacked 3J/Ge structure, the top 3J cell captures light from 300 nm to 1300 nm. Light from 1300 nm to 1700 nm passes through to the bottom Ge cell with minimal interface reflections, due to the high index of the As₂Se₃, nearly independent of the thickness of this layer, over a wide range. The 3J and Ge cells operate independently with separate sets of terminals, without electrical crosstalk, thereby eliminating constraints associated with current matching.

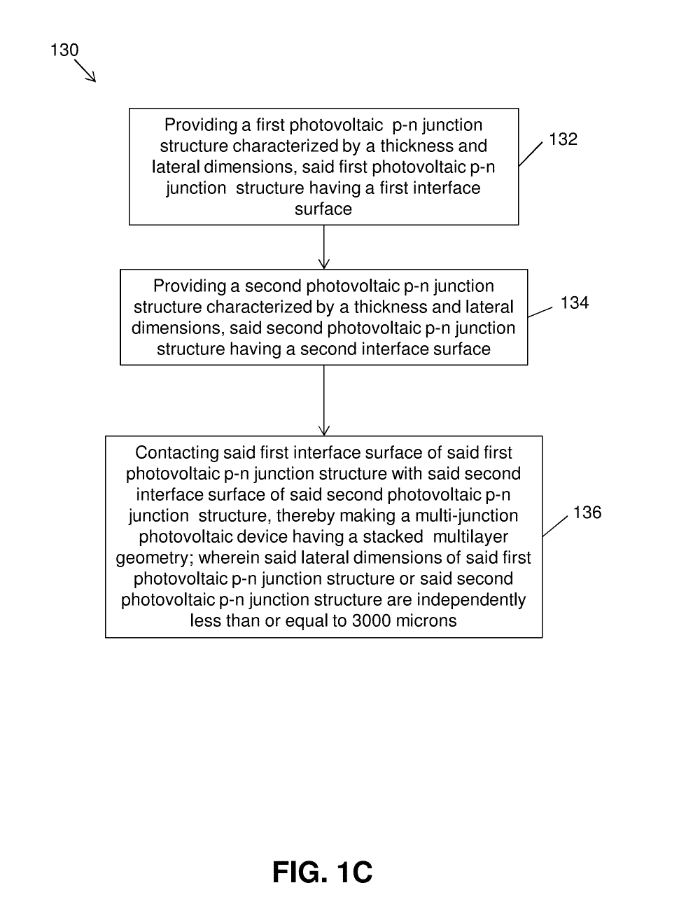

FIG. 3 and Table 1 present the performance characteristics measured from a completed microcell MJ device. The device includes lithographically defined sidewall insulation and thin-film metal contacts to the 3J and Ge cells (FIG. 3a). The thin film geometry of the 3J is beneficial because it allows for wafer-level thin-film interconnections. Current and voltage characteristics measured from the 3J and Ge cells at concentrations ranging from 1 sun (standard AM1.5D spectrum) to ˜1200 suns appear in FIGS. 3b-e. Under one sun illumination, the 3J cell and the Ge cell exhibit efficiencies of 32.2% and 0.722% respectively, thus corresponding to a summed efficiency of 32.9%. As the concentration increases, the efficiencies of both cells increase, ultimately reaching maximum values of 42.1% (3J) and 1.81% (Ge) at ˜1000 suns. The maximum total efficiency is 43.9% (FIG. 3f). Measurements of each cell separately with the other cell in different configurations (open circuit, short circuit and maximum power) show little differences. These results suggest that there is negligible photon or electron coupling between the cells. For concentrations larger than 1000 suns, the efficiencies decrease due primarily to a reduction in the fill factor, likely associated with resistive losses (FIGS. 3d and 3e). FIG. 3g quantitatively illustrates, in a manner consistent with experimental data, the external quantum efficiency (EQE). spectra for the integrated MJ device, showing absorption across the entire solar spectrum, from 300 nm to 1700 nm, with minimal reflection losses. Modeling shows that the reflectance at wavelengths larger than 1200 nm arises, almost entirely, from limitations of the tri-layer ARC, not from reflection at the interfaces with the As₂Se₃.

TABLE 1
Cell Performance

| | | J_{sc} | V_{oc} | FF | η | total η |
|---|---|---|---|---|---|---|
| | | (mA · cm⁻²) | (V) | (%) | (%) | (%) |
| 1 sun | 3J cell | 14.5 | 2.64 | 84.3 | 32.2 | 32.9 |
| | Ge cell | 6.99 | 0.181 | 57.1 | 0.722 | |
| 1000 | 3J cell | 14500 | 3.47 | 83.7 | 42.1 | 43.9 |
| suns | Ge cell | 6990 | 0.374 | 69.3 | 1.81 | |

For reasons described previously, the interface materials in these systems are critically important. Chalcogenide glasses like As₂Se₃ are commonly used in infrared optics^{28,29} but have not been explored for the use reported here. The As₂Se₃ is attractive for present purposes because it offers (1) the ability to form smooth, uniform coatings by simple solution processing, (2) a high resistivity (10¹⁰˜10¹² Ω·cm) and high electrical breakdown strength (˜10⁸ V/m), (3) a refractive index (˜2.7) that approaches the semiconductors in the cells (˜3.4 for GaAs and ˜4.3 for Ge at 1300 nm) and (4) a relatively high thermal conductivity (˜1.0 W/K/m). The role is as an electrically insulating layer to allow independent operation of the top and bottom cells, with sufficiently high thermal conductivity and index of refraction to minimize barriers to heat transport and losses due to optical reflection, respectively.

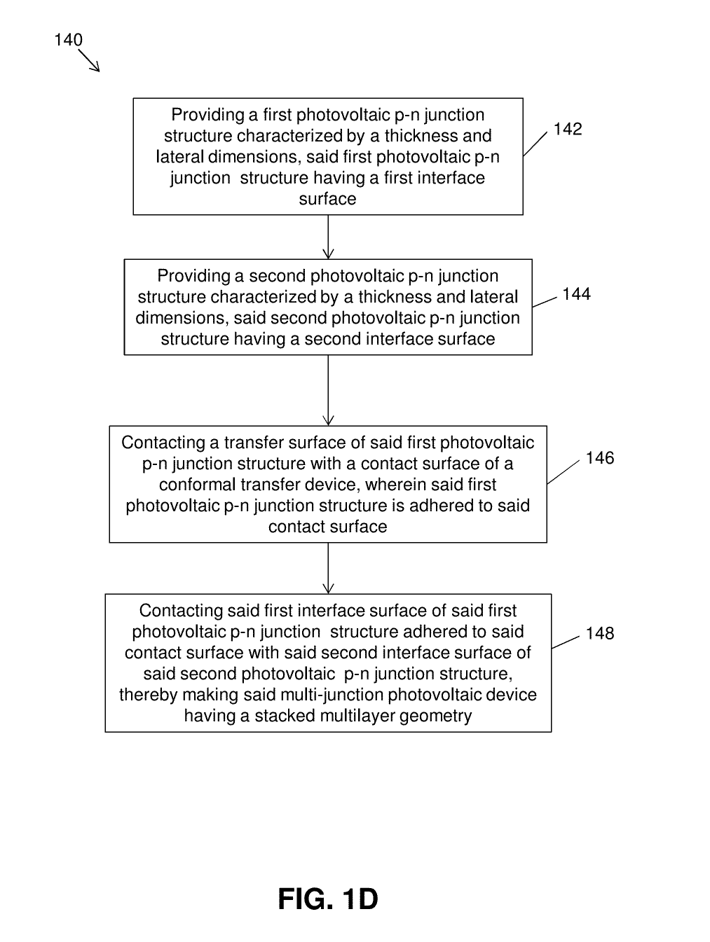

Previously explored stacked MJ cells include thick organic adhesives¹⁶⁻¹⁹ and directly bonded interfaces¹³⁻¹⁵. Comparisons of electrical, optical and thermal properties of these cases to those enabled by As₂Se₃ provide insights into the utility of this material. FIG. 4a summarizes the three structures. The thicknesses of As₂Se₃ (300 nm) and organic adhesive (NOA, 10 μm) are chosen to offer sufficient breakdown voltages to support modules with many interconnected cells. FIG. 4b presents current-voltage measurements performed by biasing the bottom p-contacts of the 3J cells relative to the top n-contacts of the Ge cells. The direct bond case exhibits a non-insulating interface (˜0.1 A at 1 V). Cells with As₂Se₃ or NOA show leakage currents (˜10⁻⁷ A for As₂Se₃ and ˜10⁻¹⁰ A for NOA at up to 20 V) much lower than the photocurrents generated under concentration (˜5×10⁻² A at ˜1000 suns), ensuring that 3J and Ge cells can operate independently in an interconnected network. Measured EQE curves in FIG. 4c indicate that the bottom Ge cell with the As₂Se₃ interface exhibits responses similar to those in the direct bonded structure, both of which are significantly higher than that of the structure with NOA (index=1.56). Integrating the EQE over a standard AM1.5D spectrum yields a short-circuit current density (J_{sc}) for the Ge cell with As₂Se₃ of 7.0 mA/cm², consistent with the measured J-V curves in FIG. 3c. The Ge cell with NOA exhibits a calculated J_{sc} of 5.3 mA/cm². This difference is consistent with both the measured optical reflectance spectra from the surfaces of the top 3J cells (FIG. 4d) and the simulated results (FIG. 4e). Thermal properties are also important, especially for operation at high optical concentration. Here, the interface material must not impede dissipation of heat away from the 3J cell. As₂Se₃ offers significant thermal advantages over the types of organic layers that have been explored in the past. These advantages follow from the combined effects of high breakdown strength, which allows the use of thin layer geometries, and high thermal conductivity. FIGS. 4f and 4g show measured and simulated steady-state temperature distributions at the surfaces of MJ cells during illumination with a laser beam (488 nm, 0.15 W) configured to generate thermal power density in the cell area similar to that from irradiance at ˜1000 suns. The results suggest that the As₂Se₃ interface provides a thermal conductance (3×10⁶ W/K) comparable to the direct bond interface, while the thermal conductance for the NOA interface is much lower (10⁴ W/K). The maximum temperatures associated with the As₂Se₃, direct bond and NOA structures are 39° C., 38° C. and 68° C., respectively, consistent with numerical simulations. The reduced temperatures improve performance and long-term reliablity².

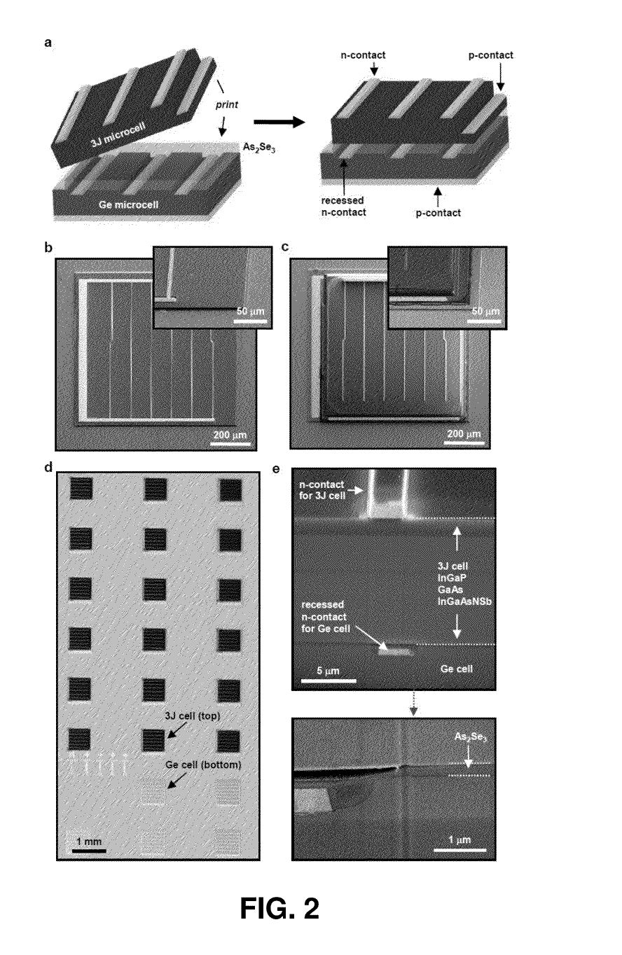

The four-terminal MJ microscale cells can be integrated with dual-stage imaging optics (FIGS. 5a and 5b) based on a molded primary lens and a secondary, miniature ball lens. Ray tracing results (FIGS. 5e and 5f) show that such a system provides geometric concentration ratios greater than 1000 and a uniform irradiance distribution on the cell surface³⁰. Under on-sun test (Air Mass condition 1.8), the four-terminal PV module exhibits an efficiency of 33.4% for the 3J cell and 1.0% for the Ge cell, reaching a total efficiency of 34.4% (FIG. 5e). The total module efficiency adjusted to standard test conditions (at cell temperature 25° C.) is 36.5%. Matching networks enable two-terminal operation, for practical applications¹⁷. FIGS. 5f and 5g present two circuit designs, one that uses a voltage matched array with 10 MJ cells and another that exploits a current matched array with 3 MJ cells. Experiments using related cells demonstrate the effectiveness of these network architectures and validate the methods for calculation. Experimentally measured performance variation data for separate 3J and Ge cells allow statistical prediction of output currents, voltages and powers associated with the proposed circuit networks. The results show that efficiencies of 35.9%±0.2% and 36.2%±0.3% are possible with current and voltage matching, respectively.

The results presented here clearly demonstrate that printing-based assembly of epitaxially released, MJ thin films with optimized interface materials provides microscale solar cells configured for use with miniaturized concentration optics and matching networks to yield ultrahigh efficiency module-level photovoltaics. These schemes can also apply immediately to more advanced systems, including those that involve increased numbers of junctions and/or stacking operations. Some possibilities are five- or even six-junction cells, for which practical efficiencies might reach more than 45%. Straightforward improvements in the concentration optics (e.g. addition of ARC layers on the primary lens would achieve an additional ˜1% efficiency boost) and enhancements to the ARC on the cell surface can lead to further increases in module performance. Other types of chalcogenide glasses with refractive indices (n>3.0) higher than As₂Se₃ can also be considered²⁹. Collectively these and other, readily achievable enhancements suggest promising paths to photovoltaic systems that utilize the entire solar spectrum and approach the thermodynamic limits in efficiency.

### Methods

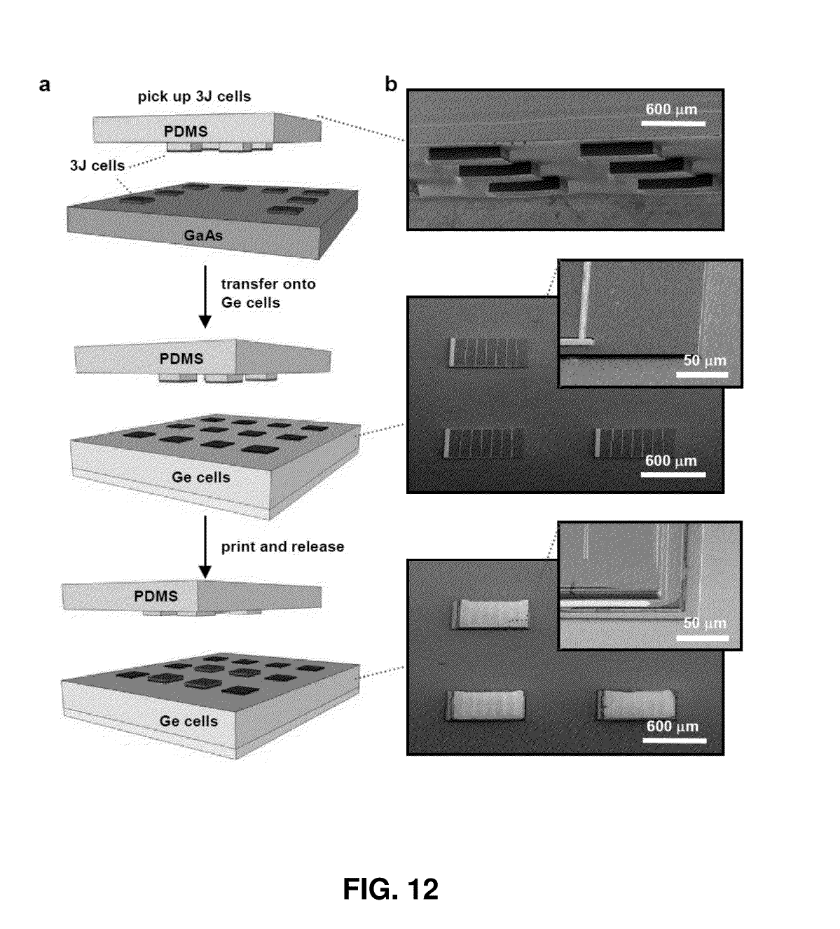

The 3J (InGaP/GaAs/InGaAsNSb) cell is epitaxially grown on a lattice matched GaAs substrate⁷, with a total thickness of ˜10 μm that includes the active materials and a GaAs current spreading layer several microns thick beneath them as well as a sacrificial layer of AlInP²⁴. An anti-reflective coating (90 nm SiO₂/45 nm Si₃N₄/30 nm TiO₂) deposited on the 3J cell minimizes reflection losses. The diffused-junction Ge cell is based on a 230 μm p-Ge wafer with a lattice matched n-GaAs epitaxial film (1.5 μm) as a transparent contact layer. Metal layers (Ge/Ni/Au) serve as contacts in recessed geometries. The cell active area (600×600 μm²), which is defined by the photomasks used in the lithographic process, is measured directly after fabrication. To minimize effects of shadowing, the metal contact lines in the 3J and the Ge cells adopt the same layout and are aligned to one another at the printing step. A solution of As₂Se₃ (powder from Alfa Aesar) dissolved in ethylenediamine (concentration 0.2 g/mL) is spin cast on the Ge cells, to form, upon curing at 150° C. for 10 hours in an inert atmosphere, a 300 nm thick As₂Se₃ glass film²⁷. An ultrathin (10 nm) adhesive layer (InterVia 8023-10) spin coated on the As₂Se₃ improves the printing yields. Etching the AlInP layer in hydrochloric acid²⁴ releases the 3J cells to enable their printing onto the As₂Se₃ coated Ge cells with the ultrathin adhesive. This process uses a poly(dimethylsiloxane) stamp mounted in an automated set of equipment for aligning and printing²⁶ 100 cells, or more, in a single step. The same printing process can produce structures with NOA (NOA61, by Norland Products, Inc. spin coated on bare Ge cells) and direct bond (no adhesive, printing followed by heating at ˜115° C. for 10 mins) interfaces. The adhesion strength between the 3J cells and Ge cells for the case of As₂Se₃ is >200 kPa. The printed 3J/Ge MJ cells are encapsulated in an epoxy layer (InterVia 8023-10, thickness 10 μm) and metallized to form contact pads. Thermal cycling tests (rapid heating at 110° C. for 1 min and cooling at 20° C. for 1 min, 10 cycles) reveal no changes in the mechanical, optical, electrical or photovoltaic characteristics of the devices (FIG. 15). A four-probe setup measures current-voltage responses. A solar simulator with an AM1.5D filter yields one sun illumination. Coupling light from a Xenon arc lamp through an optical fiber and a set of lenses yields concentrated illumination. The irradiance power is assumed to be linearly proportional to the measured short-circuit current (I_{sc}). EQE and reflectance spectra are measured using a spectroradiometer system.

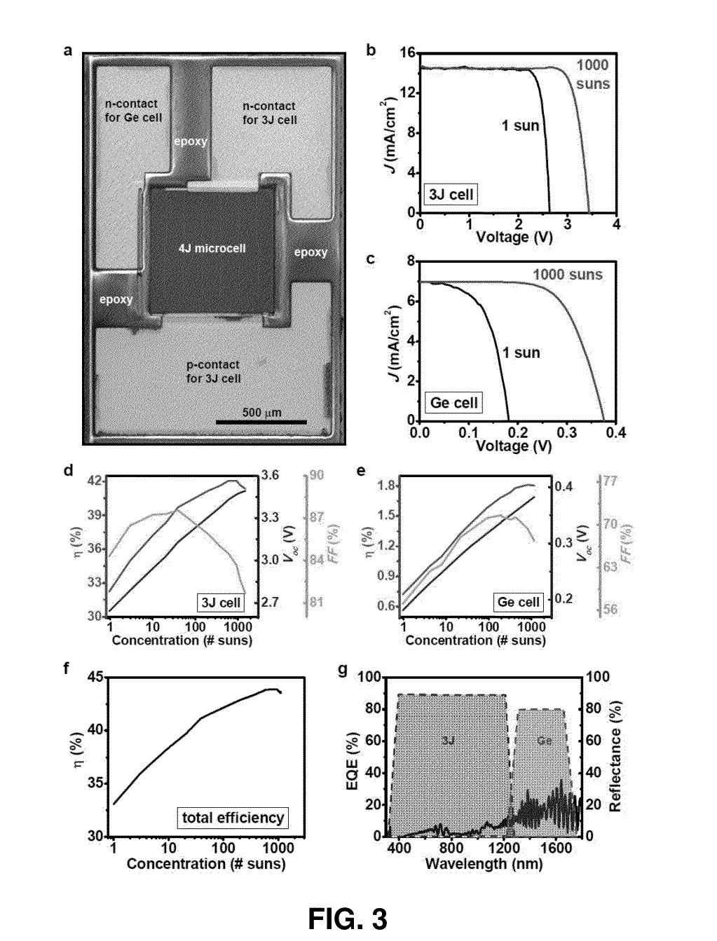

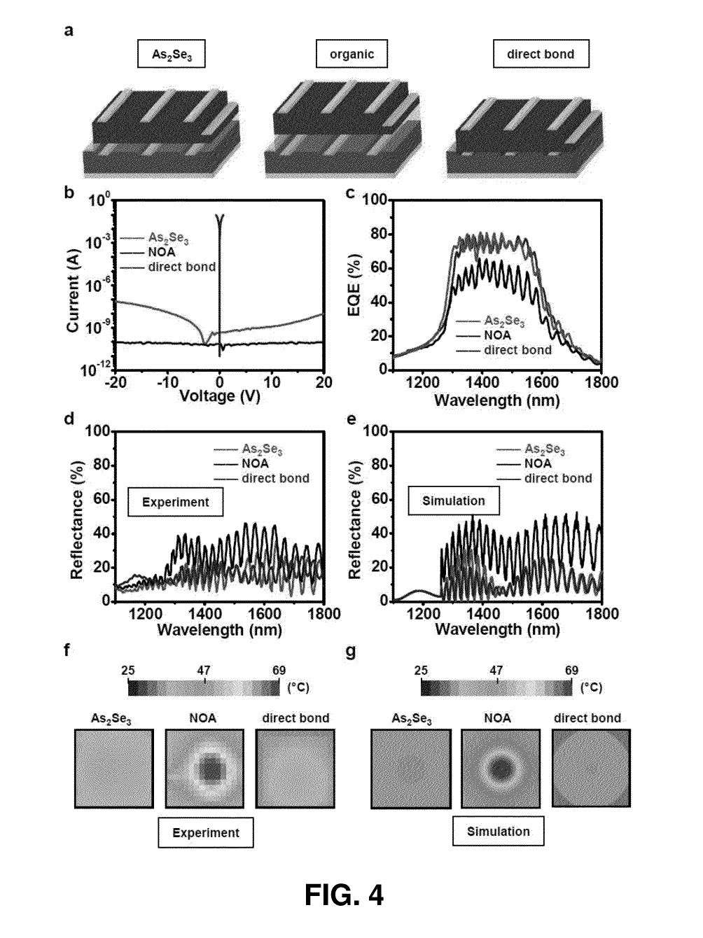

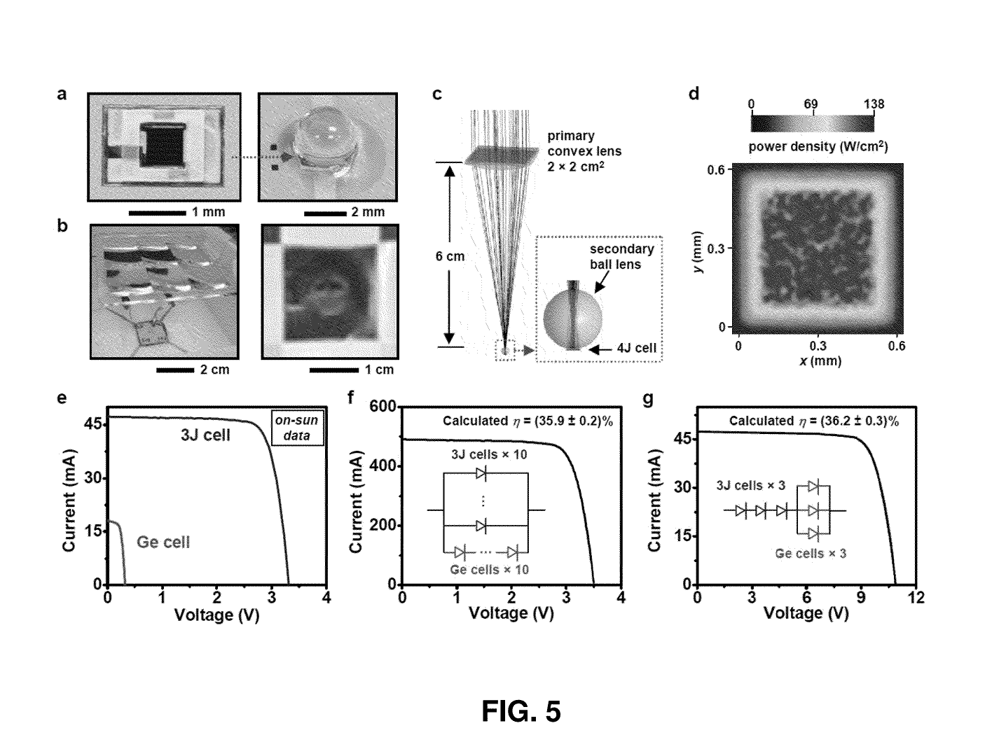

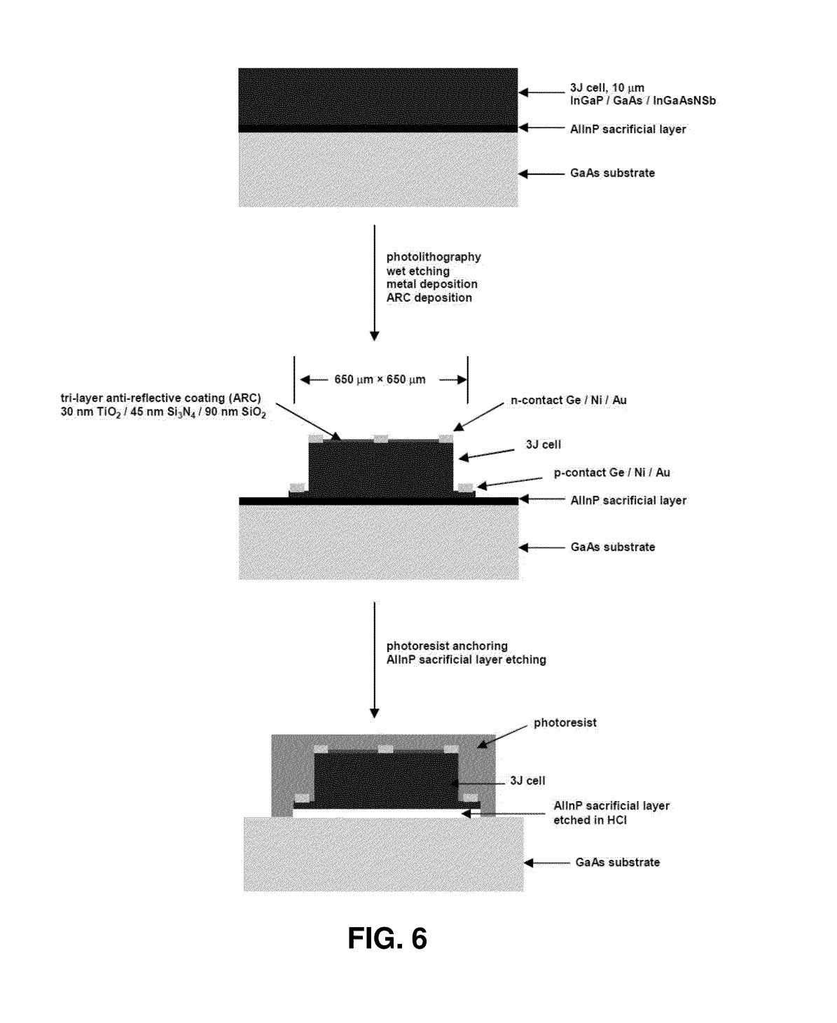

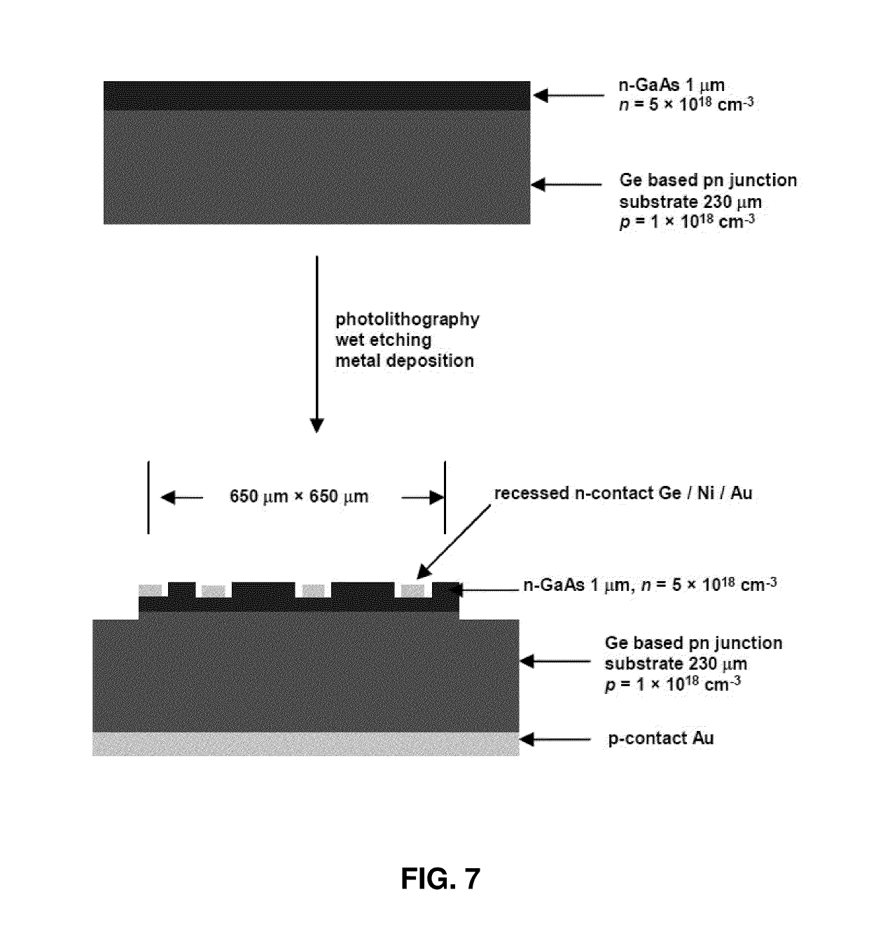

FIG. 6 is a process flow for fabricating 3J cells on a GaAs substrate with a releasable AlInP sacrificial layer. FIG. 7 is a process flow for fabricating Ge cells. FIG. 8 is a process flow for fabricating 3J/Ge cells by transfer printing. FIG. 9 is a schematic illustration for encapsulating assembled 3J/Ge cells in epoxy and metal deposition for contact pads. FIG. 10 shows schematic illustrations and SEM images of (a) a bare Ge cell, (b) an assembled 3J/Ge cell, and (c) an encapsulated 3J/Ge cell with metal contact pads.

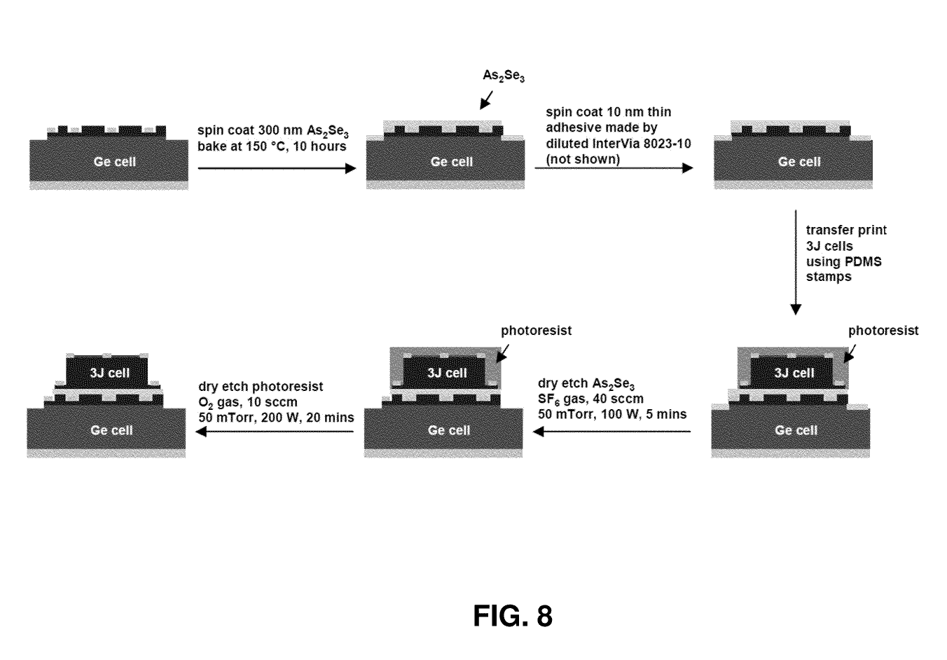

FIG. 11 shows (a) a process flow for fabricating PDMS stamps, (b) an optical image of a PDMS stamp with a 10×10 post array, and (c) an SEM image of the PDMS stamp, including post and backing layer.

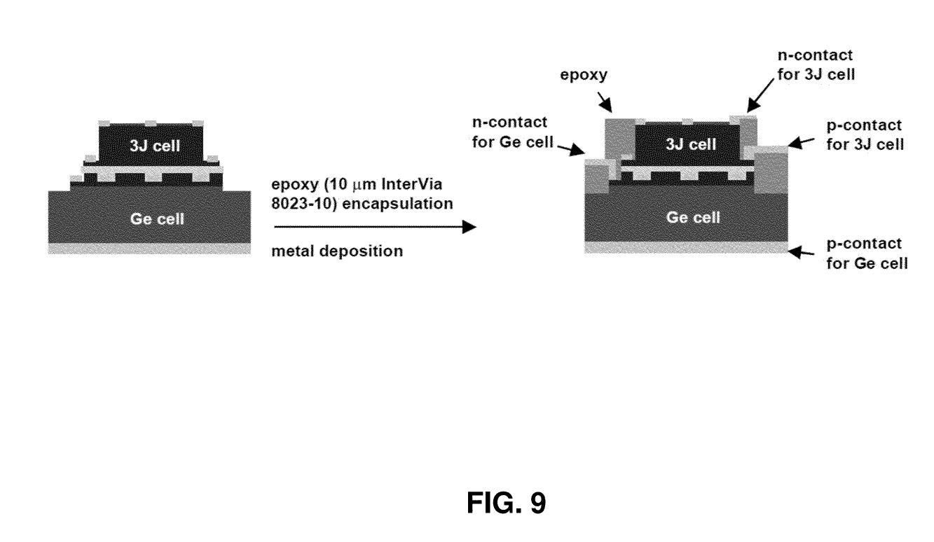

FIG. 12 shows (a) a process flow for fabricating assembled 3J/Ge cells using transfer printing and (b) SEM images (side view) of PDMS stamps with 3J cells, bare Ge cells and printed 3J/Ge cells. Images for 3J cells are colorized. Insets show magnified views of the cell structures. Reference for printing method: Carlson, A. et al. Shear enhanced adhesiveless transfer printing for use in deterministic materials assembly. Appl. Phys. Lett. 98, 264104 (2011).

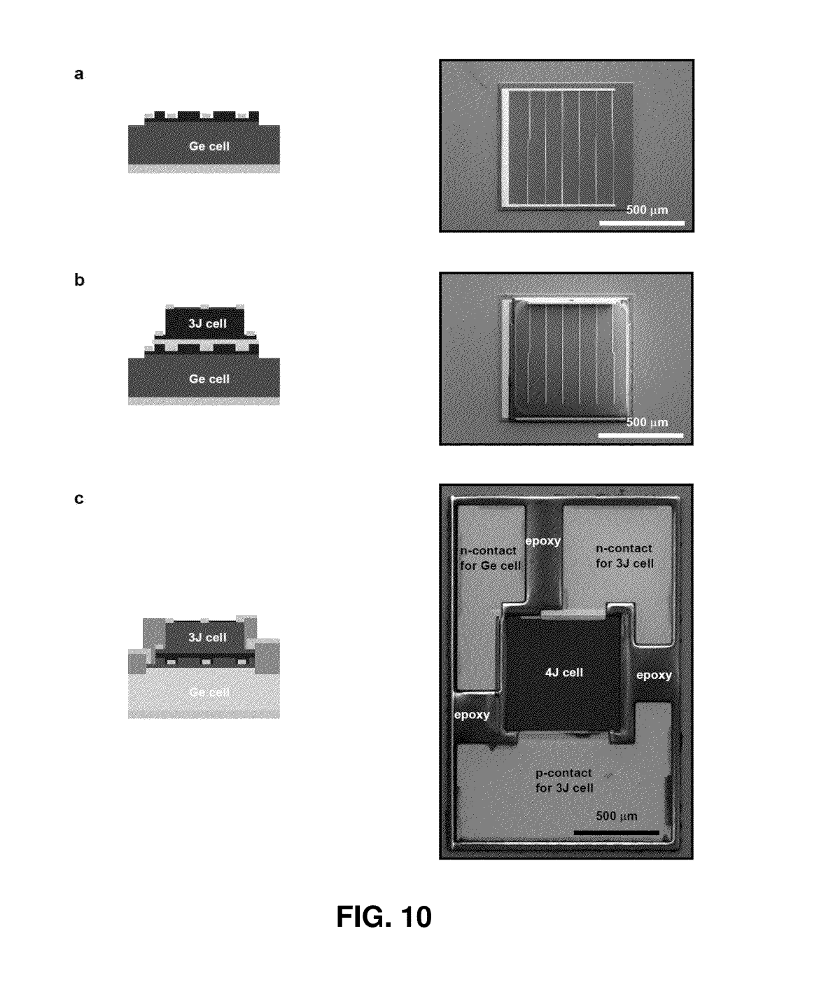

FIG. 13 is a photograph of the printing machine used to assemble the 3J/Ge solar cells. Reference on parallel, wafer-scale transfer printing process: Justice, J. et al. Wafer-scale integration of group III-V lasers on silicon using transfer printing of epitaxial layers. Nature Photonics 6, 610-614 (2012).

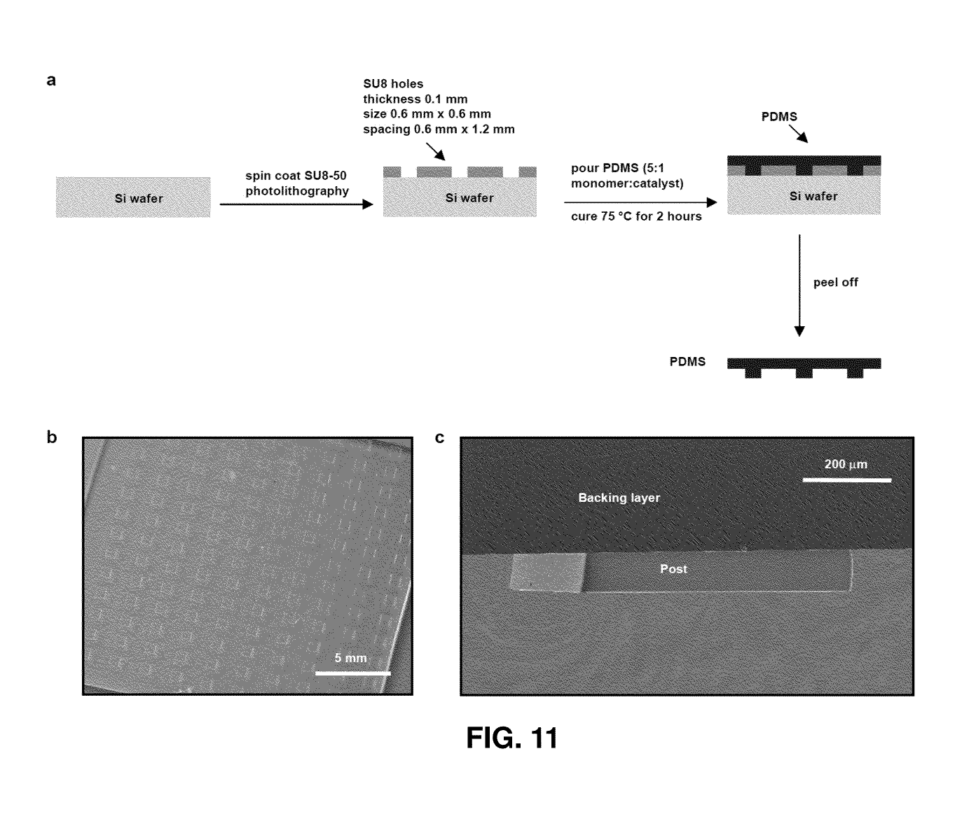

FIG. 14 shows colorized infrared optical images of two assembled 3J/Ge cells with an As₂Se₃ interface. Different colors indicate the difference in emissivity. FIG. 14(a) shows a cell with a perfectly bonded interface, while FIG. 14(b) shows a cell exhibiting air voids due to unwanted particles at the interface during the printing process.

FIG. 15 shows colorized infrared optical images of an assembled 3J/Ge cell with an As₂Se₃ interface (a) before and (b) after thermal cycling. Different colors indicate the difference in emissivity. The thermal cycling is performed by rapid heating (at 110° C. for 1 min on a hot plate) and cooling (at 20° C. for 1 min on a cold plate) for 10 cycles. No interface and performance degradations are observed.

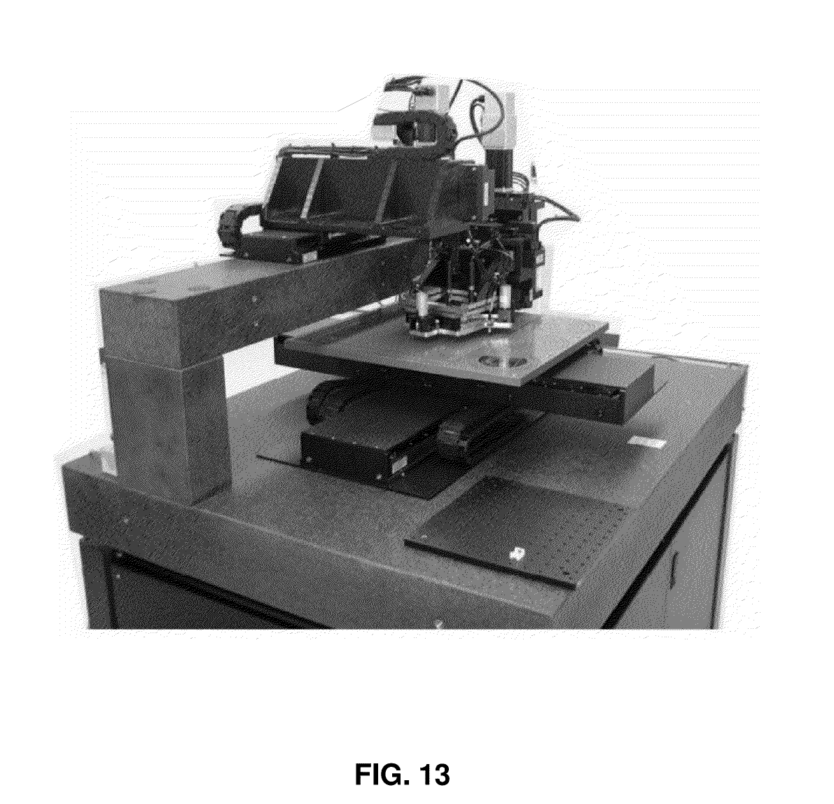

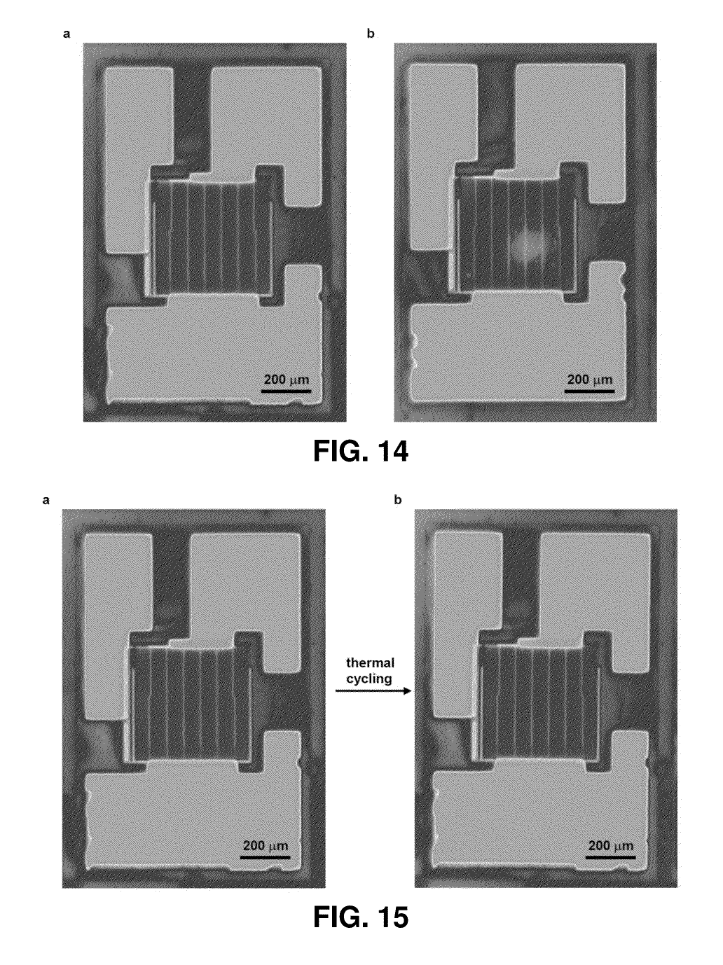

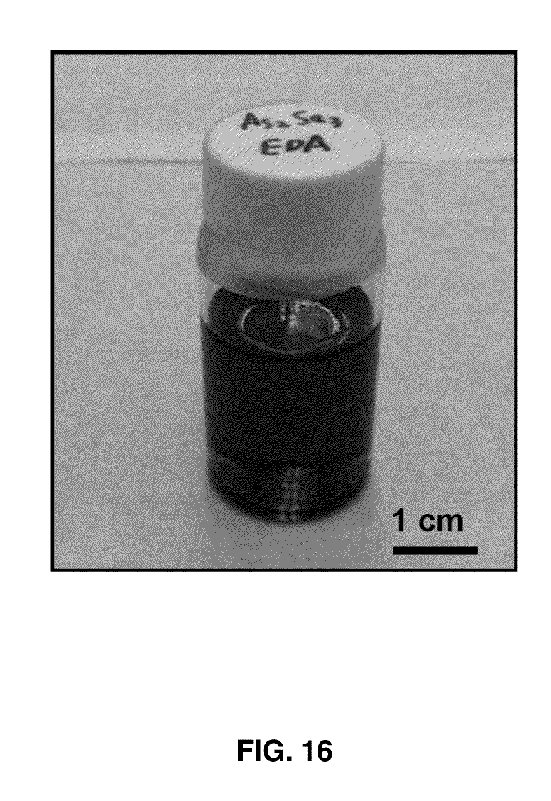

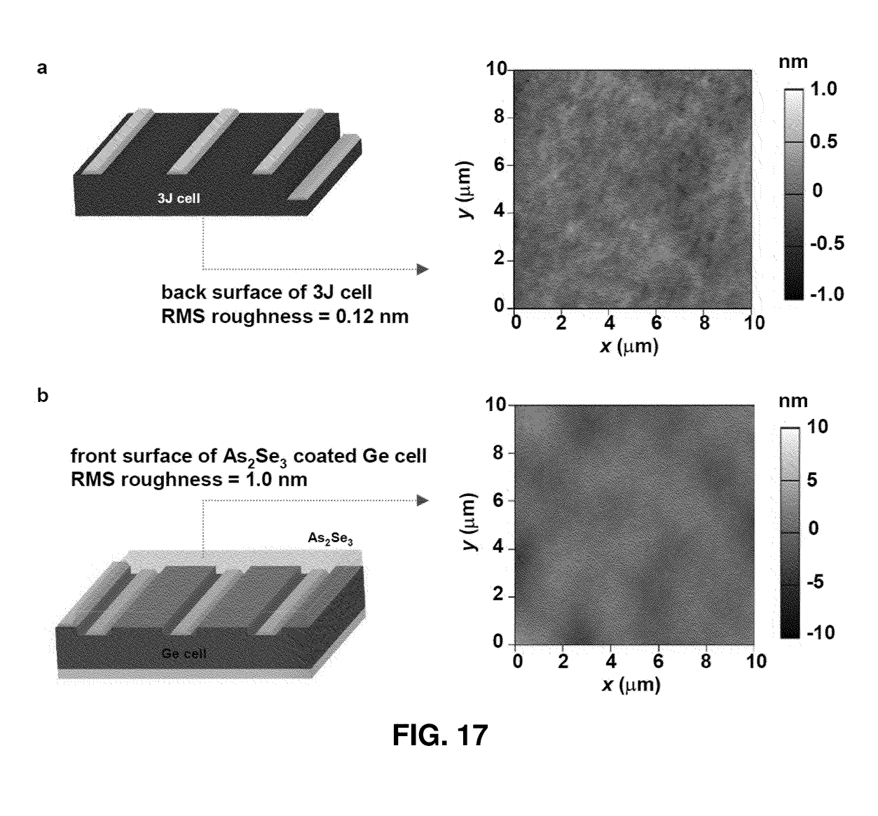

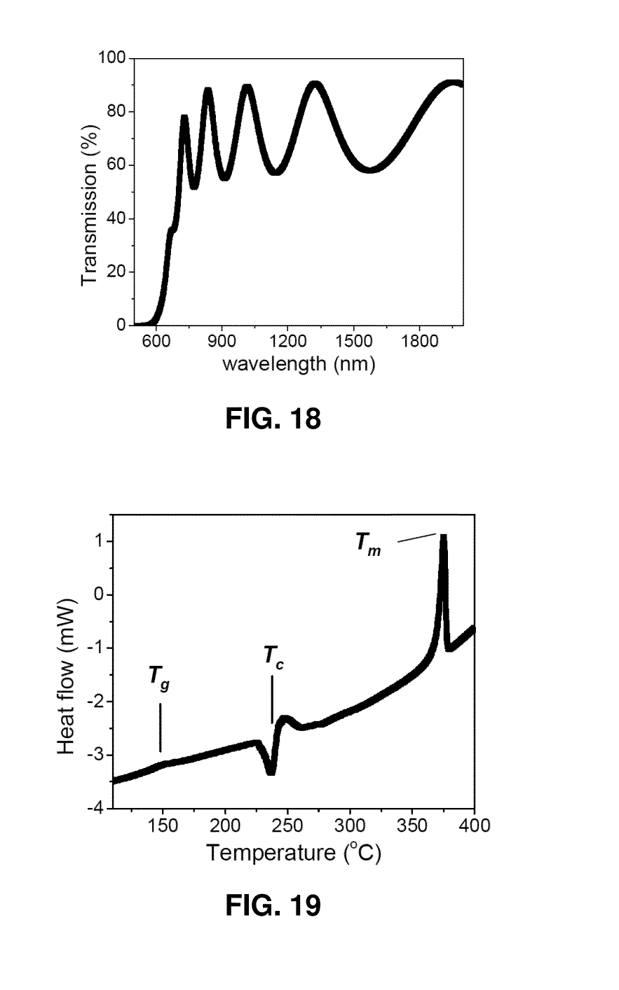

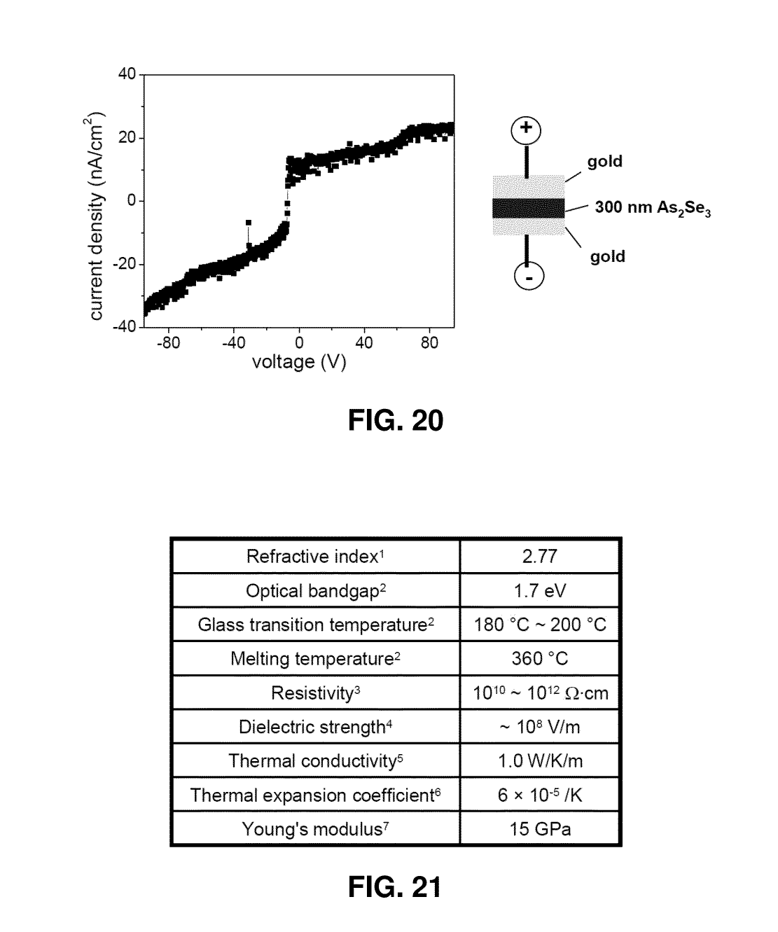

FIG. 16 shows an optical image of a bottle with As₂Se₃ dissolved into ethylenediamine solution (0.2 g/mL). FIG. 17 shows (a) an AFM image of the back surface of a 3J cell with a measured RMS roughness of 0.12 nm and (b) an AFM image of a 300 nm As₂Se₃ film coated on a Ge cell with a measured RMS roughness of 1.0 nm. FIG. 18 shows measured transmission spectrum of a 807 nm thick As₂Se₃ film coated on 1 mm thick glass. The measured refractive index for As₂Se₃ from 900 nm to 2000 nm is 2.67. Calculation is based on the method in: Swanepoel, R. Determination of the thickness and optical constants of amorphous silicon. J. Phys. E: Sci. Instrum. 16, 1214-1222 (1983). FIG. 19 shows a differential scanning calorimetric (DSC) curve of As₂Se₃ films, showing a glass transition temperature of T_{g}=150° C., a crystallization temperature of T_{c}=250° C., and a melting temperature of Tₘ=370° C. FIG. 20 shows a current-voltage curve of a 300 nm As₂Se₃ film with gold contacts on both sides, measured from −100 V to +100 V. Measured resistivity is 10¹³˜10¹⁴ Ω*cm. FIG. 21 shows properties of thin-film As₂Se₃ reported in the literature.

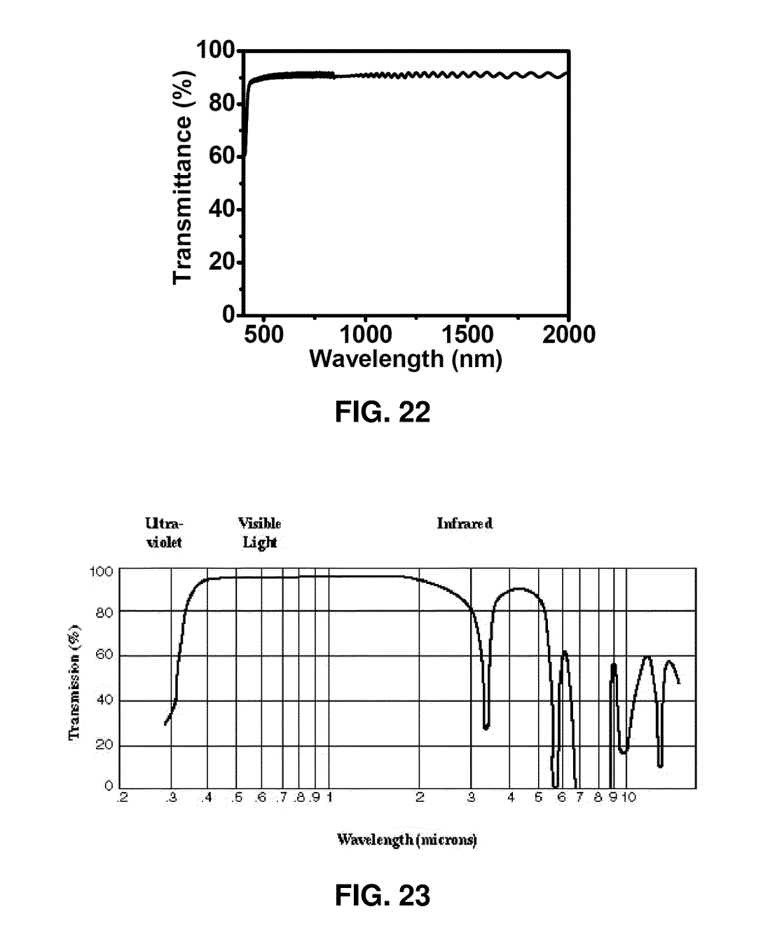

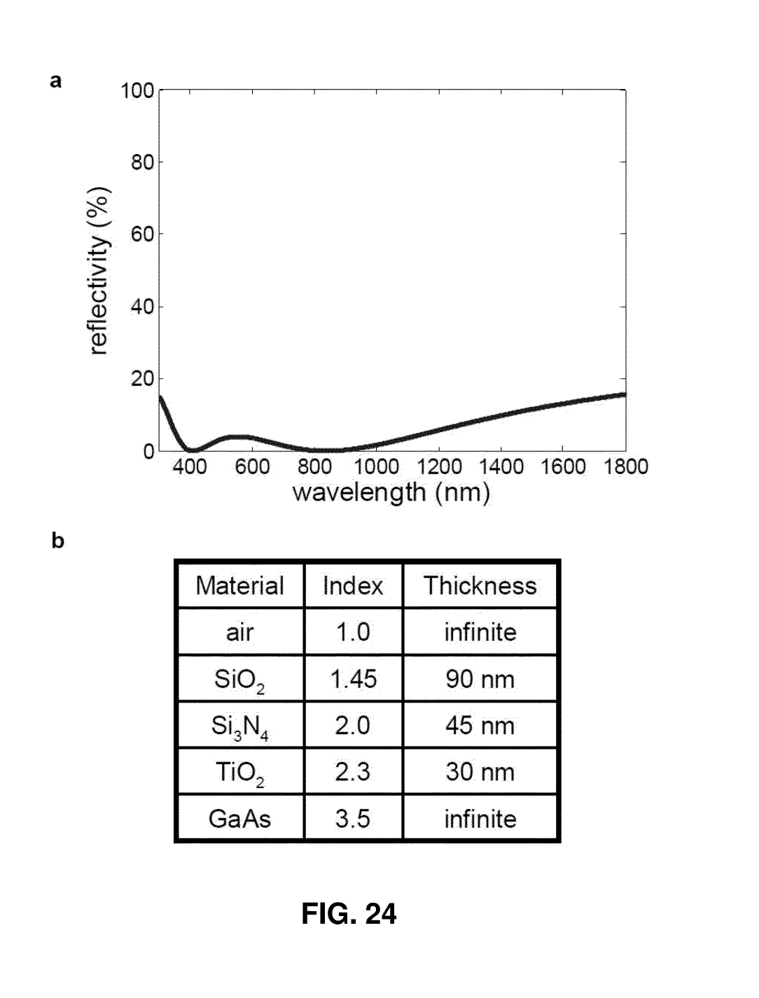

FIG. 22 shows a transmission spectrum of a 10 μm thick InterVia 8023-10 film coated on 1 mm thick glass. The material is transparent above 500 nm, and has a refractive index of 1.56. FIG. 23 shows a transmission spectrum of NOA 61 by Norland Products Inc. Further information can be found at www.norlandprod.com/adhesives/noa%2061.html.

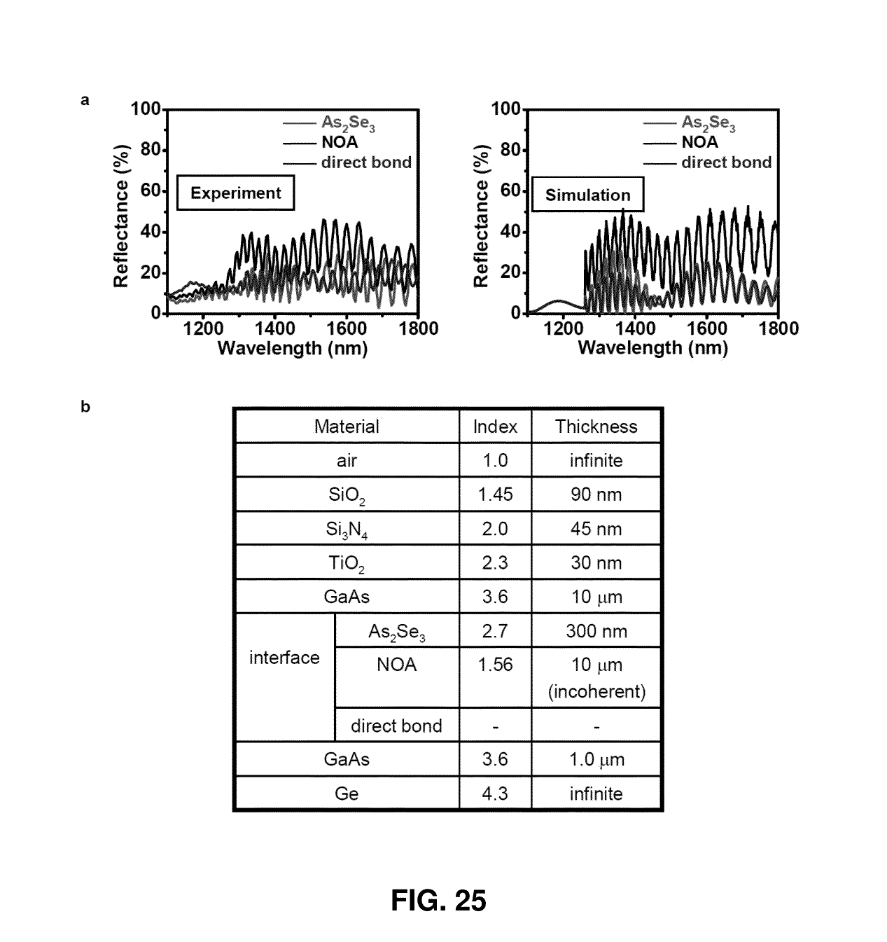

FIG. 24 shows (a) a simulated reflection spectrum of a tri-layer ARC coated on GaAs and (b) a layer structure used in the simulation.

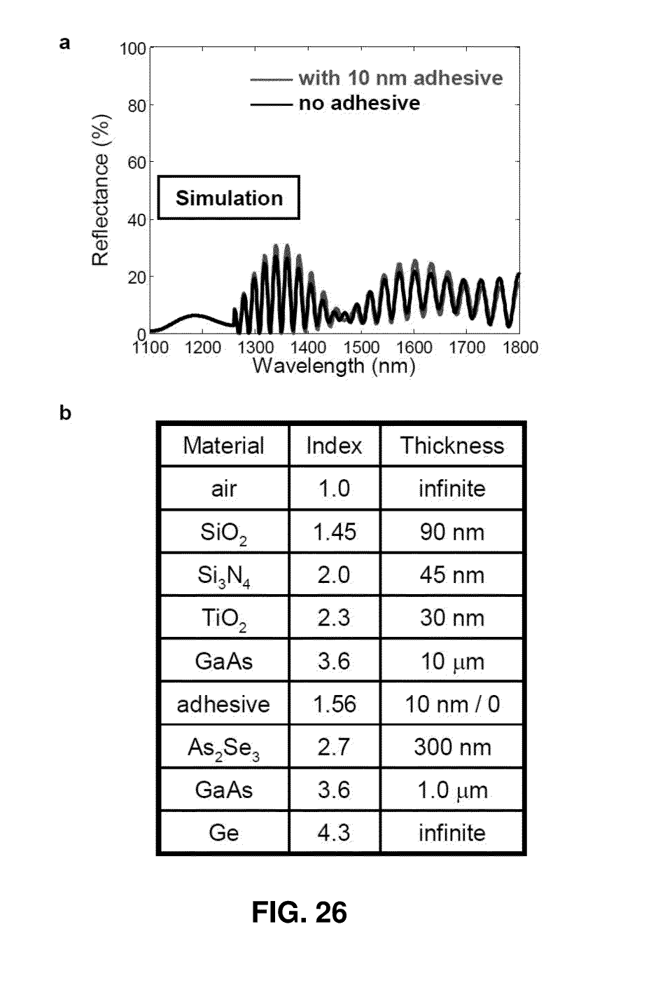

FIG. 25 shows (a) measured and simulated reflection spectra for assembled 3J/Ge cells with different interfaces (also shown in FIGS. 4d and 4f) and (b) a layer structure used in the simulation. A 10 μm thick GaAs layer is used in the simulation model to replace the actual 3J cell structure. Note that the 10 μm thick NOA layer is assumed to generate incoherent interference, due to the thickness non-uniformity. Transfer matrix method is used. Reference: Troparevsky, M. C. Transfer-matrix formalism for the calculation of optical response in multilayer systems: from coherent to incoherent interference. Opt. Express 18, 24715-24721 (2010). Details on the optical properties of different materials can be found in: Palik, E. Handbook of optical constants of solids (Academic Press, 1998).

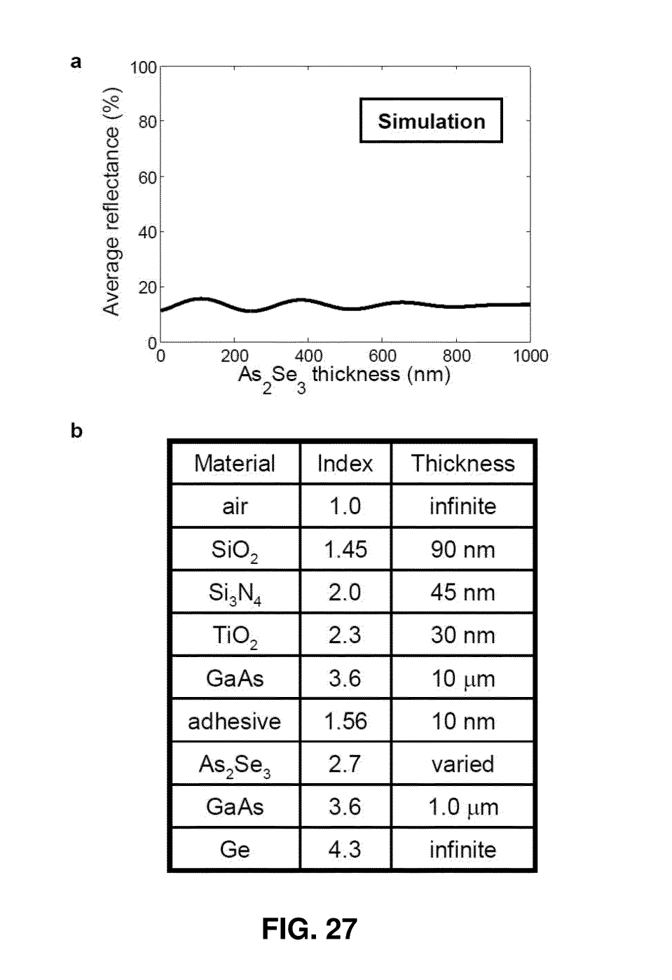

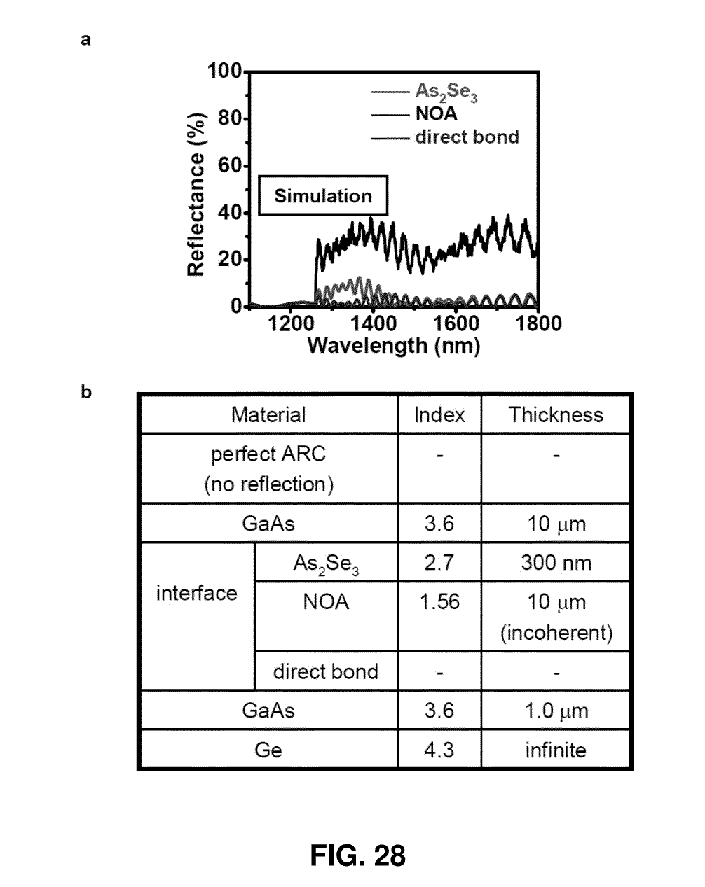

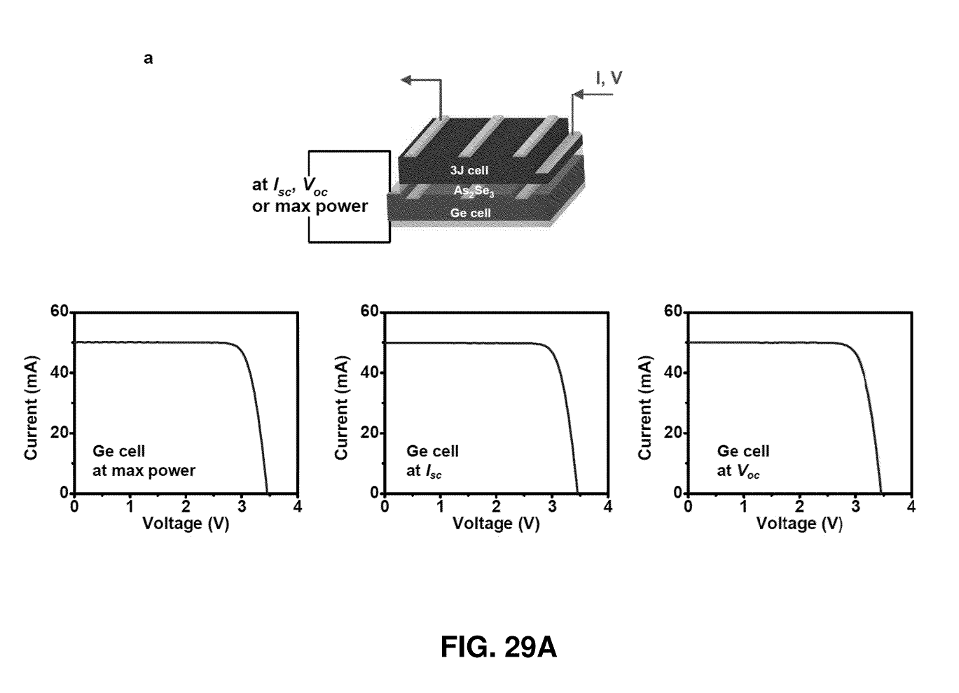

FIG. 26 shows (a) simulated reflection spectra for the 3J/Ge cell (using 300 nm As₂Se₃ as interface) with and without 10 nm adhesive layer (InterVia 8023-10), showing similar reflection responses and (b) a layer structure used in the simulation. FIG. 27(a) shows simulated reflectance (averaged between 1300 nm and 1700 nm) for the stacked 3J/Ge cell as a function of the As₂Se₃ thickness at the interface. The results show that the interface reflection is slightly dependent on the As₂Se₃ thickness. FIG. 27(b) shows a layer structure used in the simulation. FIG. 28 shows (a) simulated reflection spectra for 3J/Ge cells with different interfaces, assuming a perfect ARC is applied between air and the cells, and (b) a layer structure used in the simulation.

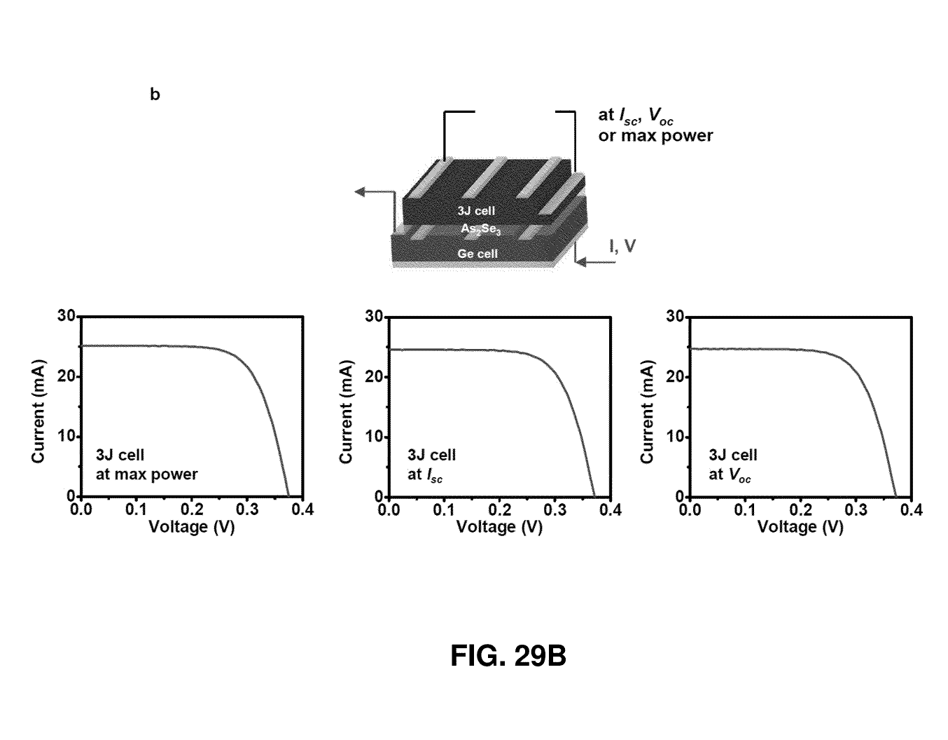

FIG. 29A shows measured current-voltage curves for a 3J cell under concentrations (1000 suns) when the Ge cell is at I_{sc}, V_{oc} or maximum power. FIG. 29B shows measured current-voltage curves for a Ge cell under concentrations (˜1000 suns) when the 3J cell is at I_{sc}, V_{oc} or maximum power. The results in FIGS. 29A and 29B show that the 3J cell and the Ge cell in the stack work independently without optical and electronic coupling.

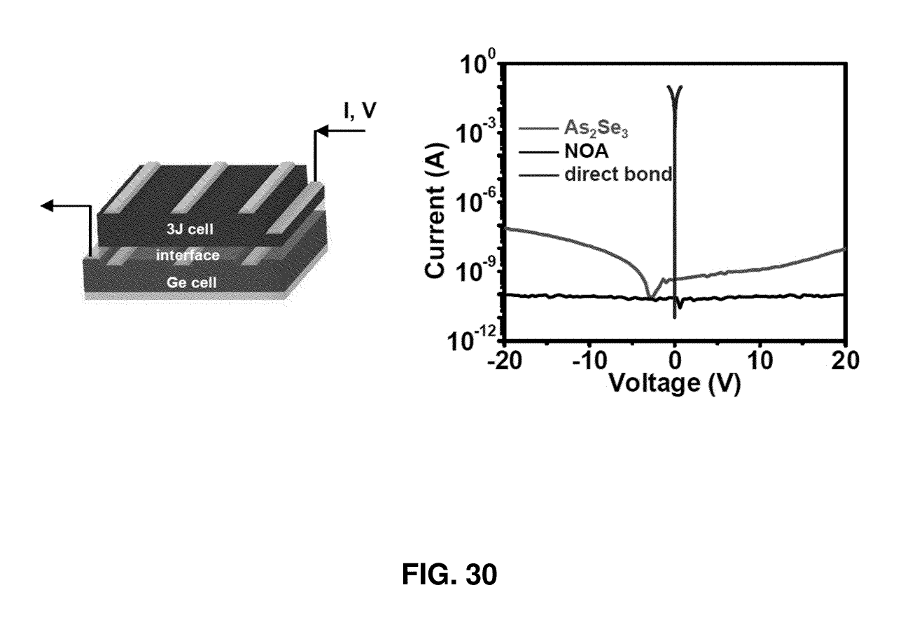

FIG. 30 shows measured current-voltage curves between the bottom p-contact for the 3J cell and the top n-contact for the Ge cell, for cells with different interfaces (also shown in FIG. 4b). The resistivities for As₂Se₃ and NOA are measured to be ˜1010 Ω*cm and ˜1011 Ω*cm, respectively.

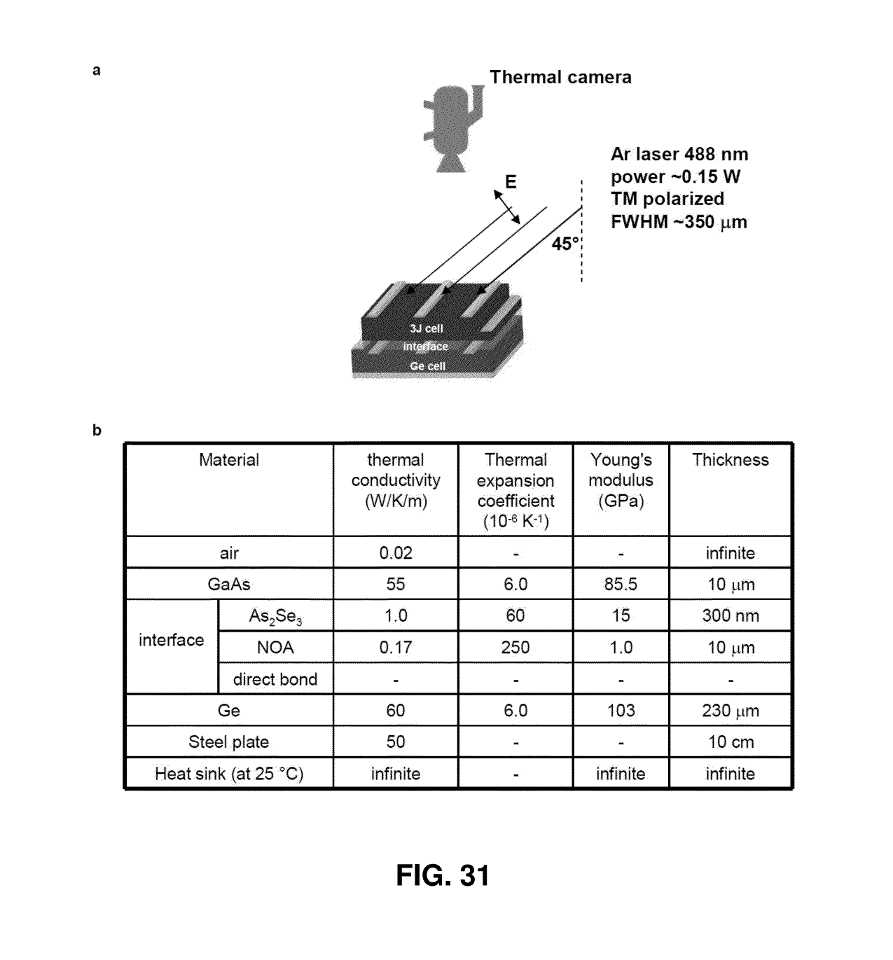

FIG. 31 shows (a) an experimental setup for temperature measurements under laser heating and (b) a layer structure and material properties used in thermal simulations by Finite Element Analysis (FEA). Experiment and simulation results are shown in FIGS. 4f and 4g, respectively. An interfacial thermal conductivity of 85000 W/K/m² (very good thermal contact) is prescribed to simulate the contact interface between the Ge substrates and the stainless steel based optical stage.

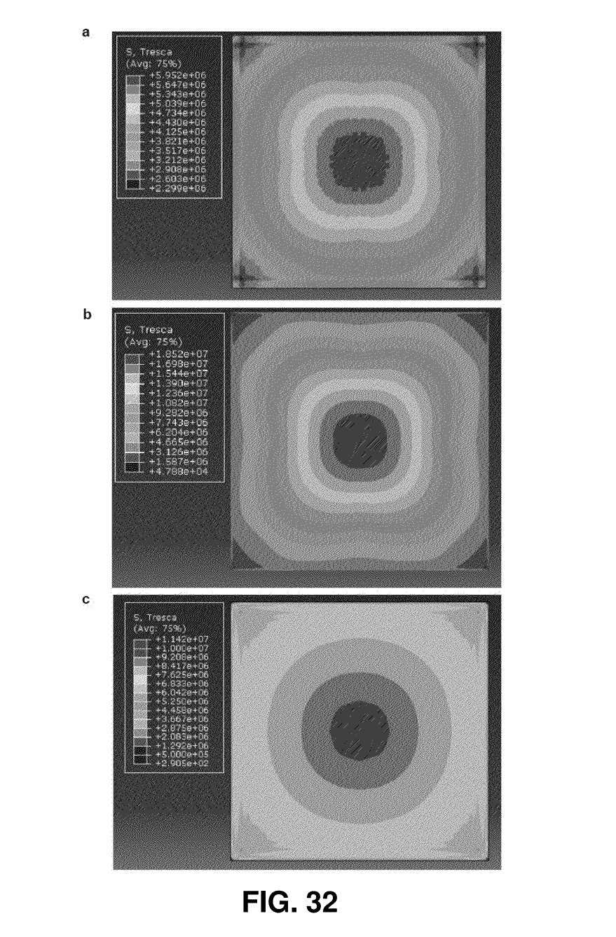

FIG. 32 shows simulated FEA results for Tresca stresses at the interface between 3J cells and adjacent interface layers under laser heating, for the cases of (a) 300 nm As₂Se₃; (b) 10 μm NOA; (c) direct bonding. The unit shown in scale bars is Pa.

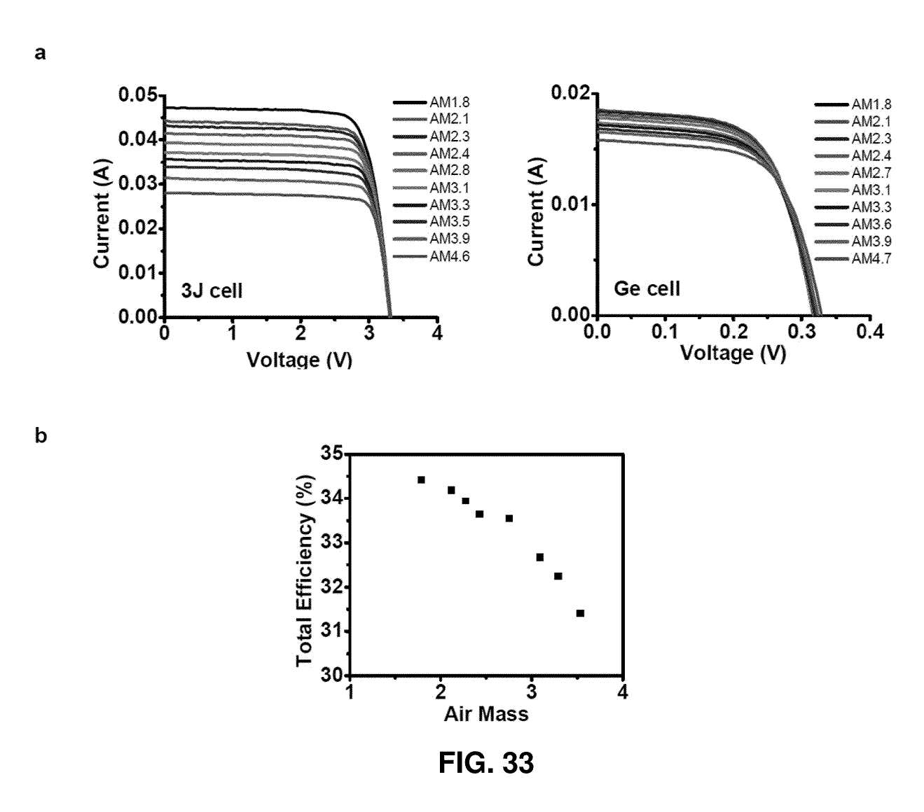

FIG. 33(a) shows I-V curves for an assembled 3J/Ge cell module with concentration optics (FIGS. 5a and 5b). A pair of curves, one for the 3J cell and the other for the Ge cell, were collected under a range of air mass conditions corresponding to different times of the day. FIG. 33(b) shows total efficiency (3J+Ge) versus air mass as measured on sun by comparison to simultaneously measured direct normal irradiance (DNI): efficiency=Pₘₐₓ/(DNI*Aperture area).

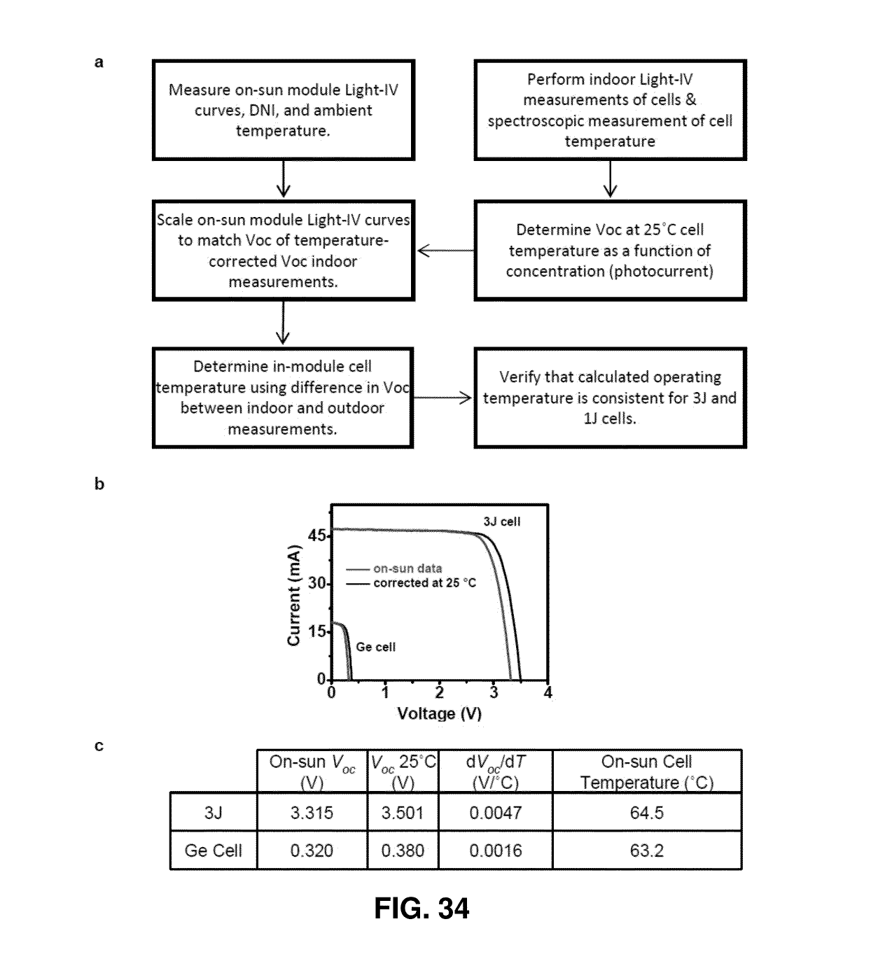

FIG. 34 shows on-sun module light-IVdata and adjustment to account for cell heating in-module. FIG. 34(a) shows a method for determining module performance with cell temperature at 25° C. FIG. 34(b) shows raw light-IV data from on-sun module measurements and adjusted curves obtained through the method of

FIG. 34(a). FIG. 34(c) shows tabulated V_{oc} data from raw on-sun module measurements and indoor measurements. Air Mass at the time of measurement was 1.8, DNI was 914 W/m², and air temperature was 14° C. For indoor measurements, 4 lasers were selected to excite each sub-cell. Lasers were tuned to match currents in each of the 3 upper sub-cells and to produce roughly half of the current in the Ge cell. dV_{oc}/dT values for the 3J cell were determined using the same laser set-up, varying the temperature of the chuck underneath the cells. dV_{oc}/dT for the Ge cell was estimated at one third of the value of dV_{oc}/dT for the 3J.

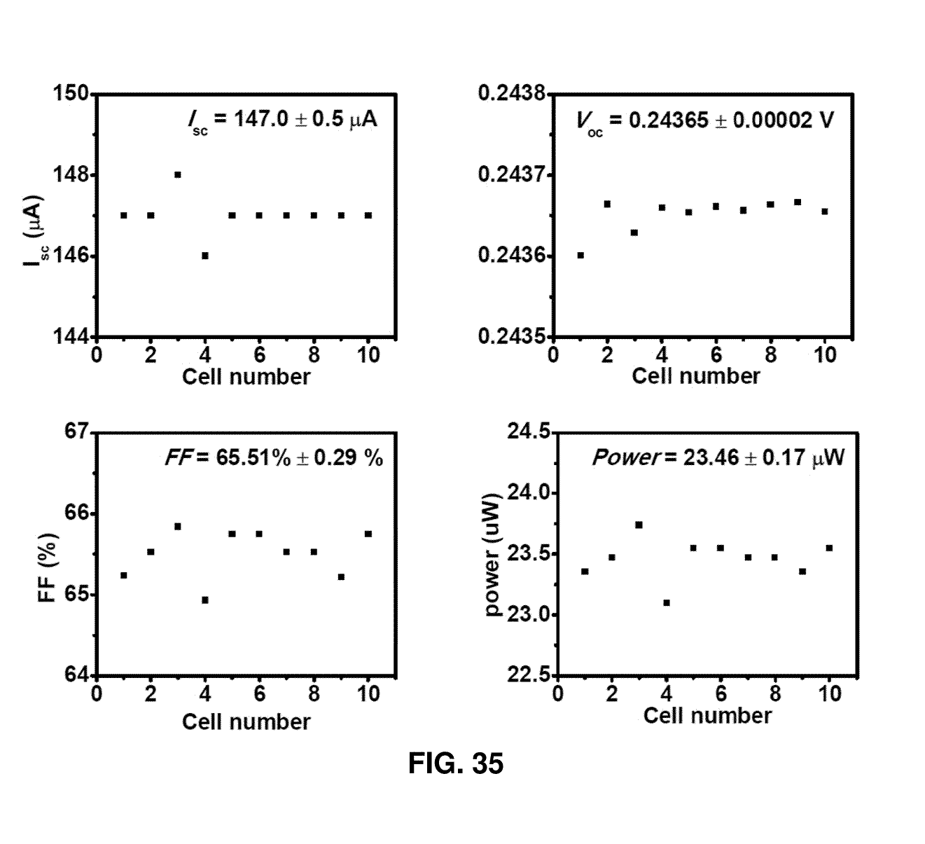

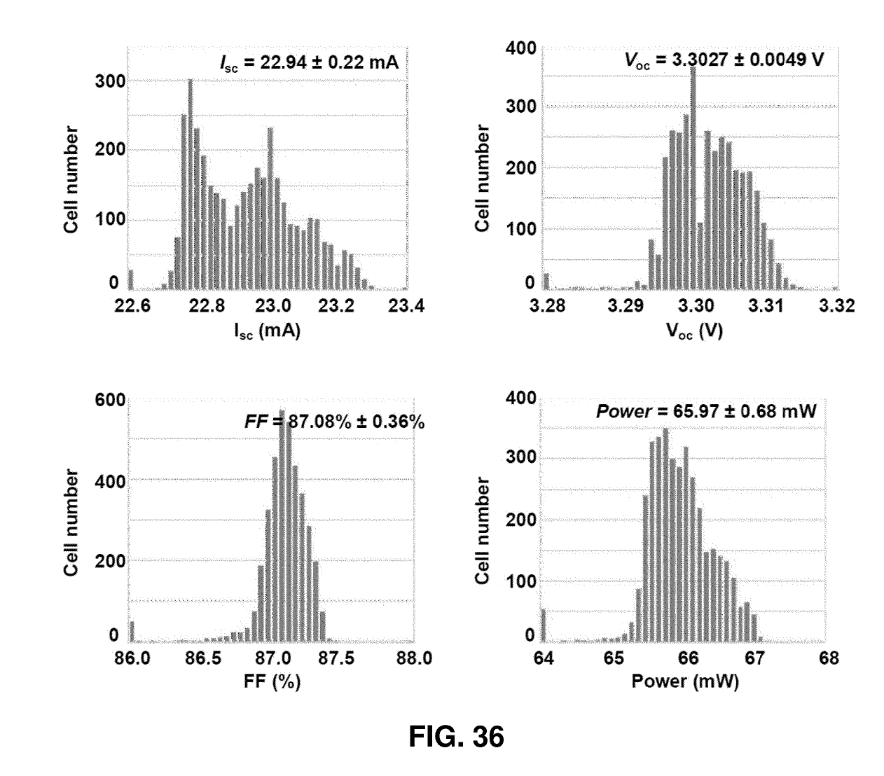

FIG. 35 shows statistical variations in I_{sc}, V_{oc}, FF and power measured for 10 bare Ge cells (no stack, no ARC) under standard AM1.5D one-sun illumination. FIG. 36 shows statistical variations in I_{sc}, V_{oc}, FF and power measured for about 4000 3J cells released on a ceramic substrate, under concentrated illumination (with a power equivalent to ˜400 suns).

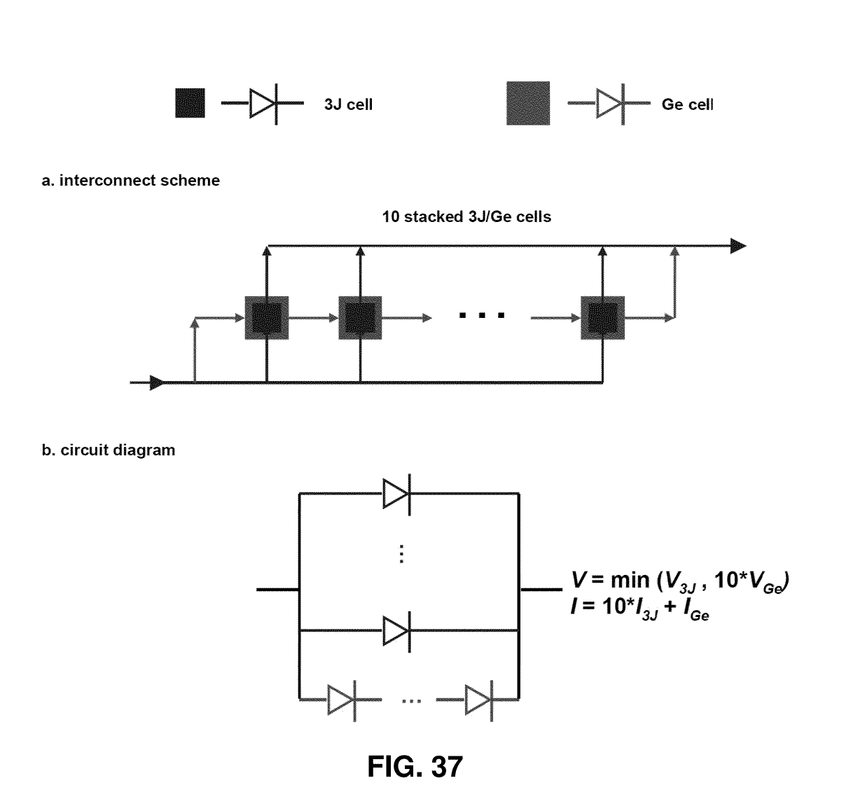

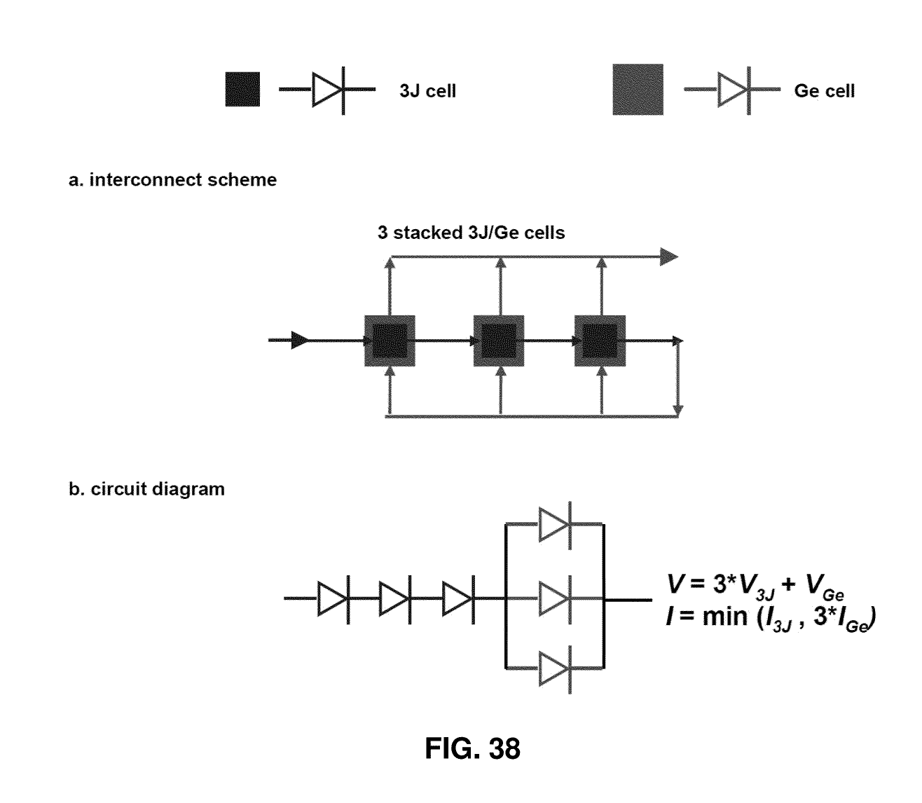

FIG. 37 shows a designed voltage matching interconnected scheme and equivalent circuit diagram for a module array with 10 3J/Ge cells. FIG. 38 shows a designed current matching interconnected scheme and equivalent circuit diagram for a module array with 3 3J/Ge cells.

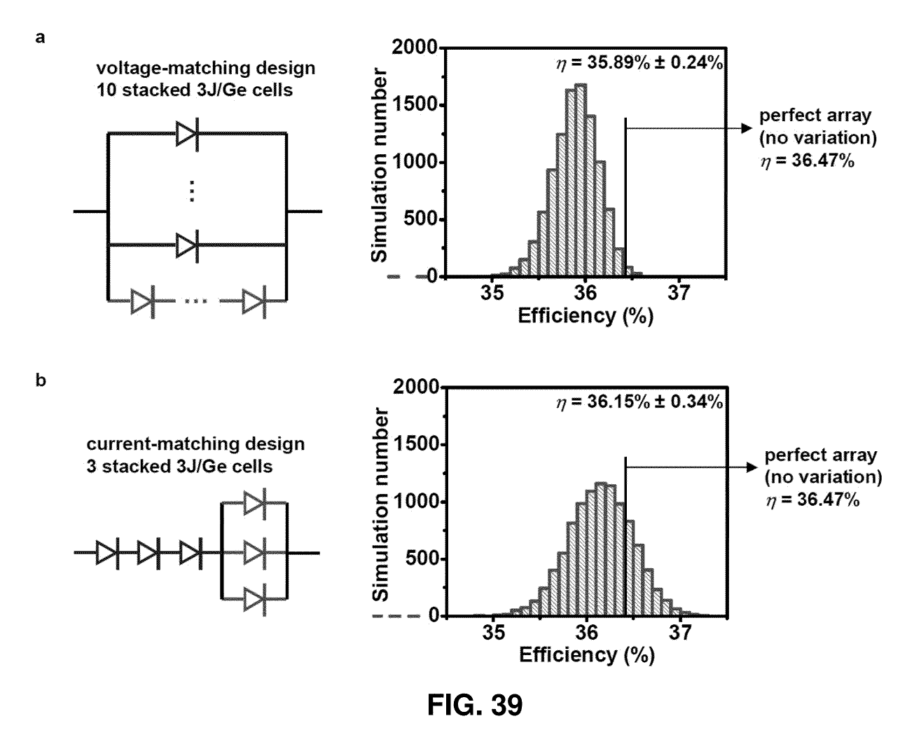

FIG. 39 shows theoretically predicted module performance including the measured cell variation results (FIGS. 35 and 36), assuming both measured current and voltage have a standard deviation of about 1%. FIG. 39(a) shows a voltage-matching design and FIG. 39(b) shows a current-matching design.

### REFERENCES

[1] Kann, S. Evolution and Revolution in the U.S. PV Market. Proc. 39th IEEE Photovolt. Spec. Conf. (2013).
[2] Luque, A. & Hegedus, S. Handbook of Photovoltaic Science and Engineering (Wiley & Sons, 2011).
[3] Polman, A. & Atwater, H. A. Nature Mater. 11, 174-177 (2012).
[4] Green, M. A., Emery, K., Hishikawa, Y., Warta, W. & Dunlop, E. D. Solar cell efficiency tables (version 42). Prog. Photovolt: Res. Appl. 21, 827-837 (2013).
[5] Shockley, W. & Queisser, H. J. Detailed balance limit of efficiency of p-n junction solar cells. J. Appl. Phys. 32, 510-519 (1961).
[6] Luque, A. Will we exceed 50% efficiency in photovoltaics? J. Appl. Phys. 110, 031301 (2011).
[7] Derkacs, D., Jones-Albertus, R., Suarez, F. & Fidaner, O. Lattice-matched multijunction solar cells employing a 1 eV GaInNAsSb bottom cell. J. Photon. Energy 2, 021805 (2012).
[8] King, R. R. et al. 40% efficient metamorphic GaInP/GaInAs/Ge multijunction solar cells. Appl. Phys. Lett. 90, 183516 (2007).
[9] Geisz, J. F. et al. High-efficiency GaInP/GaAs/InGaAs triple-junction solar cells grown inverted with a metamorphic bottom junction. Appl. Phys. Lett. 91, 023502 (2007).
[10] King, R. R. et al. Band-gap-engineered architectures for high-efficiency multijunction concentrator solar cells. Proc. 24th Euro. Photovolt. Solar Energy Conf. 55-61 (2009).
[11] Wojtczuk, S. et al. 42% 500× bi-facial growth concentrator cells. AIP Conf. Proc. 1407, 9-12 (2011).
[12] Sharp develops concentrator solar cell with world's highest conversion efficiency of 44.4%. Sharp Corp. Press Release, Jun. 14, 2013. http://sharp-world.com/corporate/news/130614.html
[13] Tanabe, K., Watanabe, K. & Arakawa, Y. III-V/Si hybrid photonic devices by direct fusion bonding. Sci. Rep. 2, 349 (2012).
[14] Derendorf, K. et al. Fabrication of GaInP/GaAs//Si solar cells by surface activated direct wafer bonding. IEEE J. Photovolt. 3, 1423-1428 (2013).
[15] World Record Solar Cell with 44.7% Efficiency. Fraunhofer ISE Press Release, No. 22/13, Sep. 23, 2013. http://www.ise.fraunhofer.de/en/press-and-media/press-releases/presseinformationen-2013/world-record-solar-cell-with-44.7-efficiency
[16] Gee, J. M. & Virshup, G. F. A 31% efficient GaAs/silicon mechanically stacked, multijunction concentrator solar cell. Proc. 20th IEEE Photovolt. Spec. Conf. 1, 754-758 (1988).
[17] Fraas, L. M. et al. Over 35% efficient GaAs/GaSb stacked concentrator cell assemblies for terrestrial applications. Proc. 21st IEEE Photovolt. Spec. Conf. 1, 190-195 (1990).
[18] Takamoto, T. et al. InGaP/GaAs and InGaAs mechanically-stacked triple-junction solar cells. Proc. 26th IEEE Photovolt. Spec. Conf. 1031-1034 (1997).
[19] Zhao, L., Flamand, G. & Poortmans, J. Recent progress and spectral robustness study for mechanically stacked multi-junction solar sells. AIP Conf. Proc., 1277, 284-289 (2010).
[20] Barnett, A. et al. Very high efficiency solar cell modules. Prog. Photovolt: Res. Appl. 17, 75-83 (2009).
[21] Green, M. A. & Ho-Baillie, A. Forty three percent composite split-spectrum concentrator solar cell efficiency. Prog. Photovolt: Res. Appl. 18, 42-47 (2010).
[22] McCambridge, J. D. et al. Compact spectrum splitting photovoltaic module with high efficiency. Prog. Photovolt: Res. Appl. 19, 352-360 (2011).
[23] Yoon, J. et al. GaAs photovoltaics and optoelectronics using releasable multilayer epitaxial assemblies. Nature 465, 329-333 (2010).
[24] Meitl, M. et al. Materials and processes for releasing printable compound semiconductor devices. International publication number: WO 2012018997A2 (2012).
[25] Posthuma, N. E., van der Heide, J., Flamand G. & Poortmans J. Emitter formation and contact realization by diffusion for germanium photovoltaic devices. IEEE Tran. Electron Dev. 54, 1210-1215 (2007).
[26] Carlson, A., Bowen, A. M., Huang, Y., Nuzzo, R. G. & Rogers, J. A. Transfer printing techniques for materials assembly and micro/nanodevice fabrication. Adv. Mater. 24, 5284-5318 (2012).
[27] Zou, Y. et al. Effect of annealing conditions on the physio-chemical properties of spin-coated As₂Se₃ chalcogenide glass films. Opt. Mater. Express 2, 1723-1732 (2013).
[28] Popescu, M. A. Non-Crystalline Chalcogenides (Kluwer Academic Publishers, 2002).
[29] McBrearty, E. J. et al. Chalcogenide glass films for the bonding of GaAs optical parametric oscillator elements. Proc. SPIE 5273, 430-439 (2003).
[30] Menard, E. et al. Optics development for micro-cell based CPV modules. Proc. SPIE 8108, 810805 (2011).

### ADDITIONAL REFERENCES

Adler, D. Amorphous Semiconductors (CRC Press, 1971).
Fairman, R. & Ushkov, B. Semiconducting Chalcogenide Glass II Properties of Chalcogenide Glasses (Elsevier, 2004).
Kolomiec, B. T. et al. Thermal conductivity of amorphous As₂Se₃ with copper. Czech. J. Phys. B 21, 657-661 (1971).
Voronova, A. E., Ananichev, V. A. & Blinov, L. N. Thermal expansion of melts and glasses in the As—Se system. Glass Phys. Chem. 27, 267-273 (2001).
Shchurova, T. N. & Savchenko, N. D. Correlation between mechanical parameters for amorphous chalcogenide films. J. Optoelectron. Adv. Mater. 3, 491-498 (2001).

### EXAMPLE 2

### Device Architectures for Enhanced Photon Recycling in Thin-Film Multifunction Solar Cells

### Abstract

Multijunction (MJ) solar cells have the potential to operate across the entire solar spectrum, for ultrahigh efficiencies in light to electricity conversion. This example presents an MJ cell architecture that offers enhanced capabilities in photon recycling and photon extraction, compared to those of conventional devices. Ideally, each layer of a MJ cell should recycle and re-emit its own luminescence to achieve the maximum possible voltage. The present design involves materials with low refractive indices as interfaces between sub-cells in the MJ structure. Experiments demonstrate that thin-film GaAs devices printed on low-index substrates exhibit improved photon recycling, leading to increased open-circuit voltages (V_{oc}), consistent with theoretical predictions. Additional systematic studies reveal important considerations in the thermal behavior of these structures under highly concentrated illumination. Particularly when combined with other optical elements such as anti-reflective coatings, these architectures represent important aspects of design for solar cells that approach thermodynamic efficiency limits for full spectrum operation.

### Introduction

In the past few decades, significant research activity has sought to realize thermodynamic efficiency limits in different types of photovoltaic (PV) cells.^{[1-4]} Such efforts are motivated by the substantial reductions in the cost of energy with improved PV system efficiencies.^{[5]} Single junction cells made using semiconductors such as gallium arsenide (GaAs) have a theoretical limit in efficiency of ˜33.4% under one sun illumination, primarily due to the ineffective use of the entire solar spectrum.^{[1]} Multijuction (MJ) cells, by contrast, spectrally split sunlight into sub-cells with different bandgaps, thereby providing pathways to greatly improved efficiencies.^{[6-13]} Conventional MJ cells require lattice matched or metamorphic epitaxial growth of the individual sub-cells. In addition, the serially connected subcells are constrained by current matching since the photocurrent of a two-terminal MJ device is determined by the smallest current among the subcells. These considerations constrain options in material selection, thereby creating practical challenges to the growth of more than three junctions in high performance cells. Recent work demonstrates the ability to use printing techniques to assemble microscale, multijunction, multi-terminal cells with refractive-index matched interfaces, to yield ultrahigh cell and module efficiencies.^{[13]}

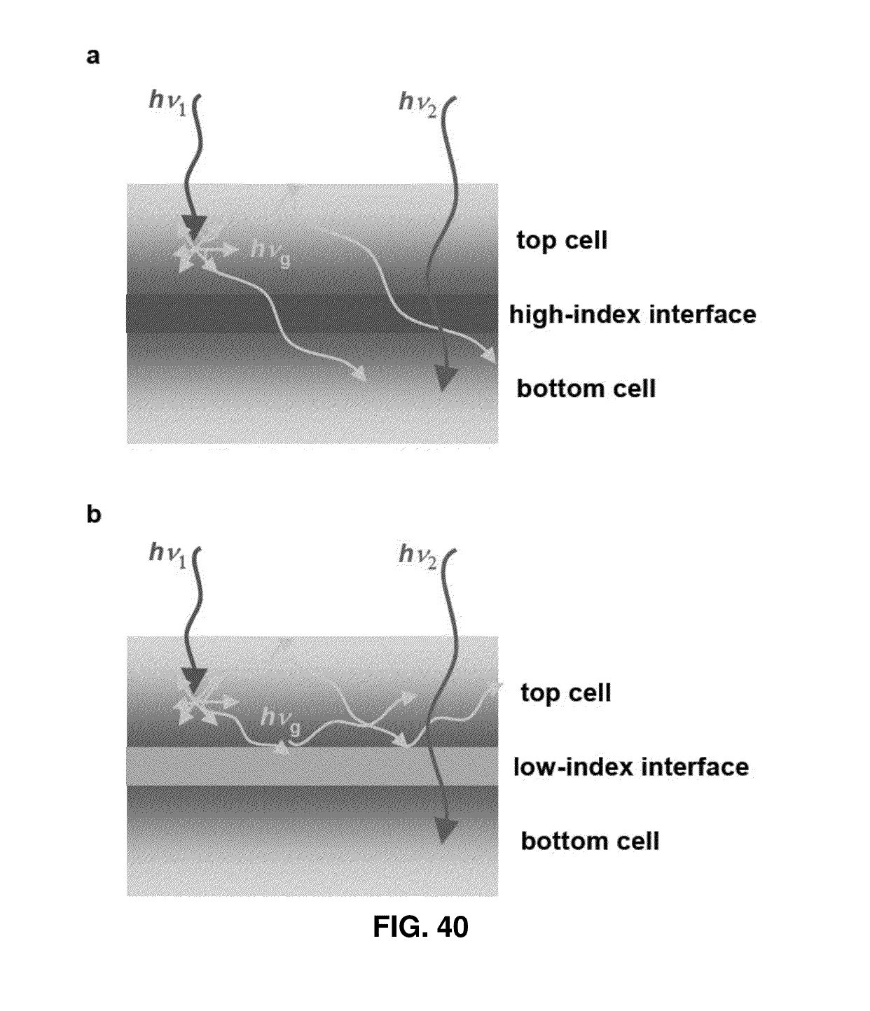

In spite of the promise of such approaches, interfaces that are index matched are unable to recycle and extract infrared photons to approach the detailed balance efficiency limit.^{[14]} FIG. 40a illustrates the challenge through a simple example of a stack of two sub-cells with a refractive-index matched (high-index) interface, which has an index similar to the semiconductor materials used for the solar cells to minimize interface reflection losses. The high bandgap top cell absorbs photons with energies above its bandgap (hν₁>hν_{g}, where hν_{g} is the bandgap of the top cell), while the low bandgap bottom cell absorbs low energy photons below the bandgap of the top cell (hν₂<hν_{g}). When the top cell operates at the open-circuit voltage (V_{oc}), photo-generated electron-hole pairs recombine. As described subsequently, most (˜99%) of the isotropically emitted photons (hν_{g}) generated by radiative recombination are trapped in the stacked device and absorbed by the bottom cell. As a result, the decreased external luminescent efficiency due to inefficient photon recycling leads to a reduced V_{oc} for the top cell.^{[14]}

This example discloses an MJ cell design that minimizes this limitation, through the use of a low-index interface material. As shown in FIG. 40b, photons from the top cell (hν_{g}) that emit outside the escape cone (at angles greater than the critical angle) undergo total internal reflection, without entering the bottom cell where they would be absorbed. The angle averaged reflectance at the low-index interface can be estimated by

$$\overline{R} = {\int }_{0}^{\frac{π}{2}} R ( θ ) sin θ d θ = {\int }_{0}^{{θ}_{c}} R ( θ ) sin θ d θ + cos {θ}_{c} \qquad ( 1 )$$

where θ_{c} is the critical angle for total internal reflection at the interface (sin θ_{c}=n_{interface}/n_{cell}), n_{interface} and n_{cell} are the refractive indices of the interface material and the solar cell material, respectively, and R(θ) is reflectance at the interface for light with different propagation angles and polarizations, which can be calculated by the transfer-matrix method. This expression indicates that R̅ increases with the difference between the index of the cell and the interface material. For the case of a GaAs top cell (n_{cell}=3.5) and an air gap interface (n_{interface}=1.0), R̅ is ˜98%. This result clearly indicates the high degree with which photon recycling can be enabled in this way. The outcome is an increased external luminescent efficiency and V_{oc} for the top cell.^{[15]} At the same time, normally incident low energy photons (hν₂<hν_{g}) can pass through the interface to reach the bottom cell. Antireflective coatings (ARCs) can be used to minimize reflection losses for low energy photons without affecting R for isotropically re-emitted photons, as described subsequently.

### Results and Discussion

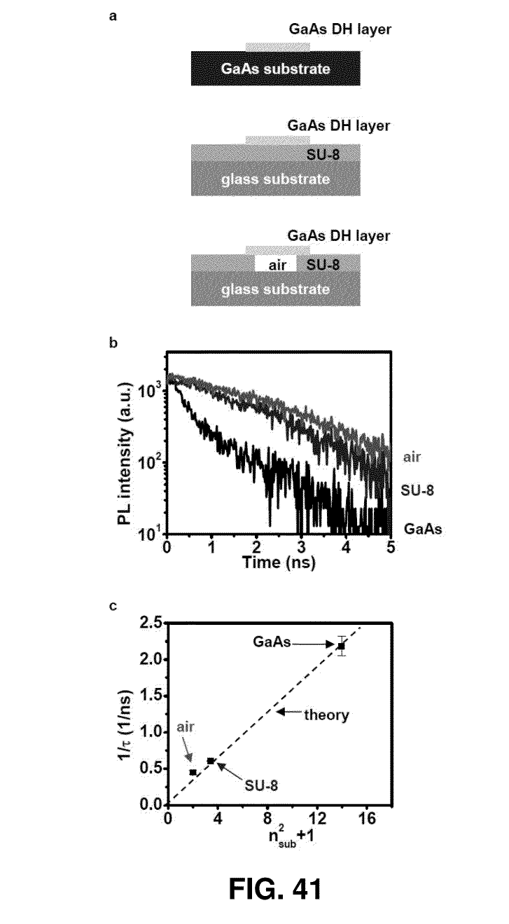

The luminescent properties for thin-film semiconductor layers on substrates with different refractive indices reveal essential aspects of the photon recycling processes, as shown in FIG. 41. Here, GaAs-based double heterostructure (DH) thin films (100 nm Al_{0.3}Ga_{0.7}As/1000 nm GaAs/100 nm Al_{0.3}Ga_{0.7}As) act as active device layers. The DHs are grown on a GaAs wafer with a lattice matched Al_{0.95}Ga_{0.05}As sacrificial layer, to enable release by epitaxial liftoff. FIG. 41a schematically illustrates these layers on a GaAs substrate (unreleased), and transfer printed onto a glass substrate with a 25 μm thick layer of a photodefinable epoxy (SU-8) layer, and onto a glass substrate with a 25 μm thick air gap in between, respectively. The SU-8 layer and the air gap are sufficiently thick that the underlying glass substrates have negligible effects on the evanescent photon outcoupling from the GaAs DH layers. FIG. 41b presents photoluminescence (PL) decay measurements for these various substrates (GaAs, SU-8 and air) under excitation at 776 nm. At high carrier densities, the radiative recombination lifetimes, τ, are (0.46±0.03) ns, (1.64±0.01) ns and (2.22±0.14) ns, for GaAs DH layers on GaAs, SU-8 and air, respectively. These results are consistent with inhibition of spontaneous emission by use of low-index substrates and, therefore, significant enhancements in the emission lifetime as well as the photon recycling.^{[16,17]} FIG. 41c plots 1/τ as a function of n_{sub}²+1, where n_{sub} is the refractive index of the substrate material (n_{sub}=3.5, 1.5 and 1.0 for GaAs, SU-8 and air, respectively). The linear relationship between 1/τ and n_{sub}²+1 is consistent with theory.^{[16]}

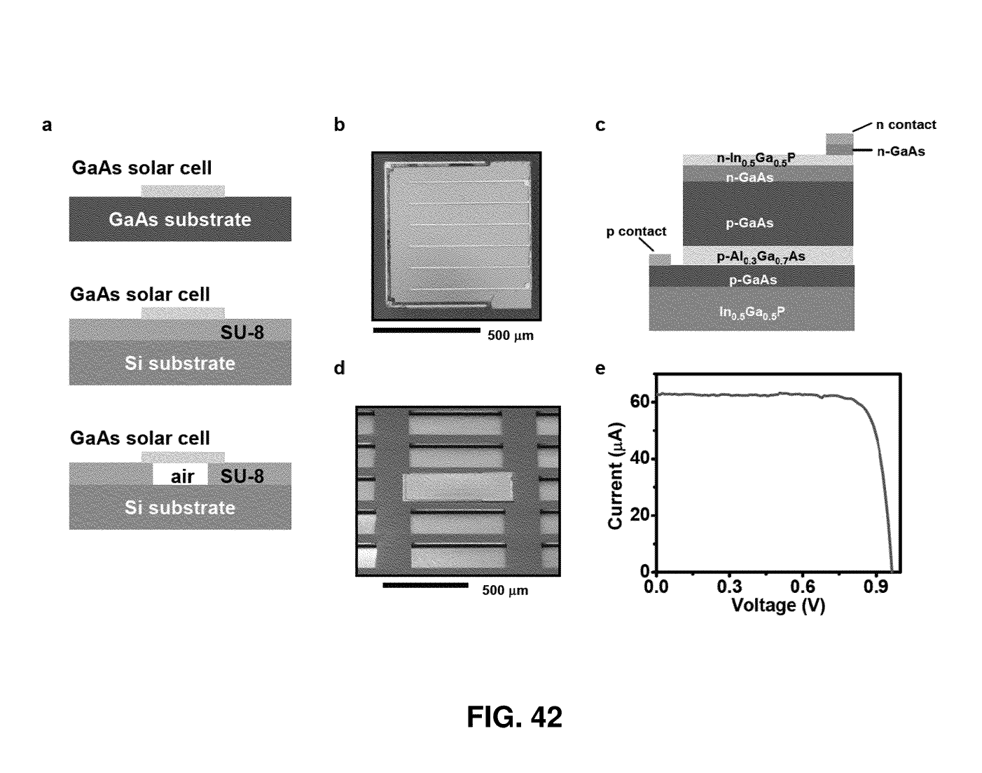

FIG. 42a shows microscale, thin-film GaAs solar cells placed on different substrates using similar epitaxial liftoff and printing approaches. The cells (with an active device area of about 0.39 mm²) use a vertical GaAs homojunction with metalized contacts on both p and n sides (FIGS. 42b and 42c). FIG. 42d presents a representative cell on a patterned film of SU-8, where the majority of the cell area remains suspended over an air gap (25 μm thick). FIG. 42e plots the corresponding current-voltage response under one-sun illumination (AM1.5g spectrum). The cell (without an ARC) reaches a short-circuit current (I_{sc}) of 62.8 μA, an open-circuit voltage (V_{oc}) of 0.96 V and a fill factor (FF) of 82%, corresponding to an efficiency of ˜12.7%.

As demonstrated in FIG. 41b, the refractive index of the substrate medium affects the spontaneous emission rate and the photon recycling processes. Analytically, the V_{oc} can be expressed as^{[18]}

$${V}_{oc} = {V}_{db} + \frac{kT}{q} ln ( {η}_{ext} ) = {V}_{db} + \frac{kT}{q} ln ( \frac{{η}_{int} \overline{{P}_{esc}}}{1 - {η}_{int} \overline{{P}_{abs}}} ) \qquad ( 2 )$$

where V_{db} is the ideal V_{oc} obtained at the detailed balance limit, ηₑₓₜ is the external luminescent efficiency for the emitted photons escaping from the cell front surface, ηᵢₙₜ is the internal luminescent efficiency, and P̅_̅{̅e̅s̅c̅}̅ and P̅_̅{̅a̅b̅s̅}̅ are the averaged probabilities of photon escape and re-absorption, respectively. P̅_̅{̅e̅s̅c̅}̅ and P̅_̅{̅a̅b̅s̅}̅ are determined by the optical properties of the GaAs device layers as well as the substrate index n.

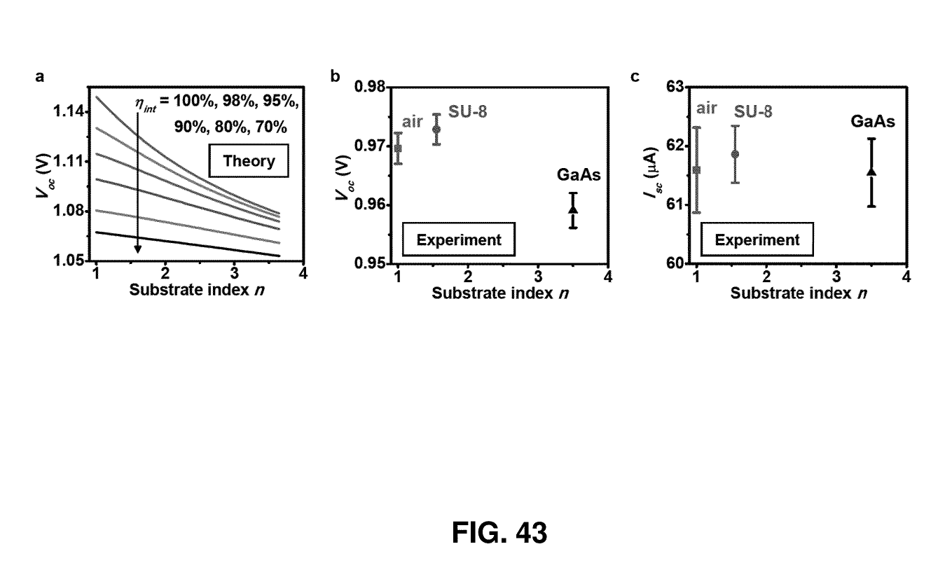

FIG. 43a calculates the relationship between V_{oc} and substrate index n, for different ηᵢₙₜ. Since increases in n lead to reductions in P̅_̅{̅e̅s̅c̅}̅ and increases in P̅_̅{̅a̅b̅s̅}̅, V_{oc} decreases monotonically with n. These analytical results are qualitatively consistent with one-sun current-voltage measurements (FIGS. 43b and 43c) on multiple GaAs cells (˜30 cells) placed on different substrates, as shown in FIG. 42a. The cells printed on Si substrates with low-index interfaces (air gap and SU-8) exhibit higher V_{oc} (0.970 V±0.003 V and 0.973 V±0.003 V for air and SU-8 interfaces, respectively) than unreleased cells on high-index GaAs substrates (0.959 V±0.003 V). The I_{sc} for all the cells remain similar. The averaged one-sun efficiencies are increased from 12.7% for unreleased GaAs cells to about 12.8% for cells with air and SU-8 interfaces. The experimental values of V_{oc} (0.95-0.98 V) are lower than the theoretically calculated values (1.05-1.15 V), likely due to the non-optimal electrical design, which leads to a lower V_{db}. The averaged V_{oc} measured for the cells with the air gap interface are lower than that for cells with the SU-8 interface. This deviation from theoretical predictions is likely associated with the mechanical instabilities (for example, bowing) for the cells suspending on the air gap patterns, as well as measurement variations. As discussed below, one-sun illumination induces negligible temperature changes for all the cells on various substrates. Therefore, thermal effects can be excluded as a source of variations in V_{oc} and I_{sc}.

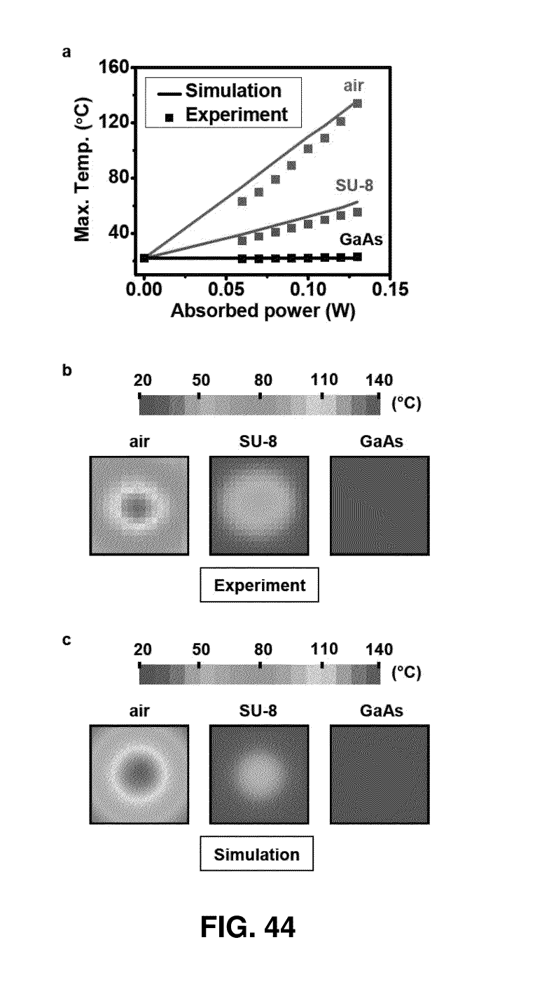

The most practical embodiments of MJ cells for terrestrial use require optical concentrators, to enable low-cost and high-efficiency operation. Under high power irradiance, thermal management is critically important. A focused laser beam (488 nm, tunable power) incident on cells with different substrates shown in FIG. 42a serves to simulate the thermal effects of concentrated sunlight. FIG. 44a compares the experiential and the simulated (using steady state conjugate heat transfer finite element model) maximum temperatures on the surfaces of the cells, as a function of absorbed laser power between 0 and 0.13 W. Under irradiance power equivalent to one-sun illumination (˜5×10⁻⁴ W), temperature changes are negligible for all cases. As the power increases, temperatures increase for cells with air gap and SU-8 interfaces, while the temperatures for cells on GaAs remain close to room temperature. FIG. 44b presents measured and simulated temperature distributions (map size: 0.7 mm×0.7 mm) on the cell surfaces for an absorbed laser power of 0.13 W, which is equivalent to the irradiance, power at a concentration level of about 250 suns. The maximum surface temperatures for air gap, SU-8 and GaAs interfaces are measured to be 134° C., 56° C. and 22° C., respectively, which agree with the simulation results. These temperature differences can be attributed to differences in thermal conductivities of the different interface materials (0.02 W/m/K for air, 0.2 W/m/K for SU-8 and 55 W/m/K for GaAs). The results suggest that thermal management is important to consider, particularly for low-index interfaces that have low thermal conductivity (e.g. air gap or SU-8). An effective way to minimize increases in cell temperature is to reduce the thickness of the low index material, as shown for the case of an air gap in FIG. 44c. Here, the calculated maximum temperature decreases from 130° C. to 20° C., as the gap size decreases from 25 μm to 0 μm. Meanwhile, the optical reflectance at the interface (calculated using Equation 1) decreases as the gap size approaches the sub-wavelength scale, due to the increased evanescent coupling. Air gap of ˜200-1000 nm balance these considerations in optical and thermal performance. The inset of FIG. 44c illustrates the measured temperature distribution for a GaAs cell printed on a Si substrate with a 500 nm thick air gap interface. The maximum cell temperature is around 35° C., in agreement with the numerical calculation.

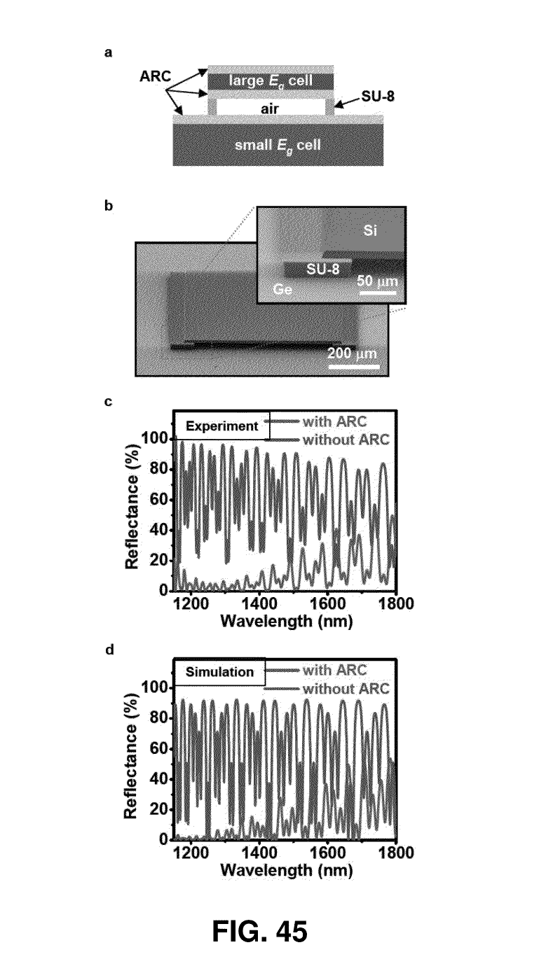

The results demonstrated here indicate that MJ device architectures with low-index interfaces can effectively improve V_{oc} for the top cell due to enhanced photon recycling processes. To enable low energy photons to pass through the top cell and reach the bottom cell with minimized losses, anti-reflective coatings can be introduced between the cells and the low-index interface materials (air or SU-8), as illustrated in FIG. 45a. While these ARCs allow low energy photons to pass through the top cell, total internal reflection (TIR) conditions remain for re-emitted photons, since the critical angle θ_{c} for TIR is still determined by the solar cell material and the low-index interlace material (sin θ_{c}=nₐᵢᵣ/n_{cell}). As a result, photon recycling processes inside the top cell are largely unaffected by the ARCs. FIG. 45b shows a proof-of-concept device layout made using a silicon/germanium (Si/Ge) stacked structure with an air gap interface. (More realistic device demonstrations can be achieved using semiconductors with high luminescence efficiencies like GaAs and InGaAs.) A thin-film Si layer (size 0.7 mm×0.7 mm, thickness 10 μm) released from a silicon-on-insulator wafer printed onto a Ge substrate with patterned posts of SU-8 forms a 25 μm thick air gap in between. A 150 nm thick layer of HfO₂ (n˜2.0) formed on both front and back surfaces of the Si as well as the front surface of the Ge, using atomic layer deposition (ALD), forms an ARC. Reflection spectra measured and simulated for the Si/air gap/Ge stacked structures with and without ARCs appear in FIGS. 45c and 45d, respectively, for wavelengths between 1150 nm and 1800 nm, where photons can pass through the Si to be absorbed by the Ge. The introduction of ARCs greatly suppresses the Fresnel reflection losses at the cell/air interfaces, by reducing the averaged reflectance from 61% (without ARCs) to 13% (with ARCs). Further improvements in optical efficiencies can be achieved, for example, by using multilayered ARCs at all of the cell surfaces.^{[19]}

### Conclusion

In summary, the results presented here illustrate an MJ solar cell architecture in which efficiency improvements are achieved by using low refractive index interfaces between different sub-cells. Released thin-film GaAs micro cells printed on structures with low-index air and SU-8 interfaces exhibit enhanced photon recycling effects and thus increased V_{oc}. This device design can be applied to practical MJ devices, such as InGaP/GaAs double junction or InGaP/GaAs/InGaAs triple junction cells, with potential to reach higher cell efficiencies than those possible with conventional devices and to eliminate requirements of lattice and current matching. In addition, vertically stacked device architectures realized by processes of epitaxial liftoff and transfer printing avoid complexities in optical design associated with other spectral splitting methods.^{[20,21]} For cells that operate under high concentrations, additional issues in thermal management must be considered. Thermally conductive interface materials such as low-index oxides or fluids might be used to replace air or SU-8, thereby facilitating heat dissipation. The collective set of design and assembly concepts presented here provide potential routes to PV devices that further approach thermodynamic limits in efficiency.

### Experimental Section

Fabrication of GaAs double heterostructures (DH) and micro solar cells: The GaAs DH and solar cell device structures are grown on GaAs substrates using metal-organic chemical vapor deposition (MOCVD). The DH structure (from bottom to top) includes: the GaAs substrate, a 500 nm Al_{0.95}Ga_{0.05}As sacrificial layer, a 5 nm GaAs protection layer, a 100 nm n-Al_{0.3}Ga_{0.7}As (n=3×10¹⁸ cm⁻³), a 1000 nm p-GaAs (p=5×10¹⁷ cm⁻³), a 100 nm p-Al_{0.3}Ga_{0.7}As (p=3×10¹⁸ cm⁻³), and another 5 nm GaAs protection layer. The solar cell structure (from bottom to top) includes: the GaAs substrate, a 500 nm Al_{0.95}Ga_{0.05}As sacrificial layer, a 700 nm In_{0.5}Ga_{0.5}P supporting layer, a 300 nm p-GaAs (p=3×10¹⁹ cm⁻³) bottom contact layer, a 100 nm p-Al_{0.3}Ga_{0.7}As (p=5×10¹⁸ cm⁻³) back surface field (BSF) layer, a 2500 nm p-GaAs (p=1×10¹⁷ cm⁻³)base layer, a 100 nm n-GaAs (n=2×10¹⁸ cm⁻³) emitter layer, a 25 nm n-In_{0.5}Ga_{0.5}P (n=2×1 0¹⁸ cm⁻³) window layer and a 200 nm n-GaAs (n=1×10¹⁹ cm⁻³) top contact layer. Zn and Si serve as p-type and n-type dopants, respectively. 10 nm Cr/200 nm Au serve as electrical contacts. The DH and solar cell devices (size 0.7 mm×0.7 mm) are lithographically fabricated, with the Al_{0.95}Ga_{0.05}As sacrificial layer removed by a hydrofluoric acid (HF) based solution (ethanol:HF=1.5:1 by volume).^{[22,23]} Subsequently, individual DH and solar cells devices are transfer printed onto other substrates (glass and Si) with different interfaces (air gap and SU-8) using shaped PDMS stamps.^{[24]} The air gaps (0.5 mm×0.5 mm) are formed by lithographically defined patterns in SU-8 (25 μm thick).

Device Characterization: Photoluminescence (PL) decay measurements are performed using GaAs DH layers printed on different substrates. Excitation light is generated by using a supercontinuum laser (NKT Photonics EXR-15) passed through a bandpass filter (center wavelength 776 nm, FWHM=10 nm). PL intensity is collected by a single photon detector (ID Quantique id100-20). The current-voltage curves of GaAs solar cells are measured by a Keithley 2400 source meter under standard AM1.5g illumination.

Thermal Measurement and Modeling: Steady-state temperature distributions on the top surface of micro cells on different substrates are measured by a thermal imaging camera (FLIR A655sc), under irradiance generated with an Argon laser beam (center wavelength 488 nm, Gaussian beam width 0.35 mm, TM polarized). A 3D steady-state conjunct heat transfer finite element analysis model is developed (COMSOL Multiphysics) to evaluate the temperature rise during the laser heating. The model accounts for the heat transfer through different interfaces (air, SU-8 and GaAs) underneath the cells, as well as the natural heat convection to the atmosphere due to air interaction with cell surfaces. Furthermore, the thermal radiation from cells to the atmosphere has been included in the model assuming an emissivity of 0.7 for GaAs. It should be noted that the near-field heat transfer effect is not taken into account in the model, which may cause some deviations at sub-micron scale.

Optical Reflection Measurement and Modeling: Infrared reflectance spectra for the Si/air gap/Ge stacked structures with and without ARCs are measured using a microscope-coupled Fourier transform infrared (FTIR) spectrometer (Bruker Vertex). Transfer matrix method is used to simulate optical reflections of the multilayer structures.

### REFERENCES

[1] W. Shockley, H. J. Queisser, J. Appl. Phys. 1961, 32, 510.
[2] A. Polman, H. A. Atwater, Nature Mater. 2012, 11, 174.
[3] A. Luque, J. Appl. Phys. 2011, 110, 031301.
[4] M. A. Green, K. Emery, Y. Hishikawa, W. Warta, E. D. Dunlop, Prog. Photovolt: Res. Appl. 2014, 22, 1.
[5] C. Breyer, A. Gerlach, Prog. Photovolt: Res. Appl. 2013, 21, 121.
[6] K. A. Bertness, S. R. Kurtz, D. J. Friedman, A. E. Kibbler, C. Kramer, J. M. Olson, Appl. Phys. Lett. 1994, 65, 989.
[7] D. Derkacs, R. Jones-Albertus, F. Suarez, O. Fidaner, J. Photon. Energy 2012, 2, 021805.
[8] R. R. King, D. C. Law, K. M. Edmondson, C. M. Fetzer, G. S. Kinsey, H. Yoon, R. A. Sherif, N. H. Karam, Appl. Phys. Lett. 2007, 90, 183516.
[9] J. F. Geisz, Sarah Kurtz, M. W. Wanlass, J. S. Ward, A. Duda, D. J. Friedman, J. M. Olson, W. E. McMahon, T. E. Moriarty, J. T. Kiehl, Appl. Phys. Lett. 2007, 91, 023502.
[10] R. R. King, A. Boca, W. Hong, X. Q. Liu, D. Bhusari, D. Larrabee, K. M. Edmondson, D. C. Law, C. M. Fetzer, S. Mesropian, N. H. Karam, Proc. 24th Euro. Photovolt. Solar Energy Conf. 2009, 55.
[11] S. Wojtczuk, P. Chiu, X. Zhang, D. Pulver, C. Harris, B. Siskavich, AIP Conf. Proc. 2011, 1407, 9.
[12] K. Sasaki, T. Agui, K. Nakaido, N. Takahashi, R. Onitsuka, T. Takamoto, AIP Conf. Proc. 2013, 1556, 22.
[13] X. Sheng, C. A. Bower, S. Bonafede, J. W. Wilson, B. Fisher, M. Meitl, H. Yuen, S. Wang, L. Shen, A. R. Banks, C. J. Corcoran, R. G. Nuzzo, S. Burroughs, J. A. Rogers, Nat. Mater. 2014, 13, 593.
[14] 0. D. Miller, E. Yablonovitch, S. R. Kurtz, IEEE J. Photovolt. 2012, 2, 303.
[15] V. Ganapati, C. S. Ho, E. Yablonovitch, “Intermediate Mirrors to Reach Theoretical Efficiency Limits of Multijunction Solar Cells”, IEEE J. Photovolt. submitted.
[16] E. Yablonovitch, T. J. Gmitter, R. Bhat, Phys. Rev. Lett. 1988, 61, 2546.
[17] P. Renaud, F. Raymond, B. Bensaid, C. Verie, J. Appl. Phys. 1992, 71, 1907.
[18] M. A. Steiner, J. F. Geisz, I. Garcia, D. J. Friedman, A. Duda, S. R. Kurtz, J. Appl. Phys. 2013, 113, 123109.
[19] L. Zhao, G. Flamand, J. Poortmans, AIP Conf. Proc. 2010, 1277, 284.
[20] A. Barnett, D. Kirkpatrick, C. Honsberg, D. Moore, M. Wanlass, K. Emery, R. Schwartz, D. Carlson, S. Bowden, D. Aiken, A. Gray, S. Kurtz, L. Kazmerski, M. Steiner, J. Gray, T. Davenport, R. Buelow, L. Takacs, N. Shatz, J. Bortz, O. Jani, K. Goossen, F. Kiamilev, A. Doolittle, I. Ferguson, B. Unger, G. Schmidt, E. Christensen, D. Salzman, Prog. Photovolt: Res. Appl. 2009, 17, 75.
[21] J. D. McCambridge, M. A. Steiner, B. L. Unger, K. A. Emery, E. L. Christensen, M. W. Wanlass, A. L. Gray, L. Takacs, R. Buelow, T. A. McCollum, J. W. Ashmead, G. R. Schmidt, A. W. Haas, J. R. Wilcox, J. Van Meter, J. L. Gray, D. T. Moore, A. M. Barnett, R. J. Schwartz, Prog. Photovolt: Res. Appl. 2011, 19, 352.
[22] X. Sheng, L. Shen, T. Kim, L. Li, X. Wang, R. Dowdy, P. Froeter, K. Shigeta, X. Li, R. G. Nuzzo, N. C Giebink, J. A. Rogers, Adv. Energy Mater. 2013, 3, 991.
[23] X. Sheng, C. J. Corcoran, J. He, L. Shen, S. Kim, J. Park, R. G. Nuzzo, J. A. Rogers, Phys. Chem. Chem. Phys. 2013, 15, 20434.
[24] A. Carlson, H. J. Kim-Lee, J. Wu, P. Elvikis, H. Cheng, A. Kovalsky, S. Elgan, Q. Yu, P. M. Ferreira, Y. Huang, K. T. Turner, J. A. Rogers, Appl. Phys. Lett. 2011, 98, 264104.

### STATEMENTS REGARDING INCORPORATION BY REFERENCE AND VARIATIONS

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

When a group of substituents is disclosed herein, it is understood that all individual members of that group and all subgroups, including any isomers, enantiomers, and diastereomers of the group members, are disclosed separately. When a Markush group or other grouping is used herein, all individual members of the group and all combinations and subcombinations possible of the group are intended to be individually included in the disclosure. When a compound is described herein such that a particular isomer, enantiomer or diastereomer of the compound is not specified, for example, in a formula or in a chemical name, that description is intended to include each isomer and enantiomer of the compound described individually or in any combination. Additionally, unless otherwise specified, all isotopic variants of compounds disclosed herein are intended to be encompassed by the disclosure. For example, it will be understood that any one or more hydrogens in a molecule disclosed can be replaced with deuterium or tritium. Isotopic variants of a molecule are generally useful as standards in assays for the molecule and in chemical and biological research related to the molecule or its use. Methods for making such isotopic variants are known in the art. Specific names of compounds are intended to be exemplary, as it is known that one of ordinary skill in the art can name the same compounds differently.

Many of the molecules disclosed herein contain one or more ionizable groups [groups from which a proton can be removed (e.g., —COOH) or added (e.g., amines) or which can be quaternized (e.g., amines)]. All possible ionic forms of such molecules and salts thereof are intended to be included individually in the disclosure herein. With regard to salts of the compounds herein, one of ordinary skill in the art can select from among a wide variety of available counterions those that are appropriate for preparation of salts of this invention for a given application. In specific applications, the selection of a given anion or cation for preparation of a salt may result in increased or decreased solubility of that salt.

Every formulation or combination of components described or exemplified herein can be used to practice the invention, unless otherwise stated.

Whenever a range is given in the specification, for example, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when compositions of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

1. A multi-junction photovoltaic device comprising:
a first photovoltaic p-n junction structure characterized by a thickness and lateral dimensions, said first photovoltaic p-n junction structure having a first interface surface;
a second photovoltaic p-n junction structure characterized by a thickness and lateral dimensions, said second photovoltaic p-n junction structure having a second interface surface; and
an interface layer provided between said first interface surface and said second interface surface, said interface layer comprising a chalcogenide dielectric layer;
wherein said first photovoltaic p-n junction structure, said interface layer and said second photovoltaic p-n junction structure are provided in a stacked multilayer geometry.

2. The device of claim 1, wherein said lateral dimensions of said first photovoltaic p-n junction structure and said second photovoltaic p-n junction structure are each independently less than or equal to 3000 microns.

3. The device of claim 1, wherein said lateral dimensions of said first photovoltaic p-n junction structure, said second photovoltaic p-n junction structure or both are independently selected from the range of 800 microns to 3000 microns.

4. The device of claim 1, wherein said multi-junction photovoltaic device is characterized by a conversion efficiency for incident solar radiation greater than or equal to 43%.

5. The device of claim 1, wherein said interface layer is provided using a sol-gel process, a spin-on process, a spray process or a combination thereof.

6. The device of claim 1, wherein said interface layer comprises an electrically insulating layer characterized by an electrical resistance greater than or equal to 100,000 Ωcm².

7. The device of claim 1, wherein said interface layer comprises a refractive index-matched layer characterized by a refractive index within 30% of the refractive indices at said first interface surface and said second interface surface.

8. The device of claim 1, wherein said interface layer comprises a thermally conductive layer characterized by a thermal conductivity greater than or equal to 0.5 W/m/K.

9. The device of claim 1, wherein said interface layer comprises an optically transparent layer characterized by a transmittance equal to or greater than 90% for light having wavelengths selected over the range of 800 nm to 1800 nm.

10. The device of claim 1, wherein said interface layer comprises an electrostatically stable layer characterized by an electrical breakdown threshold voltage equal to or greater than 15 V.

11. The device of claim 1, wherein said interface layer has a thickness selected from the range of 50 nm to 5 microns.

12. The device of claim 1, wherein said interface layer comprises a selenide, a sulfide or a telluride composition.

13. The device of claim 1, wherein said interface layer comprises As₂Se₃.

14. The device of claim 1, wherein said first photovoltaic p-n junction structure, said second photovoltaic p-n junction structure or both independently comprise epitaxially grown multilayer structures.

15. The device of claim 1, wherein said first photovoltaic p-n junction structure is not epitaxially grown on top of said second photovoltaic p-n junction structure and said second photovoltaic p-n junction structure is not epitaxially grown on top of said first photovoltaic p-n junction structure.

16. The device of claim 1, wherein said first photovoltaic p-n junction structure comprises 1-4 p-n junctions and said second photovoltaic p-n junction structure comprises 1-3 p-n junctions.

17. The device of claim 1, wherein said first photovoltaic p-n junction structure and said second photovoltaic p-n junction structure comprise different multi-junction structures.

18. The device of claim 1, wherein said first photovoltaic p-n junction structure has a different composition than said second photovoltaic p-n junction structure.

19. The device of claim 1, wherein said first photovoltaic p-n junction structure has a composition selected from the group consisting of: InGaP/GaAs/InGaAsNSb; AlGaAs; InGaAlP and combinations of these.

20. The device of claim 1, wherein said second photovoltaic p-n junction structure has a composition selected from the group consisting of: a diffusion-junction Ge cell; InGaAs; InGaAsP; AlGaInAs and combinations of these.

21. The device of claim 1, wherein said first photovoltaic p-n junction structure and said second photovoltaic p-n junction structure each have a thickness selected from the range of 1 micron to 250 microns.

22. The device of claim 1, wherein said first photovoltaic p-n junction structure and said second photovoltaic p-n junction structure absorb electromagnetic radiation of different wavelengths.

23. The device of claim 1, wherein said first photovoltaic p-n junction structure absorbs electromagnetic radiation having a wavelength selected from the range of 300 nm to 1250 nm and said second photovoltaic p-n junction structure absorbs electromagnetic radiation having a wavelength selected from the range of 850 nm to 1800 nm.

24. The device of claim 1 further comprising one or more additional electronic components in electrical contact with said first photovoltaic p-n junction structure or said second photovoltaic p-n junction structure, said one or more additional electronic components selected from the group consisting of an electrode, a dielectric layer or any combinations of these.

25. The device of claim 1 further comprising one or more electrical contacts provided in a recessed region of said first interface surface or said second interface surface.

26. The device of claim 1 further comprising one or more additional optical components in optical communication with said first photovoltaic p-n junction structure or said second photovoltaic p-n junction structure, said one or more additional optical components selected from the group consisting of an antireflection coating, a concentrator, an optical filter, a window or any combinations of these.

27. The device of claim 1 further comprising one or more antireflection coatings on said first interface surface or said second interface surface.

28. A method for making a multi-junction photovoltaic device, said method comprising the steps of:
providing a first photovoltaic p-n junction structure characterized by a thickness and lateral dimensions, said first photovoltaic p-n junction structure having a first interface surface;
providing a second photovoltaic p-n junction structure characterized by a thickness and lateral dimensions, said second photovoltaic p-n junction structure having a second interface surface;
providing an interface layer between said first interface surface and said second interface surface, said interface layer comprising a chalcogenide dielectric layer; and
contacting said first interface surface of said first photovoltaic p-n junction structure or said interface layer provided thereon with said second interface surface of said second photovoltaic p-n junction structure or said interface layer provided thereon, thereby making said multi-junction photovoltaic device having a stacked multilayer geometry.

29. The method of claim 28, wherein said lateral dimensions of said first photovoltaic p-n junction structure and said second photovoltaic p-n junction structure are each independently less than or equal to 3000 microns.

30. The method of claim 28, wherein said lateral dimensions of said first photovoltaic p-n junction structure, said second photovoltaic p-n junction structure or both are independently selected from the range of 800 microns to 3000 microns.

31. The method of claim 28, wherein said multi-junction photovoltaic device is characterized by a conversion efficiency for incident solar radiation greater than or equal to 43%.

32. The method of claim 28, wherein said step of providing a first photovoltaic p-n junction structure comprises:
fabricating said first photovoltaic p-n junction structure via epitaxial growth on a mother substrate, wherein said first photovoltaic p-n junction structure is connected to said mother substrate via a sacrificial layer; and
at least partially removing said sacrificial layer.

33. The method of claim 28, wherein said contacting step is carried out via an assembly technique selected from the group consisting of dry transfer printing, solution printing, pick and place assembly, and electrostatic transfer.

34. The method of claim 28, wherein said contacting step further comprises:
contacting a transfer surface of said first photovoltaic p-n junction structure with a contact surface of a conformal transfer device, wherein said first photovoltaic p-n junction structure is adhered to said contact surface; and
contacting said first photovoltaic p-n junction structure adhered to said contact surface with said second photovoltaic p-n junction structure.

35. The method of claim 34, further comprising separating said first photovoltaic p-n junction structure and said conformal transfer device, thereby transferring said first photovoltaic p-n junction structure onto said second photovoltaic p-n junction structure.

36. The method of claim 34, further comprising the step of moving said conformal transfer device having said first photovoltaic p-n junction structure adhered to said contact surface, thereby releasing said first photovoltaic p-n junction structure from a mother substrate; wherein said release involves fracture or disengagement of one or more alignment maintaining elements connecting said first photovoltaic p-n junction structure to said mother wafer.

37. The method of claim 36, wherein said first photovoltaic p-n junction structure is provided in a selected orientation which is maintained by said one or more alignment maintaining elements during contact with said contact surface of said conformal transfer device.

38. The method of claim 34, further comprising contacting transfer surfaces of a first set of additional photovoltaic p-n junction structures with said contact surface of a conformal transfer device, wherein said first set of additional photovoltaic p-n junction structures is adhered to said contact surface; and
contacting said additional photovoltaic p-n junction structures adhered to said contact surface with a second set of photovoltaic p-n junction structures;
wherein contacting of said first set of additional photovoltaic p-n junction structures is carried out in parallel.

39. The method of claim 34, wherein said conformal transfer device comprises an elastomeric stamp.

40. The method of claim 34, wherein said conformal transfer device has a Young's modulus selected from the range of 0.2 MPa to 50 MPa.

41. The method of claim 34, wherein said conformal transfer device has a flexural rigidity selected from the range of 1×10⁻⁷ Nm to 1×10⁻⁵ Nm.

42. The method of claim 28, wherein said interface layer is provided using a sol-gel process, a spin-on process, a spray process or a combination thereof.

43. The method of claim 28, wherein said interface layer comprises an electrically insulating layer characterized by an electrical resistance greater than or equal to 100,000 Ωcm².

44. The method of claim 28, wherein said interface layer comprises a refractive index-matched layer characterized by a refractive index within 30% of the refractive indices at said first interface surface and said second interface surface.

45. The method of claim 28, wherein said interface layer comprises a thermally conductive layer characterized by a thermal conductivity greater than or equal to 0.5 W/m/K.

46. The method of claim 28, wherein said interface layer comprises an optically transparent layer characterized by a transmittance equal to or greater than 90% for light having wavelengths selected over the range of 800 nm to 1800 nm.

47. The method of claim 28, wherein said interface layer comprises an electrostatically stable layer characterized by an electrical breakdown threshold voltage equal to or greater than 15 V.

48. The method of claim 28, wherein said interface layer has a thickness selected from the range of 50 nm to 5 microns.

49. The method of claim 28, wherein said interface layer comprises a selenide, a sulfide or a telluride composition.

50. The method of claim 28, wherein said interface layer comprises As₂Se₃.

51. The method of claim 28, wherein said first photovoltaic p-n junction structure, said second photovoltaic p-n junction structure or both independently comprise epitaxially grown multilayer structures.

52. The method of claim 28, wherein said first photovoltaic p-n junction structure is not epitaxially grown on top of said second photovoltaic p-n junction structure and said second photovoltaic p-n junction structure is not epitaxially grown on top of said first photovoltaic p-n junction structure.

53. The method of claim 28, wherein said first photovoltaic p-n junction structure comprises 1-4 p-n junctions and said second photovoltaic p-n junction structure comprises 1-3 p-n junctions.

54. The method of claim 28, wherein said first photovoltaic p-n junction structure and said second photovoltaic p-n junction structure comprise different multi-junction structures.

55. The method of claim 28, wherein said first p-n junction has a different composition than said second p-n junction.

56. The method of claim 28, wherein said first photovoltaic p-n junction structure has a composition selected from the group consisting of: InGaP/GaAs/InGaAsNSb; AlGaAs; InGaAlP and combinations of these.

57. The method of claim 28, wherein said second photovoltaic p-n junction structure has a composition selected from the group consisting of: a diffusion-junction Ge cell; InGaAs; InGaAsP; AlGaInAs and combinations of these.

58. The method of claim 28, wherein said first photovoltaic p-n junction structure and said second photovoltaic p-n junction structure each have a thickness selected from the range of 1 micron to 250 microns.

59. The method of claim 28, wherein said first photovoltaic p-n junction structure and said second photovoltaic p-n junction structure absorb electromagnetic radiation of different wavelengths.

60. The method of claim 28, wherein said first photovoltaic p-n junction structure absorbs electromagnetic radiation having a wavelength selected from the range of 300 nm to 1250 nm and said second photovoltaic p-n junction structure absorbs electromagnetic radiation having a wavelength selected from the range of 850 nm to 1800 nm.

61. The method of claim 28 further comprising providing one or more additional electronic components in electrical contact with said first photovoltaic p-n junction structure or said second photovoltaic p-n junction structure, said one or more additional electronic components selected from the group consisting of an electrode, a dielectric layer or any combinations of these.

62. The method of claim 28 further comprising providing one or more electrical contacts provided in a recessed region of said first interface surface or said second interface surface.

63. The method of claim 28 further comprising providing one or more additional optical components in optical communication with said first photovoltaic p-n junction structure or said second photovoltaic p-n junction structure, said one or more additional optical components selected from the group consisting of an antireflection coating, a concentrator, an optical filter, a window or any combinations of these.

64. The method of claim 28 further comprising providing one or more antireflection coatings on said first interface surface or said second interface surface.

65. A multi-junction photovoltaic device comprising:
a first photovoltaic p-n junction structure characterized by a thickness and lateral dimensions, said first photovoltaic p-n junction structure having a first interface surface;
a second photovoltaic p-n junction structure characterized by a thickness and lateral dimensions, said second photovoltaic p-n junction structure having a second interface surface; and
an intermediate layer connecting at least a portion of said first photovoltaic p-n junction structure and at least a portion of said second photovoltaic p-n junction structure; wherein an air gap exists between at least a portion of said first interface surface of said first photovoltaic p-n junction structure and at least a portion of said second interface surface of said second photovoltaic p-n junction structure, thereby providing a stacked multilayer device geometry.

66. (canceled)

67. A method for making a multi-junction photovoltaic device, said method comprising the steps of:
providing a first photovoltaic p-n junction structure characterized by a thickness and lateral dimensions, said first photovoltaic p-n junction structure having a first interface surface;
providing a second photovoltaic p-n junction structure characterized by a thickness and lateral dimensions, said second p-n junction having a second interface surface; and
providing an intermediate layer to connect at least a portion of said first photovoltaic p-n junction structure and at least a portion of said second photovoltaic p-n junction structure; wherein an air gap exists between at least a portion of said first interface surface of said first photovoltaic p-n junction structure and at least a portion of said second interface surface of said second photovoltaic p-n junction structure, thereby making said multi-junction photovoltaic device having a stacked multilayer geometry.

68-70. (canceled)

71. A method for making a multi-junction photovoltaic device, said method comprising the steps of:
providing a first photovoltaic p-n junction structure characterized by a thickness and lateral dimensions, said first photovoltaic p-n junction structure having a first interface surface;
providing a second photovoltaic p-n junction structure characterized by a thickness and lateral dimensions, said second photovoltaic p-n junction structure having a second interface surface;
wherein at least one of said first photovoltaic p-n junction structure and said second photovoltaic p-n junction structure independently comprises a multi-junction structure; and wherein said lateral dimensions of said first photovoltaic p-n junction structure, said second photovoltaic p-n junction structure or both are independently selected from the range of 800 microns to 3000 microns;
contacting a transfer surface of said first photovoltaic p-n junction structure with a contact surface of a conformal transfer device, wherein said first photovoltaic p-n junction structure is adhered to said contact surface; and
contacting said first interface surface of said first photovoltaic p-n junction structure adhered to said contact surface, or an intermediate layer provided on said first photovoltaic p-n junction structure, with said second interface surface of said second photovoltaic p-n junction structure, or an intermediate layer provided on said second photovoltaic p-n junction structure, thereby making said multi-junction photovoltaic device having a stacked multilayer geometry.

72-85. (canceled)
